(19) United States
(12) Patent Application Publication
(10) Pub. No.: US 2025/0293198 A1
(43) Pub. Date: Sep. 18, 2025

(54) SEMICONDUCTOR DEVICE

(71) Applicant: ROHM CO., LTD., Kyoto-shi (JP)

(72) Inventors: Shinji YATO, Kyoto-shi (JP); Shumei SHIMOSAKO, Kyoto-shi (JP)

(21) Appl. No.: 19/076,457

(22) Filed: Mar. 11, 2025

(30) Foreign Application Priority Data
Mar. 14, 2024 (JP) 2024-040014

(51) Int. Cl. H01L 23/00; H01L 23/538; H01L 25/07

(52) U.S. Cl. CPC H01L 24/48; H01L 23/5386; H01L 24/73; H01L 25/072; H01L 24/32; H01L 2224/32227; H01L 2224/48139; H01L 2224/48229; H01L 2224/73265

(57) ABSTRACT

A semiconductor device includes a first switching element having a first gate electrode and a second switching element having a second gate electrode and being connected in parallel to the first switching element, a gate interconnect, a first gate connection member connecting the first gate electrode to the gate interconnect, and a second gate connection member connecting the second gate electrode to the gate interconnect. The gate interconnect includes a first interconnect portion and a second interconnect portion extending in one direction, and a joint portion joining the first interconnect portion and the second interconnect portion. The first gate connection member is connected to a part of the first interconnect portion distant from the joint portion in the direction. The second gate connection member is connected to a part of the second interconnect portion distant from the joint portion in the direction.

### CROSS-REFERENCE TO RELATED APPLICATIONS

This application is based upon and claims the benefit of priority from Japanese Patent Application No. 2024-040014, filed on Mar. 14, 2024, the entire contents of which are incorporated herein by reference.

### BACKGROUND

### 1. Field

The present disclosure relates to a semiconductor device.

### 2. Description of Related Art

Japanese Laid-Open Patent Publication No. 2022-79670 discloses a power module including a half-bridge circuit formed of multiple first switching elements and multiple second switching elements. The first switching elements are connected in parallel to each other. The second switching elements are connected in parallel to each other.

### BRIEF DESCRIPTION OF THE DRAWINGS

FIG. 1 is a schematic perspective view of an exemplary semiconductor device according to a first embodiment.

FIG. 2 is a schematic plan view showing the inside of the semiconductor device shown in FIG. 1.

FIG. 3 is a schematic cross-sectional view of the semiconductor device taken along line F3-F3 in FIG. 2.

FIG. 4 is a schematic cross-sectional view of the semiconductor device taken along line F4-F4 in FIG. 2.

FIG. 5 is a schematic cross-sectional view of the semiconductor device taken along line F5-F5 in FIG. 2.

FIG. 6 is a schematic cross-sectional view of the semiconductor device taken along line F6-F6 in FIG. 2.

FIG. 7 is a schematic enlarged plan view showing a portion of FIG. 2.

FIG. 8 is a schematic enlarged plan view showing another portion of FIG. 2.

FIG. 9 is a schematic enlarged plan view showing a first gate interconnect shown in FIG. 2.

FIG. 10 is a schematic circuit diagram of the exemplary semiconductor device according to the first embodiment.

FIG. 11 is a schematic plan view showing the inside of an exemplary semiconductor device according to a second embodiment.

FIG. 12 is a schematic enlarged plan view showing a portion of FIG. 11.

FIG. 13 is a schematic enlarged plan view showing another portion of FIG. 11.

FIG. 14 is a schematic plan view showing the inside of an exemplary semiconductor device according to a third embodiment.

FIG. 15 is a schematic enlarged plan view showing a portion of FIG. 14.

FIG. 16 is a schematic plan view showing the inside of an exemplary semiconductor device according to a fourth embodiment.

FIG. 17 is a schematic cross-sectional view of the semiconductor device taken along line F17-F17 in FIG. 16.

FIG. 18 is a schematic circuit diagram of an inverter device including a semiconductor device.

FIG. 19 is a schematic enlarged plan view of a first gate interconnect and its surroundings in a modified example of a semiconductor device.

FIG. 20 is a schematic enlarged plan view of a first gate interconnect and its surroundings in a modified example of a semiconductor device.

FIG. 21 is a schematic enlarged plan view of a first gate interconnect and its surroundings in a modified example of a semiconductor device.

FIG. 22 is a schematic enlarged plan view of a first gate interconnect and its surroundings in a modified example of a semiconductor device.

FIG. 23 is a schematic enlarged plan view of a first gate interconnect and its surroundings in a modified example of a semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Embodiments of a semiconductor device according to the present disclosure will now be described with reference to the accompanying drawings. In the drawings, elements may not be drawn to scale for simplicity and clarity of illustration. To aid understanding, hatching lines may not be shown in the cross-sectional drawings. The accompanying drawings only illustrate embodiments of the present disclosure and are not intended to limit the present disclosure. The following detailed description includes exemplary embodiments of a device, a system, and a method according to the present disclosure. The detailed description is illustrative and is not intended to limit embodiments of the present disclosure or the application and use of the embodiments.

The phrase “at least one of” as used in this disclosure means “one or more” of a desired choice. For one example, the phrase “at least one of” as used in this disclosure means “only one single choice” or “both of two choices” if the number of its choices is two. For another example, the phrase “at least one of” as used in this disclosure means “only one single choice” or “any combination of two or more choices” if the number of its choices is three or more.

The descriptions used in the present disclosure such as “the dimension (depth, width, length) of A is equal to the dimension (depth, width, length) of B” or “the dimension (depth, width, length) of A and the dimension (depth, width, length) of B are equal to each other” include, for example, a relationship in which the difference is 10% or less between the dimension (depth, width, length) of A and the dimension (depth, width, length) of B.

### First Embodiment

### Structure of Semiconductor Device

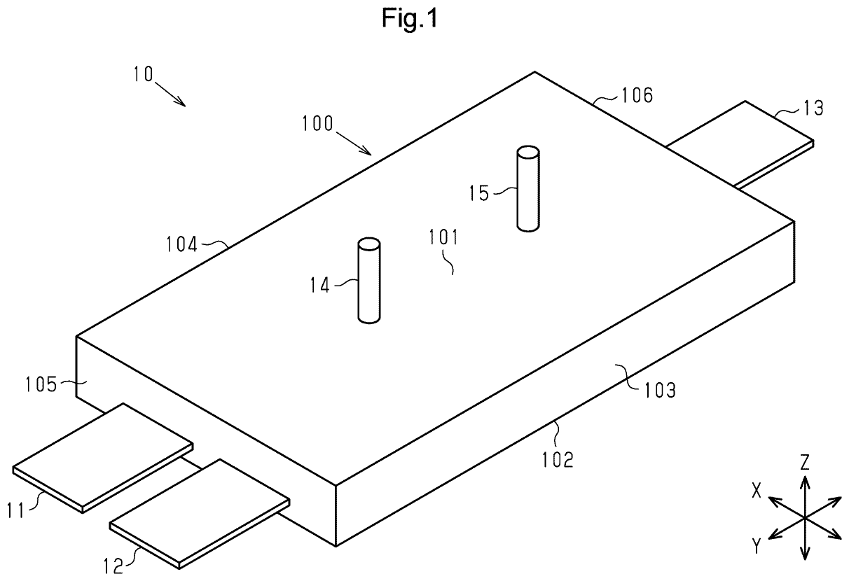

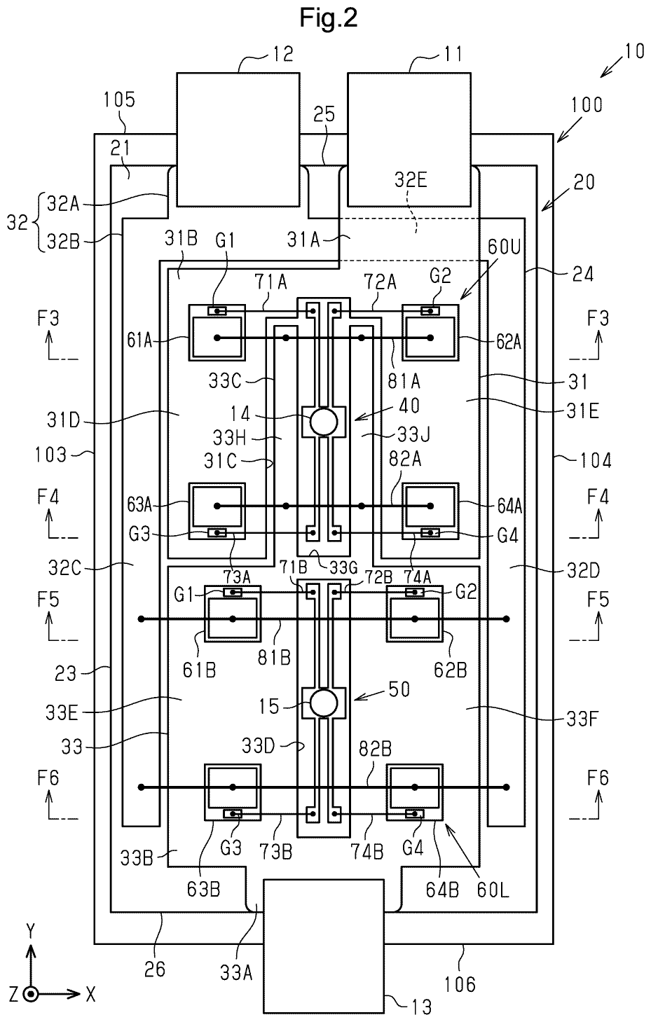

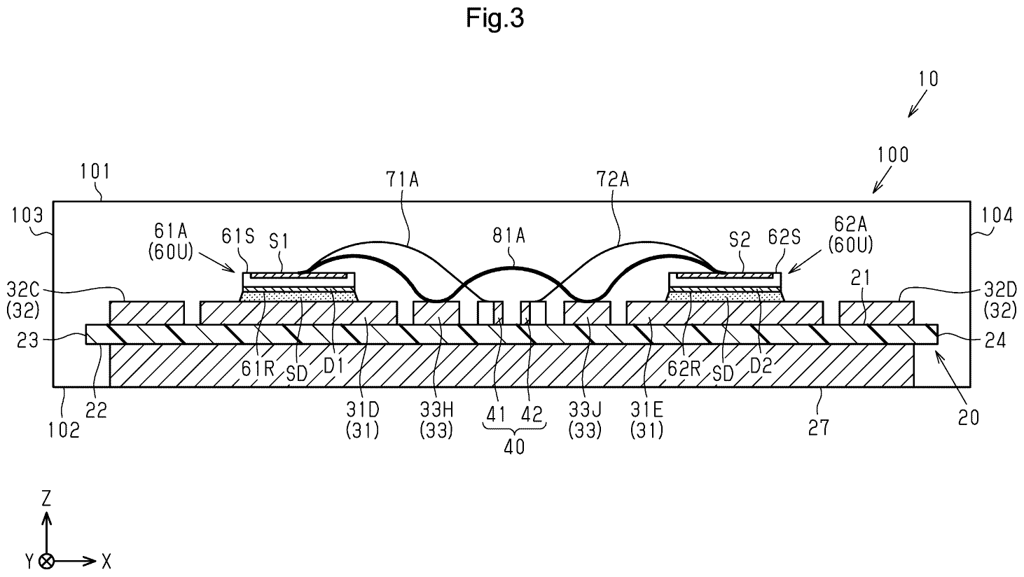

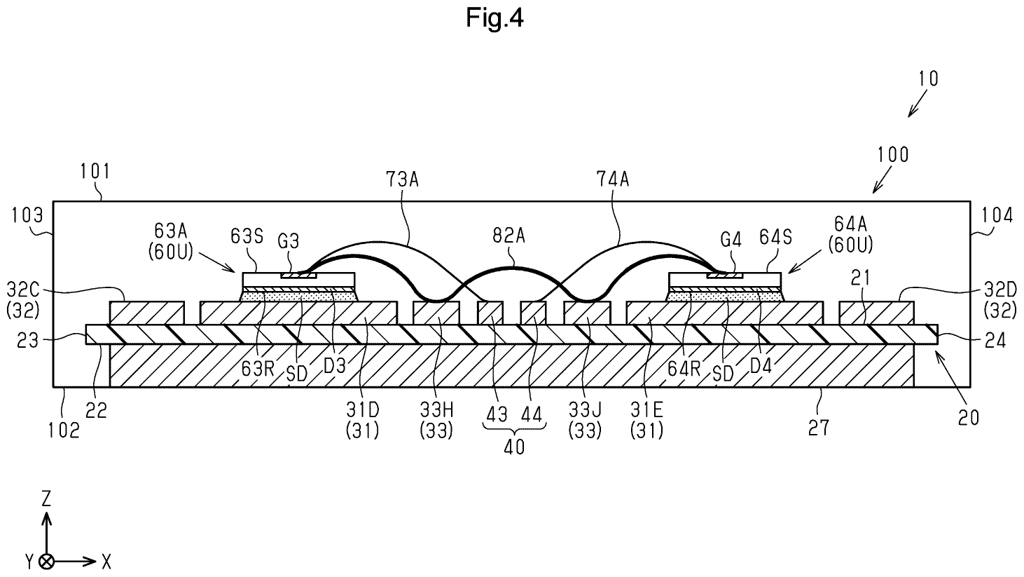

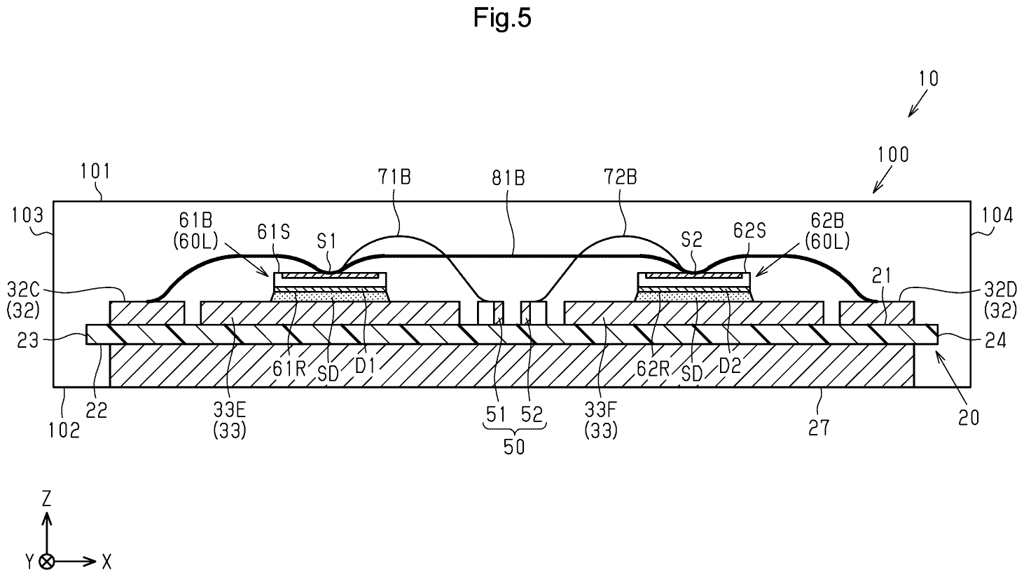

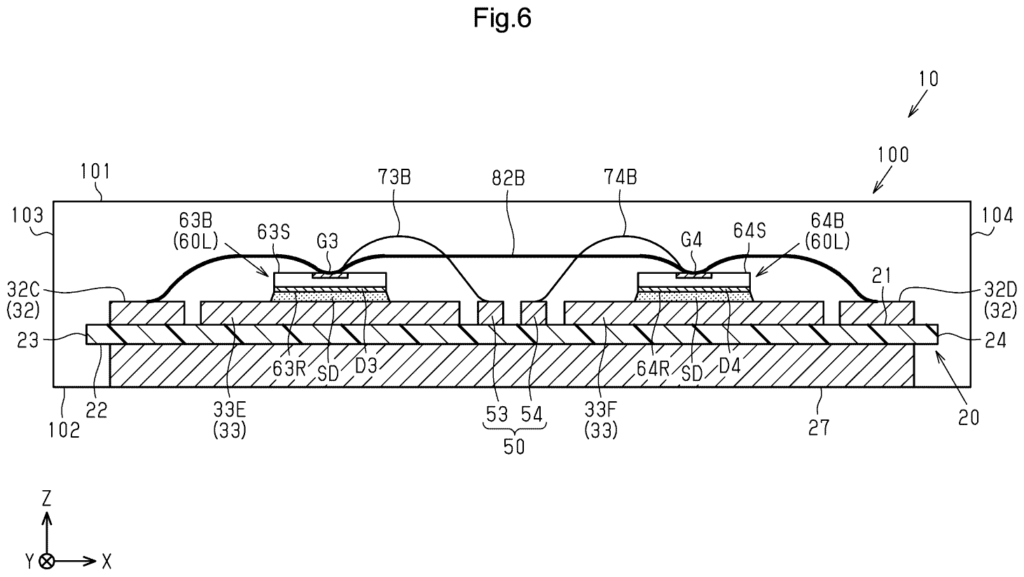

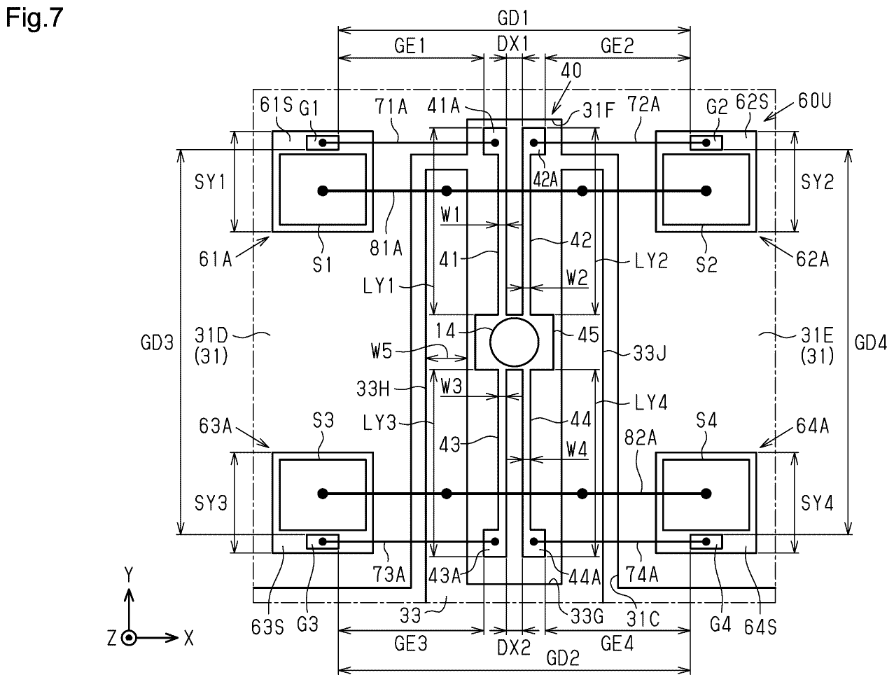

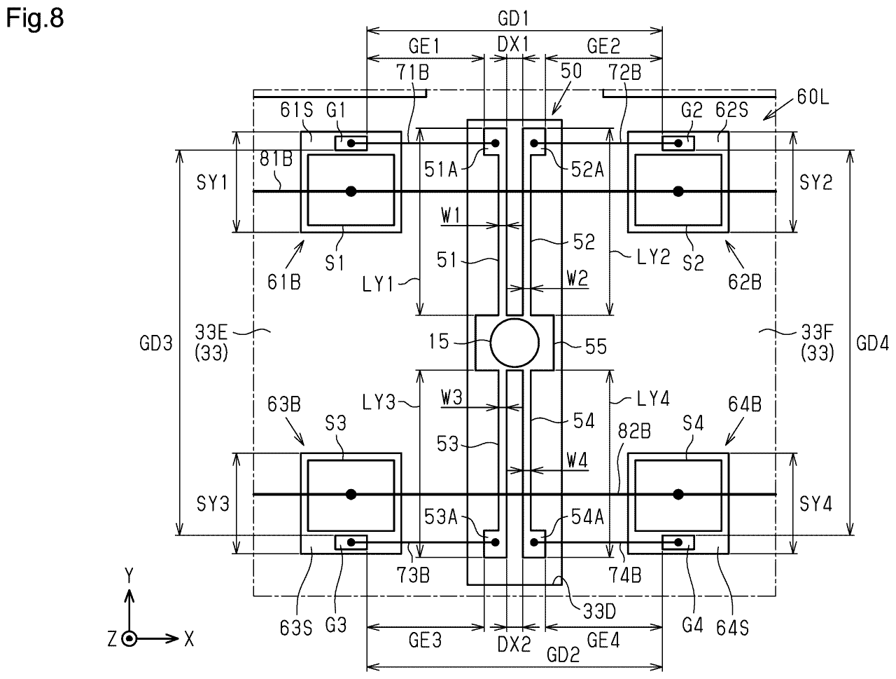

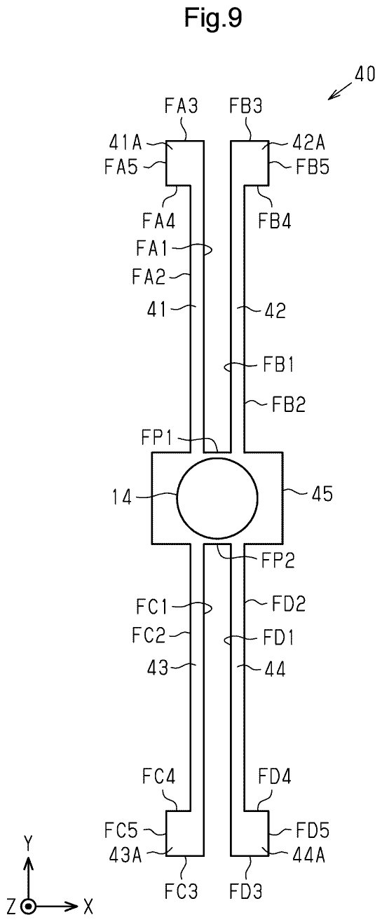

The structure of a first embodiment of a semiconductor device 10 will now be described with reference to FIGS. 1 to 9. FIG. 1 is a schematic perspective view showing a structure of the semiconductor device 10. FIG. 2 is a plan view schematically showing the internal structure of the semiconductor device 10. FIG. 3 is a schematic cross-sectional view showing the structure of the semiconductor device 10 taken along line F3-F3 in FIG. 2. FIG. 4 is a schematic cross-sectional view showing the structure of the semiconductor device 10 taken along line F4-F4 in FIG. 2. FIG. 5 is a schematic cross-sectional view showing the structure of the semiconductor device 10 taken along line F5-F5 in FIG. 2. FIG. 6 is a schematic cross-sectional view showing the structure of the semiconductor device 10 taken along line F6-F6 in FIG. 2. FIG. 7 is a schematic enlarged view showing a portion of the planar structure shown in FIG. 2. FIG. 8 is a schematic enlarged view showing another portion of the planar structure shown in FIG. 2 differing from the portion shown in FIG. 7. FIG. 9 is a schematic view showing the planar structure of a first gate interconnect 40, which will be described later.

### External Appearance of Semiconductor Device

As shown in FIG. 1, the semiconductor device 10 includes a package body 100 and a first power terminal 11, a second power terminal 12, an output terminal 13, a first gate terminal 14, and a second gate terminal 15, each of which projects from the package body 100. The first gate terminal 14 and the second gate terminal 15 are each an example of a “gate terminal.”

The package body 100 is formed of an insulating material. An example of the insulating material is a resin material such as an epoxy resin. The package body 100 has the form of, for example, a rectangular plate having a thickness extending in a Z-direction. In the description hereafter, a view of the semiconductor device 10 taken in the Z-direction will be referred to as “plan view.” Directions that are orthogonal to the Z-direction and are orthogonal to each other are referred to as an “X-direction” and a “Y-direction.” The X-direction is an example of a “first direction.” The Y-direction is an example of a “second direction.”

In plan view, the package body 100 is rectangular such that the long sides extend in the Y-direction and the short sides extend in the X-direction. The package body 100 includes a first surface 101, a second surface 102 opposite to the first surface 101, and first to fourth side surfaces 103 to 106, which are four side surfaces connecting the first surface 101 and the second surface 102. The first surface 101 and the second surface 102 each include, for example, a flat surface orthogonal to the Z-direction. The first side surface 103 and the second side surface 104 define two end surfaces of the package body 100 in the X-direction. The third side surface 105 and the fourth side surface 106 define two end surfaces of the package body 100 in the Y-direction.

The first power terminal 11 and the second power terminal 12 project from the third side surface 105 of the package body 100. The output terminal 13 projects from the fourth side surface 106 of the package body 100. That is, the first power terminal 11 and the second power terminal 12 project at a side of the package body 100 opposite from the side of the output terminal 13. The first power terminal 11 and the second power terminal 12 are arranged next to each other in the X-direction in plan view. Each of the first power terminal 11, the second power terminal 12, and the output terminal 13 has the form of a rectangular plate in plan view. The first gate terminal 14 and the second gate terminal 15 project from the first surface 101. The first gate terminal 14 and the second gate terminal 15 each have the form of a pin extending in the Z-direction.

The first power terminal 11, the second power terminal 12, the output terminal 13, the first gate terminal 14, and the second gate terminal 15 are each formed from a conductive material. Examples of the conductive material include aluminum (Al) and copper (Cu). The conductive material forming the first gate terminal 14 and the second gate terminal 15 may be the same as or differ from the conductive material forming the first power terminal 11, the second power terminal 12, and the output terminal 13. In an example, the first gate terminal 14 and the second gate terminal 15 are formed from a material including Al, and the first power terminal 11, the second power terminal 12, and the output terminal 13 are formed from a material including Cu. The conductive material is not limited to Al and Cu and may be any material.

### Internal Structure of Semiconductor Device

As shown in FIG. 2, the semiconductor device 10 includes an insulative substrate 20, switching elements 60U and switching elements 60L that are mounted on the insulative substrate 20, first to fourth gate connection members 71A to 74A and 71B to 74B, first source connection members 81A and 81B, and second source connection members 82A and 82B. In the semiconductor device 10, the switching elements 60U and the switching elements 60L are connected to each other in series to form an inverter circuit. Each switching element 60U forms an upper arm. Each switching element 60L forms a lower arm. Thus, the switching elements 60U is an example of an “upper-arm switching element.” The switching element 60L is an example of a “lower-arm switching element.”

The insulative substrate 20 has the form of a rectangular plate having a thickness extending in the Z-direction. In the example shown in FIG. 2, in plan view, the insulative substrate 20 is rectangular so that the long sides extend in the Y-direction and the short sides extend in the X-direction. The insulative substrate 20 is formed from, for example, ceramic such as silicon nitride (Si₃N₄) or alumina (Al₂O₃).

The insulative substrate 20 includes a first substrate surface 21, a second substrate surface 22 opposite to the first substrate surface 21, and first to fourth substrate side surfaces 23 to 26 that are four substrate side surfaces connecting the first substrate surface 21 and the second substrate surface 22. The first substrate side surface 23 and the second substrate side surface 24 define two end surfaces of the insulative substrate 20 in the X-direction. The third substrate side surface 25 and the fourth substrate side surface 26 define two end surfaces of the insulative substrate 20 in the Y-direction.

As shown in FIG. 3, a heat dissipation plate 27 is bonded to the second substrate surface 22 of the insulative substrate 20. The heat dissipation plate 27 is exposed from the second surface 102 of the package body 100. The heat dissipation plate 27 is formed from, for example, a material including Cu or Al. In an example, the heat dissipation plate 27 is formed from a material including Cu. The heat dissipation plate 27 has the form of a rectangular plate having a thickness extending in the Z-direction. The heat dissipation plate 27 is rectangular and slightly smaller than the insulative substrate 20 in plan view. In the example shown in FIG. 3, the thickness of the heat dissipation plate 27 is greater than that of the insulative substrate 20. The thickness of the heat dissipation plate 27 may be changed in any manner in accordance with the heat dissipation property.

As shown in FIGS. 2 to 4, the semiconductor device 10 includes first to third power interconnects 31 to 33, a first gate interconnect 40, and a second gate interconnect 50 that are arranged on the first substrate surface 21 of the insulative substrate 20. The first to third power interconnects 31 to 33, the first gate interconnect 40, and the second gate interconnect 50 are formed from, for example, a material including Al and/or Cu. In an example, the first to third power interconnects 31 to 33, the first gate interconnect 40, and the second gate interconnect 50 are formed from a material including Cu. Each of the first gate interconnect 40 and the second gate interconnect 50 is an example of a “gate interconnect.”

As shown in FIG. 2, the first power interconnect 31 is configured to be electrically connected to the first power terminal 11. The first power interconnect 31 is arranged on the first substrate surface 21 toward the third substrate side surface 25 in plan view. The first power interconnect 31 includes a terminal connector 31A, to which the first power terminal 11 is connected, and an element mount 31B, on which the switching elements 60U are mounted. In the example shown in FIG. 2, the terminal connector 31A is integrated with the element mount 31B. Since the switching elements 60U are mounted on the first power interconnect 31, the first power interconnect 31 is an example of an “upper-arm power interconnect.”

The terminal connector 31A and the element mount 31B are arranged next to each other in the Y-direction. The terminal connector 31A is arranged on the first substrate surface 21 toward the second substrate side surface 24 and the third substrate side surface 25 in plan view. In plan view, the element mount 31B is located closer to the fourth substrate side surface 26 than the terminal connector 31A is. The element mount 31B includes a recess 31C that is open toward the fourth substrate side surface 26. In an example, the recess 31C has the form of a rectangular recess in plan view. The element mount 31B includes a first mount portion 31D and a second mount portion 31E located at opposite sides of the recess 31C in the X-direction. The first mount portion 31D and the second mount portion 31E each extend in the Y-direction. The recess 31C is an example of a “first recess.”

The second power interconnect 32 is configured to be electrically connected to the second power terminal 12. The second power interconnect 32 includes a terminal connector 32A, to which the second power terminal 12 is connected, and an element connector 32B, to which switching elements 60L are electrically connected. In the example shown in FIG. 2, the terminal connector 32A is integrated with the element connector 32B.

The terminal connector 32A is arranged next to the terminal connector 31A of the first power interconnect 31 in the X-direction in plan view. The terminal connector 32A is arranged toward the first substrate side surface 23 with respect to the terminal connector 31A. The terminal connector 32A and the terminal connector 31A differ from each other in position in the Z-direction. The terminal connector 31A is spaced apart from the first substrate surface 21 in the Z-direction. The terminal connector 32A is in contact with the first substrate surface 21.

The element connector 32B includes a first connection portion 32C and a second connection portion 32D spaced apart from each other in the X-direction and a joint portion 32E joining the first connection portion 32C and the second connection portion 32D. Each of the first connection portion 32C, the second connection portion 32D, and the joint portion 32E is in contact with the first substrate surface 21.

The first connection portion 32C and the second connection portion 32D are spaced apart from each other in the X-direction. In plan view, each of the first connection portion 32C and the second connection portion 32D is belt-shaped and extends in the Y-direction. The first connection portion 32C and the second connection portion 32D each extend in the Y-direction from the joint portion 32E to the same position as a third switching element 63B and a fourth switching element 64B, which will be described later.

The first connection portion 32C is arranged closer to the first substrate side surface 23 than the terminal connector 32A is. The first connection portion 32C is arranged adjacent to the first mount portion 31D of the first power interconnect 31 in the X-direction. The first connection portion 32C is arranged closer to the first substrate side surface 23 than the first mount portion 31D is.

The second connection portion 32D is arranged closer to the second substrate side surface 24 than the terminal connector 32A is. The second connection portion 32D is arranged closer to the second substrate side surface 24 than the terminal connector 31A is. The second connection portion 32D is arranged adjacent to the second mount portion 31E of the first power interconnect 31 in the X-direction. The second connection portion 32D is arranged closer to the second substrate side surface 24 than the second mount portion 31E is.

The joint portion 32E is belt-shaped and extends in the X-direction. The joint portion 32E is connected to an end of each of the first connection portion 32C and the second connection portion 32D that is located toward the third substrate side surface 25. The joint portion 32E is located closer to the third substrate side surface 25 than the element mount 31B of the first power interconnect 31 is. The joint portion 32E includes a part overlapping the terminal connector 31A of the first power interconnect 31 in plan view. The joint portion 32E is spaced apart from the terminal connector 31A and located closer to the first substrate surface 21 than the terminal connector 31A is in the Z-direction. In other words, the terminal connector 31A is spaced apart from the first substrate surface 21 in the Z-direction. The joint portion 32E is connected to the terminal connector 32A.

The third power interconnect 33 is configured to be electrically connected to the output terminal 13. The third power interconnect 33 is arranged on the first substrate surface 21 toward the fourth substrate side surface 26 in plan view. The third power interconnect 33 includes a terminal connector 33A to which the output terminal 13 is connected, an element mount 33B on which the switching elements 60L are mounted, and an element connector 33C electrically connected to the switching elements 60U. In the example shown in FIG. 2, the terminal connector 33A, the element mount 33B, and the element connector 33C are integrated with each other. Since the switching elements 60L are mounted on the third power interconnect 33, the third power interconnect 33 is an example of a “lower-arm power interconnect.” The element connector 33C is an example of a “connector.”

The terminal connector 33A, the element mount 33B, and the element connector 33C are arranged next to one another in the Y-direction. The terminal connector 33A is arranged closer to the fourth substrate side surface 26 than the element mount 33B and the element connector 33C are. The terminal connector 33A is arranged on an end of the first substrate surface 21 located toward the fourth substrate side surface 26 in the center in the X-direction.

The element mount 33B is arranged closer to the fourth substrate side surface 26 than the element connector 33C is. Therefore, the element mount 33B is arranged between the terminal connector 33A and the element connector 33C in the Y-direction. The element mount 33B is arranged closer to the fourth substrate side surface 26 than the element mount 31B of the first power interconnect 31 is. The element mount 33B is arranged between the first connection portion 32C and the second connection portion 32D of the second power interconnect 32 in the X-direction.

The element mount 33B includes an opening 33D arranged in the center in the X-direction. The opening 33D extends in the Y-direction in plan view. The element mount 33B includes a first mount portion 33E and a second mount portion 33F located at opposite sides of the opening 33D in the X-direction. The first mount portion 33E is arranged closer to the first substrate side surface 23 than the opening 33D is. The second mount portion 33F is arranged closer to the second substrate side surface 24 than the opening 33D is. The first mount portion 33E is arranged adjacent to the first connection portion 32C of the second power interconnect 32 in the X-direction. The second mount portion 33F is arranged adjacent to the second connection portion 32D of the second power interconnect 32 in the X-direction.

In plan view, the element connector 33C is disposed in the recess 31C of the element mount 31B of the first power interconnect 31. The element connector 33C extends in the Y-direction. In plan view, the element connector 33C includes a recess 33G that is open toward the third substrate side surface 25. The element connector 33C includes a first connection portion 33H and a second connection portion 33J spaced apart from each other in the X-direction and defining the recess 33G. The first connection portion 33H is located closer to the first substrate side surface 23 than the second connection portion 33J is. The first connection portion 33H is located closer to the second substrate side surface 24 than the first mount portion 31D of the first power interconnect 31. The second connection portion 33J is located closer to the first substrate side surface 23 than the second mount portion 31E of the first power interconnect 31 is. Each of the first connection portion 33H and the second connection portion 33J is belt-shaped and extends in the Y-direction in plan view. The recess 33G is an example of a “second recess.”

The first gate interconnect 40 is configured to be electrically connected to the first gate terminal 14. In plan view, the first gate interconnect 40 is arranged in the recess 31C of the first power interconnect 31. In plan view, the first gate interconnect 40 is arranged in the recess 33G of the element connector 33C of the third power interconnect 33. In other words, the first gate interconnect 40 is arranged in a region surrounded by the recesses 31C and 33G in plan view. The first connection portion 33H and the second connection portion 33J are separately arranged at opposite sides of the first gate interconnect 40 in the X-direction.

The second gate interconnect 50 is configured to be electrically connected to the second gate terminal 15. The second gate interconnect 50 is arranged in the opening 33D of the third power interconnect 33 in plan view. The structure of the first gate interconnect 40 and the second gate interconnect 50 will be later described in detail.

The switching elements 60U are configured to be mounted on the first power interconnect 31. The switching elements 60U include a first switching element 61A, a second switching element 62A, a third switching element 63A, and a fourth switching element 64A. The first to fourth switching elements 61A to 64A include, for example, a metal insulation semiconductor field effect transistor (MISFET) arranged on a silicon (Si) substrate, a silicon carbide (SiC) substrate, or a wide-bandgap semiconductor substrate. In an example, the first to fourth switching elements 61A to 64A are identical to each other. In an example, the first to fourth switching elements 61A to 64A are each formed of a vertical transistor. The first to fourth switching elements 61A to 64A each have the form of, for example, a rectangular plate having a thickness extending in the Z-direction. Therefore, the plan view refers to, for example, a view taken in the thickness-wise direction of the first switching element 61A. In the example shown in FIG. 2, the first to fourth switching elements 61A to 64A are each square in plan view. The first to fourth switching elements 61A to 64A may be changed to any shape in plan view. In an example, in plan view, the first to fourth switching elements 61A to 64A may be rectangular such that the long sides extend in the Y-direction and the short sides extend in the X-direction.

As shown in FIGS. 2, 3, and 7, the first switching element 61A is mounted on the first mount portion 31D of the first power interconnect 31. More specifically, the first switching element 61A is bonded to the first mount portion 31D by a conductive bonding material SD.

The first switching element 61A includes a first front surface 61S and a first back surface 61R opposite to the first front surface 61S. The first switching element 61A includes a first gate electrode G1 and a first source electrode S1, which are arranged on the first front surface 61S, and a first drain electrode D1, which is arranged on the first back surface 61R. The first back surface 61R of the first switching element 61A is bonded to the first mount portion 31D by the conductive bonding material SD. Thus, the first drain electrode D1 of the first switching element 61A is electrically connected to the first mount portion 31D (first power interconnect 31). The first front surface 61S is an example of a “first element surface.”

The first gate electrode G1 is arranged on an end of the first front surface 61S in the Y-direction at the center in the X-direction. In the example shown in FIG. 2, the first switching element 61A is arranged so that the first gate electrode G1 is located on an end of the first front surface 61S located toward the third substrate side surface 25. The position of the first gate electrode G1 may be changed in any manner. In an example, the first gate electrode G1 may be arranged on any of the four corners of the first front surface 61S.

The first gate electrode G1 is electrically connected to the first gate interconnect 40 by the first gate connection member 71A. The first gate connection member 71A is, for example, a bonding wire. The first gate connection member 71A is formed from a conductive material such as Al, Cu and/or gold (Au).

The second switching element 62A is mounted on the second mount portion 31E of the first power interconnect 31. More specifically, the second switching element 62A is bonded to the second mount portion 31E by the conductive bonding material SD. In the example shown in FIG. 2, the first switching element 61A and the second switching element 62A are located at the same position in the Y-direction and spaced apart from each other in the X-direction.

The second switching element 62A includes a second front surface 62S and a second back surface 62R opposite to the second front surface 62S. The second switching element 62A includes a second gate electrode G2 and a second source electrode S2, which are arranged on the second front surface 62S, and a second drain electrode D2, which is arranged on the second back surface 62R. The second front surface 62S is an example of a “second element surface”.

The second back surface 62R of the second switching element 62A is bonded to the second mount portion 31E by the conductive bonding material SD. Thus, the second drain electrode D2 of the second switching element 62A is electrically connected to the second mount portion 31E (first power interconnect 31). The first switching element 61A is mounted on the first mount portion 31D, and the second switching element 62A is mounted on the second mount portion 31E. Thus, the first gate interconnect 40 is arranged between the first switching element 61A and the second switching element 62A in the X-direction.

The second gate electrode G2 is arranged on an end of the second front surface 62S in the Y-direction at the center in the X-direction. In the example shown in FIG. 2, the second switching element 62A is arranged so that the second gate electrode G2 is located on an end of the second front surface 62S located toward the third substrate side surface 25. The position of the second gate electrode G2 may be changed in any manner. In an example, the second gate electrode G2 may be arranged on any of the four corners of the second front surface 62S.

The second gate electrode G2 is electrically connected to the first gate interconnect 40 by the second gate connection member 72A. The second gate connection member 72A is, for example, a bonding wire. The second gate connection member 72A is formed from a conductive material such as Al, Cu and/or Au.

The first source electrode S1 of the first switching element 61A and the second source electrode S2 of the second switching element 62A are electrically connected to the third power interconnect 33 by the first source connection member 81A. In other words, the first source connection member 81A is a wire that connects the first source electrode S1, the second source electrode S2, and the third power interconnect 33. The first source connection member 81A extends in the X-direction in plan view. More specifically, the first source connection member 81A may be divided into first to third parts in the X-direction. The first part of the first source connection member 81A connects the first source electrode S1 and the first connection portion 33H of the third power interconnect 33. The second part connects the first connection portion 33H and the second connection portion 33J of the third power interconnect 33. The second part extends over the first gate interconnect 40. The third part connects the second connection portion 33J and the second source electrode S2. The first source connection member 81A is, for example, a bonding wire. In an example, the diameter of the first source connection member 81A is greater than the diameter of the first gate connection member 71A and the diameter of the second gate connection member 72A. The first source connection member 81A is formed from a conductive material such as Al, Cu and/or Au.

As shown in FIGS. 2, 4, and 7, the third switching element 63A is mounted on the first mount portion 31D. More specifically, the third switching element 63A is bonded to the first mount portion 31D by the conductive bonding material SD. Thus, the third switching element 63A is arranged toward the first switching element 61A with respect to the first gate interconnect 40 in the X-direction. The third switching element 63A is arranged on the first mount portion 31D closer to the fourth substrate side surface 26 than the first switching element 61A is. The third switching element 63A is arranged to overlap the first switching element 61A as viewed in the Y-direction. In the example shown in FIG. 2, the third switching element 63A and the first switching element 61A are located at the same position in the X-direction.

The third switching element 63A includes a third front surface 63S and a third back surface 63R opposite to the third front surface 63S. The third switching element 63A includes a third gate electrode G3 and a third source electrode S3, which are arranged on the third front surface 63S, and a third drain electrode D3, which is arranged on the third back surface 63R. The third back surface 63R of the third switching element 63A is bonded to the first mount portion 31D by the conductive bonding material SD. Thus, the third drain electrode D3 of the third switching element 63A is electrically connected to the first mount portion 31D (first power interconnect 31).

The third gate electrode G3 is arranged on an end of the third front surface 63S in the Y-direction at the center in the X-direction. In the example shown in FIG. 2, the third switching element 63A is arranged so that the third gate electrode G3 is located on an end of the third front surface 63S located toward the fourth substrate side surface 26. The position of the third gate electrode G3 may be changed in any manner. In an example, the third gate electrode G3 may be arranged on any of the four corners of the third front surface 63S.

The third gate electrode G3 is electrically connected to the first gate interconnect 40 by the third gate connection member 73A. The third gate connection member 73A is, for example, a bonding wire. The third gate connection member 73A is formed from a conductive material such as Al, Cu, and/or Au.

The fourth switching element 64A is mounted on the second mount portion 31E. More specifically, the fourth switching element 64A is bonded to the second mount portion 31E by the conductive bonding material SD. Thus, the fourth switching element 64A is arranged toward the second switching element 62A with respect to the first gate interconnect 40 in the X-direction. The fourth switching element 64A is arranged on the second mount portion 31E closer to the fourth substrate side surface 26 than the second switching element 62A is. As viewed in the Y-direction, the fourth switching element 64A is arranged to overlap the second switching element 62A. In the example shown in FIG. 2, the fourth switching element 64A and the second switching element 62A are located at the same position in the X-direction. In the example shown in FIG. 2, the third switching element 63A and the fourth switching element 64A are located at the same position in the Y-direction and spaced apart from each other in the X-direction.

The fourth switching element 64A includes a fourth front surface 64S and a fourth back surface 64R opposite to the fourth front surface 64S. The fourth switching element 64A includes a fourth gate electrode G4 and a fourth source electrode S4, which are arranged on the fourth front surface 64S, and a fourth drain electrode D4, which is arranged on the fourth back surface 64R. The fourth back surface 64R of the fourth switching element 64A is bonded to the second mount portion 31E by the conductive bonding material SD. Thus, the fourth drain electrode D4 of the fourth switching element 64A is electrically connected to the second mount portion 31E (first power interconnect 31).

The fourth gate electrode G4 is arranged on an end of the fourth front surface 64S in the Y-direction at the center in the X-direction. In the example shown in FIG. 2, the fourth switching element 64A is arranged so that the fourth gate electrode G4 is located on an end of the fourth front surface 64S located toward the fourth substrate side surface 26. The position of the fourth gate electrode G4 may be changed in any manner. In an example, the fourth gate electrode G4 may be arranged on any of the four corners of the fourth front surface 64S.

The fourth gate electrode G4 is electrically connected to the first gate interconnect 40 by the fourth gate connection member 74A. The fourth gate connection member 74A is, for example, a bonding wire. The fourth gate connection member 74A is formed from a conductive material such as Al, Cu and/or Au.

The third source electrode S3 of the third switching element 63A and the fourth source electrode S4 of the fourth switching element 64A are electrically connected to the third power interconnect 33 by the second source connection member 82A. In other words, the second source connection member 82A is a wire that connects the third source electrode S3, the fourth source electrode S4, and the third power interconnect 33. The second source connection member 82A extends in the X-direction in plan view. More specifically, the second source connection member 82A may be divided into first to third parts in the X-direction. The first part of the second source connection member 82A connects the third source electrode S3 and the first connection portion 33H of the third power interconnect 33. The second part connects the first connection portion 33H and the second connection portion 33J of the third power interconnect 33. The second part extends over the first gate interconnect 40. The third part connects the second connection portion 33J and the fourth source electrode S4. The second source connection member 82A is, for example, a bonding wire. In an example, the diameter of the second source connection member 82A is greater than the diameter of the third gate connection member 73A and the diameter of the fourth gate connection member 74A. The second source connection member 82A is formed from a conductive material such as Al, Cu and/or Au.

The diameter of the first source connection member 81A and the second source connection member 82A and the number of first source connection members 81A and second source connection members 82A may be changed in any manner. In an example, multiple first source connection members 81A and multiple second source connection members 82A may be arranged. In this case, the number of first source connection members 81A may be equal to the number of second source connection members 82A.

As shown in FIG. 2, the switching elements 60L are configured to be mounted on the third power interconnect 33. In other words, the switching elements 60L form a lower arm of an inverter circuit. The switching elements 60L include a first switching element 61B, a second switching element 62B, a third switching element 63B, and a fourth switching element 64B. The first to fourth switching elements 61B to 64B include, for example, a MISFET arranged on a Si substrate, a SiC substrate, or a wide-bandgap semiconductor substrate. In an example, the first to fourth switching elements 61B to 64B are identical to each other. In an example, the first to fourth switching elements 61B to 64B are formed of a vertical transistor. In the example shown in FIG. 2, the first to fourth switching elements 61B to 64B are the same in structure and size as the first to fourth switching elements 61A to 64A. Hence, the same reference characters are given to the first to fourth switching elements 61B to 64B that are the same as the corresponding first to fourth switching elements 61A to 64A. Such elements will not be described in detail. The first switching element 61B is an example of a “fifth switching element,” and the second switching element 62B is an example of a “sixth switching element.” The first gate electrode G1 of the first switching element 61B is an example of a “fifth gate electrode.” The second gate electrode G2 of the second switching element 62B is an example of a “sixth gate electrode.”

The second switching element 62A is connected in parallel to the first switching element 61A. The third switching element 63A is connected in parallel to the first switching element 61A and the second switching element 62A. The fourth switching element 64A is connected in parallel to the first switching element 61A, the second switching element 62A, and the third switching element 63A. The second switching element 62B is connected in parallel to the first switching element 61B. The third switching element 63B is connected in parallel to the first switching element 61B and the second switching element 62B. The fourth switching element 64B is connected in parallel to the first switching element 61B, the second switching element 62B, and the third switching element 63B.

As shown in FIGS. 2, 5, and 8, the first switching element 61B is located closer to the fourth substrate side surface 26 than the third switching element 63A is. The first switching element 61B is mounted on the first mount portion 33E of the third power interconnect 33. More specifically, the first switching element 61B is bonded to the first mount portion 33E by the conductive bonding material SD. Thus, the first drain electrode D1 of the first switching element 61B is electrically connected to the first mount portion 33E (third power interconnect 33).

The first switching element 61B is arranged to overlap the third switching element 63A as viewed in the Y-direction. In the example shown in FIG. 2, the first switching element 61B partially overlaps the third switching element 63A as viewed in the Y-direction. The first switching element 61B is displaced from the third switching element 63A toward the second substrate side surface 24 in the X-direction. In the example shown in FIG. 2, the first switching element 61B is arranged so that the first gate electrode G1 is located on an end of the first front surface 61S located toward the third substrate side surface 25.

The first gate electrode G1 is electrically connected to the second gate interconnect 50 by the first gate connection member 71B. The first gate connection member 71B is, for example, a bonding wire. The first gate connection member 71B is formed from a conductive material such as Al, Cu and/or Au.

The second switching element 62B is located closer to the fourth substrate side surface 26 than the fourth switching element 64A is. The second switching element 62B is mounted on the second mount portion 33F of the third power interconnect 33. More specifically, the second switching element 62B is bonded to the second mount portion 33F by the conductive bonding material SD. Thus, the second drain electrode D2 of the second switching element 62B is electrically connected to the second mount portion 33F (third power interconnect 33).

As viewed in the Y-direction, the second switching element 62B is arranged to overlap the fourth switching element 64A. In the example shown in FIG. 2, the second switching element 62B is arranged to partially overlap the fourth switching element 64A as viewed in the Y-direction. The second switching element 62B is displaced from the fourth switching element 64A toward the first substrate side surface 23 in the X-direction. Therefore, the distance between the first switching element 61B and the second switching element 62B in the X-direction is less than the distance between the third switching element 63A and the fourth switching element 64A in the X-direction. In the example shown in FIG. 2, the second switching element 62B is arranged so that the second gate electrode G2 is located at an end of the second front surface 62S located toward the third substrate side surface 25.

The second gate electrode G2 is electrically connected to the second gate interconnect 50 by the second gate connection member 72B. The second gate connection member 72B is, for example, a bonding wire. The second gate connection member 72B is formed from a conductive material such as Al, Cu and/or Au.

The first source electrode S1 of the first switching element 61B and the second source electrode S2 of the second switching element 62B are electrically connected to the second power interconnect 32 by the first source connection member 81B. In other words, the first source connection member 81B is a wire that connects the first source electrode S1, the second source electrode S2, and the second power interconnect 32. The first source connection member 81B extends in the X-direction in plan view. The first source connection member 81B may be divided into first to third parts in the X-direction. The first part of the first source connection member 81B connects the first source electrode S1 and the first connection portion 32C of the second power interconnect 32. The second part connects the first source electrode S1 and the second source electrode S2. The second part extends over the second gate interconnect 50. The third part connects the second source electrode S2 and the second connection portion 32D of the second power interconnect 32. The first source connection member 81B is, for example, a bonding wire. In an example, the diameter of the first source connection member 81B is greater than the diameter of the first gate connection member 71B and the diameter of the second gate connection member 72B. The first source connection member 81B is formed from a conductive material such as Al, Cu and/or Au.

As shown in FIGS. 2, 6, and 8, the third switching element 63B is mounted on the first mount portion 33E. More specifically, the third switching element 63B is bonded to the first mount portion 33E by the conductive bonding material SD. Since the third back surface 63R of the third switching element 63B is bonded to the first mount portion 33E by the conductive bonding material SD, the third drain electrode D3 of the third switching element 63B is electrically connected to the first mount portion 33E (third power interconnect 33).

The third switching element 63B is arranged on the first mount portion 33E closer to the fourth substrate side surface 26 than the first switching element 61B is. As viewed in the Y-direction, the third switching element 63B is arranged to overlap the first switching element 61B. In the example shown in FIG. 2, the third switching element 63B and the first switching element 61B are located at the same position in the X-direction. In the example shown in FIG. 2, the third switching element 63B is arranged so that the third gate electrode G3 is located on an end of the third front surface 63S located toward the fourth substrate side surface 26.

The third gate electrode G3 is electrically connected to the second gate interconnect 50 by the third gate connection member 73B. The third gate connection member 73B is, for example, a bonding wire. The third gate connection member 73B is formed from a conductive material such as Al, Cu and/or Au.

The fourth switching element 64B is mounted on the second mount portion 33F. More specifically, the fourth switching element 64B is bonded to the second mount portion 33F by the conductive bonding material SD. Since the fourth back surface 64R of the fourth switching element 64B is bonded to the second mount portion 33F by the conductive bonding material SD, the fourth drain electrode D4 of the fourth switching element 64B is electrically connected to the second mount portion 33F (third power interconnect 33).

The fourth switching element 64B is arranged on the second mount portion 33F closer to the fourth substrate side surface 26 than the second switching element 62B is. As viewed in the Y-direction, the fourth switching element 64B is arranged to overlap the second switching element 62B. In the example shown in FIG. 2, the fourth switching element 64B and the second switching element 62B are located at the same position in the X-direction. In the example shown in FIG. 2, the fourth switching element 64B is arranged so that the fourth gate electrode G4 is located on an end of the fourth front surface 64S located toward the fourth substrate side surface 26.

The fourth gate electrode G4 is electrically connected to the second gate interconnect 50 by the fourth gate connection member 74B. The fourth gate connection member 74B is, for example, a bonding wire. The fourth gate connection member 74B is formed from a conductive material such as Al, Cu and/or Au.

The third source electrode S3 of the third switching element 63B and the fourth source electrode S4 of the fourth switching element 64B are electrically connected to the second power interconnect 32 by the second source connection member 82B. The second source connection member 82B is a wire that connects the third source electrode S3, the fourth source electrode S4, and the second power interconnect 32. In plan view, the second source connection member 82B extends in the X-direction. The second source connection member 82B may be divided into first to third parts in the X-direction. The first part of the second source connection member 82B connects the third source electrode S3 and the first connection portion 32C of the second power interconnect 32. The second part connects the third source electrode S3 and the fourth source electrode S4. The second part extends over the second gate interconnect 50. The third part connects the fourth source electrode S4 and the second connection portion 32D of the second power interconnect 32. The second source connection member 82B is, for example, a bonding wire. In an example, the diameter of the second source connection member 82B is greater than the diameter of the third gate connection member 73B and the diameter of the fourth gate connection member 74B. The second source connection member 82B is formed from a conductive material such as Al, Cu and/or Au.

### Gate Interconnect

The structure of the first gate interconnect 40 and the second gate interconnect 50 will be described in detail with reference to FIGS. 7 and 8.

As shown in FIG. 7, the first gate interconnect 40 includes a first interconnect portion 41, a second interconnect portion 42, a third interconnect portion 43, a fourth interconnect portion 44, and a joint portion 45. In the example shown in FIG. 7, the first interconnect portion 41, the second interconnect portion 42, the third interconnect portion 43, the fourth interconnect portion 44, and the joint portion 45 are integrated with each other.

The first interconnect portion 41 and the second interconnect portion 42 are spaced apart from each other in the X-direction. The joint portion 45 joins the first interconnect portion 41 and the second interconnect portion 42. The first interconnect portion 41 and the second interconnect portion 42 extend in the Y-direction in plan view. In the example shown in FIG. 7, the first interconnect portion 41 and the second interconnect portion 42 extend from the joint portion 45 in the Y-direction. In an example, a length LY1 of the first interconnect portion 41 in the Y-direction is equal to a length LY2 of the second interconnect portion 42 in the Y-direction. In an example, a width W1 of the first interconnect portion 41 is equal to a width W2 of the second interconnect portion 42. In an example, the width W1 of the first interconnect portion 41 and the width W2 of the second interconnect portion 42 are each smaller than a width W5 of the first connection portion 33H of the third power interconnect 33. In an example, the width W1 of the first interconnect portion 41 and the width W2 of the second interconnect portion 42 are each smaller than a width of the joint portion 45 (dimension of the joint portion 45 in the X-direction).

The length LY1 of the first interconnect portion 41 in the Y-direction and the length LY2 of the second interconnect portion 42 in the Y-direction are each greater than a distance DX1 between the first interconnect portion 41 and the second interconnect portion 42 in the X-direction. The length LY1 of the first interconnect portion 41 in the Y-direction is greater than a length SY1 of the first switching element 61A in the Y-direction. The length LY2 of the second interconnect portion 42 in the Y-direction is greater than a length SY2 of the second switching element 62A in the Y-direction.

Each of the first interconnect portion 41 and the second interconnect portion 42 includes a part located between the first switching element 61A and the second switching element 62A in the X-direction. The first interconnect portion 41 is arranged toward the first switching element 61A with respect to the second interconnect portion 42. The second interconnect portion 42 is arranged toward the second switching element 62A with respect to the first interconnect portion 41.

The first interconnect portion 41 includes a distal part 41A distant from the joint portion 45 in the Y-direction. The distal part 41A of the first interconnect portion 41 is located at one of the two ends of the first interconnect portion 41 in the Y-direction that is closer to the third substrate side surface 25. The second interconnect portion 42 includes a distal part 42A distant from the joint portion 45 in the Y-direction. The distal part 42A of the second interconnect portion 42 is located at one of the two ends of the second interconnect portion 42 in the Y-direction that is closer to the third substrate side surface 25. The distal part 41A of the first interconnect portion 41 and the distal part 42A of the second interconnect portion 42 are located at the same position in the Y-direction. In plan view, the distal part 41A of the first interconnect portion 41 and the distal part 42A of the second interconnect portion 42 are located at the same position as the first gate electrode G1 of the first switching element 61A and the second gate electrode G2 of the second switching element 62A in the Y-direction. The distal part 41A of the first interconnect portion 41 and the distal part 42A of the second interconnect portion 42 are arranged in the recess 31F formed in the bottom of the recess 31C in the element mount 31B of the first power interconnect 31 in plan view.

As shown in FIG. 7, a width of the distal part 41A of the first interconnect portion 41 is greater than the width W1 of the first interconnect portion 41. The width W1 of the first interconnect portion 41 refers to the width of a part of the first interconnect portion 41 differing from the distal part 41A. Therefore, the width of the distal part 41A of the first interconnect portion 41 is greater than the width W1 of a part of the first interconnect portion 41 located closer to the joint portion 45 than the distal part 41A is. Also, a width of the distal part 42A of the second interconnect portion 42 is greater than the width W2 of the second interconnect portion 42. The width W2 of the second interconnect portion 42 refers to the width of a part of the second interconnect portion 42 differing from the distal part 42A. Therefore, the width of the distal part 42A of the second interconnect portion 42 is greater than the width W2 of a part of the second interconnect portion 42 located closer to the joint portion 45 than the distal part 42A is. The distal part 41A of the first interconnect portion 41 is arranged so that the width is increased toward the first switching element 61A from where the first interconnect portion 41 has the width W1. The distal part 42A of the second interconnect portion 42 is arranged so that the width is increased toward the second switching element 62A from where the second interconnect portion 42 has the width W2.

The first gate connection member 71A is connected to the distal part 41A of the first interconnect portion 41. The second gate connection member 72A is connected to the distal part 42A of the second interconnect portion 42. Thus, the first gate connection member 71A and the second gate connection member 72A extend in the X-direction in plan view.

The third interconnect portion 43 and the fourth interconnect portion 44 are spaced apart from each other in the X-direction. The joint portion 45 joins the third interconnect portion 43 and the fourth interconnect portion 44. The third interconnect portion 43 and the fourth interconnect portion 44 extend in the Y-direction in plan view. In the example shown in FIG. 7, the third interconnect portion 43 and the fourth interconnect portion 44 extend from the joint portion 45 in the Y-direction. The third interconnect portion 43 and the fourth interconnect portion 44 are spaced apart from the first interconnect portion 41 and the second interconnect portion 42 in the Y-direction. The joint portion 45 is located between the first interconnect portion 41 and the third interconnect portion 43 in the Y-direction and between the second interconnect portion 42 and the fourth interconnect portion 44 in the Y-direction. The third interconnect portion 43 and the fourth interconnect portion 44 are located closer to the fourth substrate side surface 26 (refer to FIG. 2) than the first interconnect portion 41 and the second interconnect portion 42 are.

In an example, a length LY3 of the third interconnect portion 43 in the Y-direction is equal to a length LY4 of the fourth interconnect portion 44 in the Y-direction. In an example, a width W3 of the third interconnect portion 43 is equal to a width W4 of the fourth interconnect portion 44. In an example, the width W3 of the third interconnect portion 43 and the width W4 of the fourth interconnect portion 44 are each smaller than the width W5 of the first connection portion 33H of the third power interconnect 33. In an example, the width W3 of the third interconnect portion 43 and the width W4 of the fourth interconnect portion 44 are each smaller than the width of the joint portion 45.

In an example, the length LY3 of the third interconnect portion 43 in the Y-direction is equal to the length LY1 of the first interconnect portion 41 in the Y-direction. The length LY4 of the fourth interconnect portion 44 in the Y-direction is equal to the length LY2 of the second interconnect portion 42 in the Y-direction. In the example shown in FIG. 7, the lengths LY1 to LY4 of the first to fourth interconnect portions 41 to 44 in the Y-direction are equal to each other.

The length LY3 of the third interconnect portion 43 in the Y-direction and the length LY4 of the fourth interconnect portion 44 in the Y-direction are each greater than a distance DX2 between the third interconnect portion 43 and the fourth interconnect portion 44 in the X-direction. The distance DX2 is equal to the distance DX1 between the first interconnect portion 41 and the second interconnect portion 42 in the X-direction. The length LY3 of the third interconnect portion 43 in the Y-direction is greater than a length SY3 of the third switching element 63A in the Y-direction. The length LY4 of the fourth interconnect portion 44 in the Y-direction is greater than a length SY4 of the fourth switching element 64A in the Y-direction. In the example shown in FIG. 7, since the first to fourth switching elements 61A to 64A are equal in size, the lengths SY1 to SY4 are equal to each other. The width W3 of the third interconnect portion 43 is equal to the width W1 of the first interconnect portion 41. The width W4 of the fourth interconnect portion 44 is equal to the width W2 of the second interconnect portion 42. Therefore, the widths W1 to W4 of the first to fourth interconnect portions 41 to 44 are equal to each other.

Each of the third interconnect portion 43 and the fourth interconnect portion 44 includes a part located between the third switching element 63A and the fourth switching element 64A in the X-direction. The third interconnect portion 43 is located toward the third switching element 63A with respect to the fourth interconnect portion 44. The fourth interconnect portion 44 is located toward the fourth switching element 64A with respect to the third interconnect portion 43.

The third interconnect portion 43 includes a distal part 43A distant from the joint portion 45 in the Y-direction. The distal part 43A of the third interconnect portion 43 is located at one of the two ends of the third interconnect portion 43 in the Y-direction that is closer to the fourth substrate side surface 26. The fourth interconnect portion 44 includes a distal part 44A distant from the joint portion 45 in the Y-direction. The distal part 44A of the fourth interconnect portion 44 is located at one of the two ends of the fourth interconnect portion 44 in the Y-direction that is closer to the fourth substrate side surface 26 (refer to FIG. 2). The distal part 43A of the third interconnect portion 43 and the distal part 44A of the fourth interconnect portion 44 are located at the same position in the Y-direction. In plan view, the distal part 43A of the third interconnect portion 43 and the distal part 44A of the fourth interconnect portion 44 are located at the same position as the third gate electrode G3 of the third switching element 63A and the fourth gate electrode G4 of the fourth switching element 64A in the Y-direction.

As shown in FIG. 7, a width of the distal part 43A of the third interconnect portion 43 is greater the width W3 of the third interconnect portion 43. The width W3 of the third interconnect portion 43 refers to the width of a part of the third interconnect portion 43 differing from the distal part 43A. Therefore, the width of the distal part 43A of the third interconnect portion 43 is greater than the width W3 of a part of the third interconnect portion 43 located closer to the joint portion 45 than the distal part 43A is. Also, a width of the distal part 44A of the fourth interconnect portion 44 is greater than the width W4 of the fourth interconnect portion 44. The width W4 of the fourth interconnect portion 44 refers to the width of a part of the fourth interconnect portion 44 differing from the distal part 44A. Therefore, the width of the distal part 44A of the fourth interconnect portion 44 is greater than the width W4 of a part of the fourth interconnect portion 44 located closer to the joint portion 45 than the distal part 44A is. The distal part 43A of the third interconnect portion 43 is arranged so that the width is increased from where the third interconnect portion 43 has the width W3 toward the third switching element 63A. The distal part 44A of the fourth interconnect portion 44 is arranged so that the width is increased toward the fourth switching element 64A from where the fourth interconnect portion 44 has the width W4.

The third gate connection member 73A is connected to the distal part 43A of the third interconnect portion 43. The fourth gate connection member 74A is connected to the distal part 44A of the fourth interconnect portion 44. Thus, the third gate connection member 73A and the fourth gate connection member 74A extend in the X-direction in plan view.

The joint portion 45 joins the first interconnect portion 41 and the second interconnect portion 42. In other words, the first interconnect portion 41 and the second interconnect portion 42 extend from the joint portion 45 toward the third substrate side surface 25. The joint portion 45 joins the third interconnect portion 43 and the fourth interconnect portion 44. In other words, the third interconnect portion 43 and the fourth interconnect portion 44 extend from the joint portion 45 toward the fourth substrate side surface 26. The first gate terminal 14 is connected to the joint portion 45. The first gate terminal 14 is arranged, for example, at the center of the joint portion 45 in the X-direction and the Y-direction.

In the example shown in FIG. 7, the first interconnect portion 41 and the third interconnect portion 43 are located at the same position in the X-direction. The second interconnect portion 42 and the fourth interconnect portion 44 are located at the same position in the X-direction. The first interconnect portion 41 and the third interconnect portion 43 are arranged closer to the center of the joint portion 45 in the X-direction than an end of the joint portion 45 located toward the first substrate side surface 23. The second interconnect portion 42 and the fourth interconnect portion 44 are arranged closer to the center of the joint portion 45 in the X-direction than an end of the joint portion 45 located toward the second substrate side surface 24. The distance between the first interconnect portion 41 and the center of the first gate terminal 14 in the X-direction and the distance between the third interconnect portion 43 and the center of the first gate terminal 14 in the X-direction are equal to the distance between the second interconnect portion 42 and the center of the first gate terminal 14 in the X-direction and the distance between the fourth interconnect portion 44 and the center of the first gate terminal 14 in the X-direction.

In the example shown in FIG. 7, the length LY1 of the first interconnect portion 41 in the Y-direction is greater than a distance GE1 between the first gate electrode G1 of the first switching element 61A and the distal part 41A of the first interconnect portion 41 in the X-direction. The length LY1 of the first interconnect portion 41 in the Y-direction is greater than the length of the first gate connection member 71A in plan view (length in which the first gate connection member 71A extends).

The length LY2 of the second interconnect portion 42 in the Y-direction is greater than a distance GE2 between the second gate electrode G2 of the second switching element 62A and the distal part 42A of the second interconnect portion 42 in the X-direction. The length LY2 of the second interconnect portion 42 in the Y-direction is greater than the length of the second gate connection member 72A in plan view (length in which the second gate connection member 72A extends).

The length LY3 of the third interconnect portion 43 in the Y-direction is greater than a distance GE3 between the third gate electrode G3 of the third switching element 63A and the distal part 43A of the third interconnect portion 43 in the X-direction. The length LY3 of the third interconnect portion 43 in the Y-direction is greater than the length of the third gate connection member 73A in plan view (length in which the third gate connection member 73A extends).

The length LY4 of the fourth interconnect portion 44 in the Y-direction is greater than a distance GE4 between the fourth gate electrode G4 of the fourth switching element 64A and the distal part 44A of the fourth interconnect portion 44 in the X-direction. The length LY4 of the fourth interconnect portion 44 in the Y-direction is greater than the length of the fourth gate connection member 74A in plan view (length in which the fourth gate connection member 74A extends). In the example shown in FIG. 7, the distances GE1 to GE4 are equal to each other. The first to fourth gate connection members 71A to 74A are equal in length.

In the arrangement of the first to fourth interconnect portions 41 to 44 and the first gate terminal 14 described above, the distance between the first interconnect portion 41 and the first gate terminal 14, the distance between the second interconnect portion 42 and the first gate terminal 14, the distance between the third interconnect portion 43 and the first gate terminal 14, and the distance between the fourth interconnect portion 44 and the first gate terminal 14 are equal to each other in plan view. That is, in plan view, the current path between the first gate electrode G1 of the first switching element 61A and the first gate terminal 14, the current path between the second gate electrode G2 of the second switching element 62A and the first gate terminal 14, the current path between the third gate electrode G3 of the third switching element 63A and the first gate terminal 14, and the current path between the fourth gate electrode G4 of the fourth switching element 64A and the first gate terminal 14 are equal in length to each other.

In the example shown in FIG. 7, the sum of the length LY1 of the first interconnect portion 41 in the Y-direction, the length of the first gate connection member 71A in plan view (length in which the first gate connection member 71A extends), the length of the second gate connection member 72A in plan view (length in which the second gate connection member 72A extends), and the length LY2 of the second interconnect portion 42 in the Y-direction is greater than a first inter-gate distance GD1 between the first gate electrode G1 of the first switching element 61A and the second gate electrode G2 of the second switching element 62A in plan view. That is, in plan view, the length of the current path between the first gate electrode G1 and the second gate electrode G2 is greater than the first inter-gate distance GD1.

The sum of the length LY3 of the third interconnect portion 43 in the Y-direction, the length of the third gate connection member 73A in plan view (length in which the third gate connection member 73A extends), the length of the fourth gate connection member 74A in plan view (length in which the fourth gate connection member 74A extends), and the length LY4 of the fourth interconnect portion 44 in the Y-direction is greater than a second inter-gate distance GD2, that is, the distance between the third gate electrode G3 of the third switching element 63A and the fourth gate electrode G4 of the fourth switching element 64A in plan view. That is, the length of the current path between the third gate electrode G3 and the fourth gate electrode G4 in plan view is greater than the second inter-gate distance GD2.

The sum of the length LY1 of the first interconnect portion 41 in the Y-direction, the length of the first gate connection member 71A in plan view, the length of the joint portion 45 in the Y-direction, the length LY3 of the third interconnect portion 43 in the Y-direction, and the length of the third gate connection member 73A in plan view (length in which the third gate connection member 73A extends) is greater than a third inter-gate distance GD3, that is, the distance between the first gate electrode G1 of the first switching element 61A and the third gate electrode G3 of the third switching element 63A in plan view. That is, the length of the current path between the first gate electrode G1 and the third gate electrode G3 in plan view is greater than the third inter-gate distance GD3.

The sum of the length LY2 of the second interconnect portion 42 in the Y-direction, the length of the second gate connection member 72A in the Y-direction, the length of the joint portion 45 in the Y-direction, the length LY4 of the fourth interconnect portion 44 in the Y-direction, and the length of the fourth gate connection member 74A in plan view (length in which the fourth gate connection member 74A extends) is greater than a fourth inter-gate distance GD4, that is, the distance between the second gate electrode G2 of the second switching element 62A and the fourth gate electrode G4 of the fourth switching element 64A in plan view. Thus, the length of the current path between the second gate electrode G2 and the fourth gate electrode G4 in plan view is greater than the fourth inter-gate distance GD4.

In the example shown in FIG. 7, the third inter-gate distance GD3 is equal to the fourth inter-gate distance GD4. The third inter-gate distance GD3 and the fourth inter-gate distance GD4 are greater than the first inter-gate distance GD1 and the second inter-gate distance GD2. The first to fourth inter-gate distances GD1 to GD4 may be changed in any manner in accordance with changes in the arrangement of the first to fourth switching elements 61A to 64A.

As shown in FIG. 9, the first gate interconnect 40 includes side surfaces.

The first interconnect portion 41 of the first gate interconnect 40 includes a first side surface FA1, a second side surface FA2, and a third side surface FA3. The first side surface FA1 and the second side surface FA2 extend in the Y-direction. The first side surface FA1 and the second side surface FA2 are spaced apart from each other in the X-direction. The first side surface FA1 and the second side surface FA2 are connected to the joint portion 45. The third side surface FA3 extends in the X-direction. The third side surface FA3 defines a distal surface of the distal part 41A of the first interconnect portion 41. In the example shown in FIG. 9, the first side surface FA1 is greater than the second side surface FA2 in length in the Y-direction. The first side surface FA1 is connected to the third side surface FA3.

The first interconnect portion 41 includes a fourth side surface FA4 and a fifth side surface FA5 that define the distal part 41A. The fourth side surface FA4 is connected to the second side surface FA2 and extends in the X-direction. The fifth side surface FA5 connects the fourth side surface FA4 and the third side surface FA3. The fifth side surface FA5 extends in the Y-direction.

The second interconnect portion 42 includes a first side surface FB1, a second side surface FB2, a third side surface FB3, a fourth side surface FB4, and a fifth side surface FB5. The first to fifth side surfaces FB1 to FB5 have the same structure as the first to fifth side surfaces FA1 to FA5 of the first interconnect portion 41.

The third interconnect portion 43 includes a first side surface FC1, a second side surface FC2, a third side surface FC3, a fourth side surface FC4, and a fifth side surface FC5. The first to fifth side surfaces FC1 to FC5 have the same structure as the first to fifth side surfaces FA1 to FA5 of the first interconnect portion 41.

The fourth interconnect portion 44 includes a first side surface FD1, a second side surface FD2, a third side surface FD3, a fourth side surface FD4, and a fifth side surface FD5. The first to fifth side surfaces FD1 to FD5 have the same structure as the first to fifth side surfaces FA1 to FA5 of the first interconnect portion 41.

The joint portion 45 includes a first joint side surface FP1 and a second joint side surface FP2. The first joint side surface FP1 joins the first interconnect portion 41 and the second interconnect portion 42. More specifically, the first joint side surface FP1 joins the first side surface FA1 of the first interconnect portion 41 and the first side surface FB1 of the second interconnect portion 42. The second joint side surface FP2 joins the third interconnect portion 43 and the fourth interconnect portion 44. More specifically, the second joint side surface FP2 joins the first side surface FC1 of the third interconnect portion 43 and the first side surface FD1 of the fourth interconnect portion 44. The first joint side surface FP1 and the second joint side surface FP2 extend in the X-direction.

As shown in FIG. 8, in the same manner as the first gate interconnect 40, the second gate interconnect 50 includes a first interconnect portion 51, a second interconnect portion 52, a third interconnect portion 53, a fourth interconnect portion 54, and a joint portion 55. The second gate interconnect 50 is identical in shape to the first gate interconnect 40. Hence, the lengths and widths of the first to fourth interconnect portions 51 to 54 are equal to the lengths LY1 to LY4 and the widths W1 to W4 of the first to fourth interconnect portions 41 to 44 (refer to FIG. 7). In FIG. 8, the lengths of the first to fourth interconnect portions 51 to 54 are indicated by lengths LY1 to LY4 in the same manner as the first to fourth interconnect portions 41 to 44. The widths of the first to fourth interconnect portions 51 to 54 are indicated by widths W1 to W4 in the same manner as the first to fourth interconnect portions 41 to 44. Although not shown in FIG. 8, the second gate interconnect 50 includes side surfaces in the same manner as the first gate interconnect 40.

The distance between the first interconnect portion 51 and the second interconnect portion 52 in the X-direction is equal to the distance DX1 between the first interconnect portion 41 and the second interconnect portion 42 in the X-direction. Hence, in FIG. 8, the distance between the first interconnect portion 51 and the second interconnect portion 52 in the X-direction is indicated by the distance DX1. The distance between the third interconnect portion 53 and the fourth interconnect portion 54 in the X-direction is equal to the distance DX2 between the third interconnect portion 43 and the fourth interconnect portion 44 in the X-direction. Hence, in FIG. 8, the distance between the third interconnect portion 53 and the fourth interconnect portion 54 in the X-direction is indicated by the distance DX2.

The first to fourth switching elements 61B to 64B are identical in size to the first to fourth switching elements 61A to 64A. Hence, in FIG. 8, the lengths of the first to fourth switching elements 61B to 64B in the Y-direction are indicated by the lengths SY1 to SY4 in the same manner as the first to fourth switching elements 61A to 64A. The relationship of the lengths LY1 to LY4 of the first to fourth interconnect portions 51 to 54 in the Y-direction with the lengths SY1 to SY4 of the first to fourth switching elements 61B to 64B in the Y-direction is the same as the relationship of the lengths LY1 to LY4 of the first to fourth interconnect portions 41 to 44 in the Y-direction with the lengths SY1 to SY4 of the first to fourth switching elements 61A to 64A.

The first gate connection member 71B connects the first gate electrode G1 of the first switching element 61B and a distal part 51A of the first interconnect portion 51. The second gate connection member 72B connects the second gate electrode G2 of the second switching element 62B and a distal part 52A of the second interconnect portion 52. The third gate connection member 73B connects the third gate electrode G3 of the third switching element 63B and a distal part 53A of the third interconnect portion 53. The fourth gate connection member 74B connects the fourth gate electrode G4 of the fourth switching element 64B and a distal part 54A of the fourth interconnect portion 54.

As shown in FIG. 8, the first to fourth interconnect portions 51 to 54 and the second gate terminal 15 are arranged in the same manner as the first to fourth interconnect portions 41 to 44 and the first gate terminal 14 shown in FIG. 7. Hence, in plan view, the distance between the first interconnect portion 51 and the second gate terminal 15, the distance between the second interconnect portion 52 and the second gate terminal 15, the distance between the third interconnect portion 53 and the second gate terminal 15, and the distance between the fourth interconnect portion 54 and the second gate terminal 15 are equal to each other. That is, in plan view, the current path between the first gate electrode G1 of the first switching element 61B and the second gate terminal 15, the current path between the second gate electrode G2 of the second switching element 62B and the second gate terminal 15, the current path between the third gate electrode G3 of the third switching element 63B and the second gate terminal 15, and the current path between the fourth gate electrode G4 of the fourth switching element 64B and the second gate terminal 15 are equal in length to each other.

The lengths LY1 to LY4 of the first to fourth interconnect portions 41 to 44 and 51 to 54 and the widths W1 to W4 of the first to fourth interconnect portions 41 to 44 and 51 to 54 may be changed in any manner.

At least one of the lengths LY1 to LY4 of the first to fourth interconnect portions 41 to 44 may differ from the others. At least one of the lengths LY1 to LY4 of the first to fourth interconnect portions 51 to 54 may differ from the others. At least one of the widths W1 to W4 of the first to fourth interconnect portions 41 to 44 may differ from the others. At least one of the widths W1 to W4 of the first to fourth interconnect portions 51 to 54 may differ from the others.

The length LY1 of the first interconnect portion 41 may be less than or equal to the distance GE1 between the first gate electrode G1 of the first switching element 61A and the distal part 41A of the first interconnect portion 41 in the X-direction. The length LY2 of the second interconnect portion 42 may be less than or equal to the distance GE2 between the second gate electrode G2 of the second switching element 62A and the distal part 42A of the second interconnect portion 42 in the X-direction. The length LY3 of the third interconnect portion 43 may be less than or equal to the distance GE3 between the third gate electrode G3 of the third switching element 63A and the distal part 43A of the third interconnect portion 43 in the X-direction. The length LY4 of the fourth interconnect portion 44 may be less than or equal to the distance GE4 between the fourth gate electrode G4 of the fourth switching element 64A and the distal part 44A of the fourth interconnect portion 44 in the X-direction.

The length LY1 of the first interconnect portion 51 may be less than or equal to the distance GE1 between the first gate electrode G1 of the first switching element 61B and the distal part 51A of the first interconnect portion 51 in the X-direction. The length LY2 of the second interconnect portion 52 may be less than or equal to the distance GE2 between the second gate electrode G2 of the second switching element 62B and the distal part 52A of the second interconnect portion 52 in the X-direction. The length LY3 of the third interconnect portion 53 may be less than or equal to the distance GE3 between the third gate electrode G3 of the third switching element 63B and the distal part 53A of the third interconnect portion 53 in the X-direction. The length LY4 of the fourth interconnect portion 54 may be less than or equal to the distance GE4 between the fourth gate electrode G4 of the fourth switching element 64B and the distal part 54A of the fourth interconnect portion 54 in the X-direction.

### Circuit Configuration of Semiconductor Device

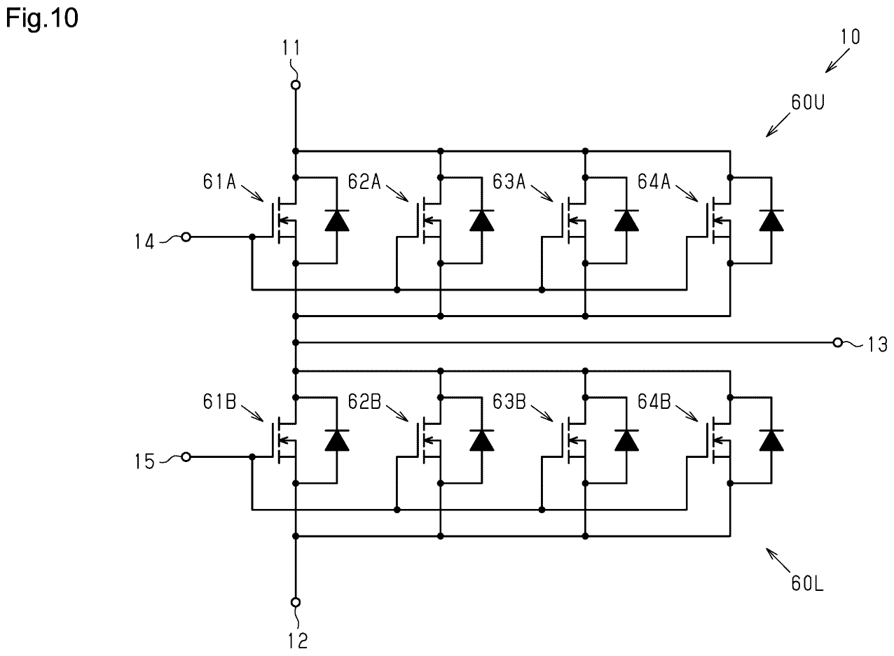

The circuit configuration of the semiconductor device 10 will now be described with reference to FIG. 10.

As shown in FIG. 10, multiple switching elements 60U and multiple switching elements 60L are connected in series to form an inverter circuit. In the switching elements 60U, the first to fourth switching elements 61A to 64A are connected in parallel. That is, the first to fourth drain electrodes D1 to D4 of the first to fourth switching elements 61A to 64A are electrically connected to each other, and the first to fourth source electrodes S1 to S4 of the first to fourth switching elements 61A to 64A are electrically connected to each other. Also, in the switching elements 60L, the first to fourth switching elements 61B to 64B are also connected in parallel.

The first to fourth drain electrodes D1 to D4 of the first to fourth switching elements 61A to 64A are electrically connected to the first power terminal 11. The first to fourth source electrodes S1 to S4 of the first to fourth switching elements 61B to 64B are electrically connected to the second power terminal 12. The first to fourth source electrodes S1 to S4 of the first to fourth switching elements 61A to 64A and the first to fourth drain electrodes D1 to D4 of the first to fourth switching elements 61B to 64B are electrically connected to each other and to the output terminal 13.

The first to fourth gate electrodes G1 to G4 of the first to fourth switching elements 61A to 64A are electrically connected to each other and to the first gate terminal 14. The first to fourth gate electrodes G1 to G4 of the first to fourth switching elements 61B to 64B are electrically connected to each other and to the second gate terminal 15.

In the semiconductor device 10, the first to fourth switching elements 61A to 64A and the first to fourth switching elements 61B to 64B are driven in a complementary manner in accordance with a gate signal provided from a gate driver (not shown) to the first gate terminal 14 and the second gate terminal 15.

### Operation of Embodiment

The operation of the semiconductor device 10 in accordance with the first embodiment will now be described.

For example, during repetitive simultaneous activation and simultaneous deactivation of the switching elements 60U connected in parallel, when the switching elements 60U are switched off, the gate-source voltage Vgs may oscillate due to a gate stray inductance of the current path (second power interconnect 32) in the semiconductor device 10. This behavior is referred to as oscillations. The oscillations may be mitigated by increasing the gate stray inductance between the switching elements 60U.

In this regard, in the semiconductor device 10 of the first embodiment, the current paths between the first to fourth gate electrodes G1 to G4 are increased in length to increase the gate stray inductance of the switching elements 60U between the first to fourth switching elements 61A to 64A and the first to fourth gate electrodes G1 to G4. More specifically, the first gate interconnect 40 includes first to fourth interconnect portions 41 to 44 extending in the Y-direction and a joint portion 45 joining the first to fourth interconnect portions 41 to 44. The first to fourth gate connection members 71A to 74A separately connect the first to fourth gate electrodes G1 to G4 of the first to fourth switching elements 61A to 64A to the distal parts 41A to 44A of the first to fourth interconnect portions 41 to 44. For example, the current path between the first gate electrode G1 and the second gate electrode G2 is formed of the first gate connection member 71A, the first interconnect portion 41, the joint portion 45, the second interconnect portion 42, and the second gate connection member 72A. Thus, the current path between the first gate electrode G1 and the second gate electrode G2 is increased in length as compared to a structure in which, for example, the first gate electrode G1 and the second gate electrode G2 are directly connected to each other by a gate connection member that extends in the X-direction in plan view. This increases the gate stray inductance between the first gate electrode G1 of the first switching element 61A and the second gate electrode G2 of the second switching element 62A. In the same manner, the current path between the third gate electrode G3 of the third switching element 63A and the fourth gate electrode G4 of the fourth switching element 64A may be increased in length. This increases the gate stray inductance of the current path.

### Advantages of Embodiment

The semiconductor device 10 of the first embodiment has the advantages described below.
(1-1) The semiconductor device 10 includes the first switching element 61A including the first gate electrode G1, the second switching element 62A including the second gate electrode G2, the second switching element 62A being spaced apart from the first switching element 61A in the X-direction and connected in parallel to the first switching element 61A, the first gate interconnect 40 arranged between the first switching element 61A and the second switching element 62A in the X-direction, the first gate connection member 71A connecting the first gate electrode G1 and the first gate interconnect 40, and the second gate connection member 72A connecting the second gate electrode G2 and the first gate interconnect 40. The first gate interconnect 40 includes the first interconnect portion 41 extending in the Y-direction in plan view, the second interconnect portion 42 spaced apart from the first interconnect portion 41 toward the second switching element 62A in the X-direction and extending in the Y-direction in plan view, and the joint portion 45 joining the first interconnect portion 41 and the second interconnect portion 42. The first gate connection member 71A is connected to a part of the first interconnect portion 41 distant from the joint portion 45 in the Y-direction. The second gate connection member 72A is connected to a part of the second interconnect portion 42 distant from the joint portion 45 in the Y-direction.

This structure increases the length of the current path between the first gate electrode G1 and the second gate electrode G2. This increases the gate stray inductance, thereby limiting occurrence of the oscillations when the first switching element 61A and the second switching element 62A are simultaneously activated and simultaneously deactivated.
(1-2) The first gate connection member 71A is connected to the distal part 41A of the first interconnect portion 41, which is distant from the joint portion 45 in the Y-direction. The second gate connection member 72A is connected to the distal part 42A of the second interconnect portion 42, which is distant from the joint portion 45 in the Y-direction.

This structure further increases the length of the current path between the first gate electrode G1 and the second gate electrode G2. As a result, the gate stray inductance is further increased, and occurrence of the oscillations is further limited.
(1-3) The length LY1 of the first interconnect portion 41 in the Y-direction and the length LY2 of the second interconnect portion 42 in the Y-direction are each greater than the distance DX1 between the first interconnect portion 41 and the second interconnect portion 42 in the X-direction.

This structure increases the length of the current path between the first gate electrode G1 and the second gate electrode G2 while limiting enlargement of the semiconductor device 10 in the X-direction. Thus, enlargement of the semiconductor device 10 and occurrence of the oscillations are both limited.
(1-4) The length LY1 of the first interconnect portion 41 in the Y-direction is greater than the length SY1 of the first switching element 61A in the Y-direction. The length LY2 of the second interconnect portion 42 in the Y-direction is greater than a length SY2 of the second switching element 62A in the Y-direction.

This structure increases the length of the current path between the first gate electrode G1 and the second gate electrode G2 as compared to a structure in which the length LY1 of the first interconnect portion 41 in the Y-direction is less than or equal to the length SY1 of the first switching element 61A in the Y-direction and the length LY2 of the second interconnect portion 42 in the Y-direction is less than or equal to the length SY2 of the second switching element 62A. This increases the gate stray inductance, thereby limiting occurrence of the oscillations when the first switching element 61A and the second switching element 62A are simultaneously activated and simultaneously deactivated.
(1-5) The sum of the length LY1 of the first interconnect portion 41 in the Y-direction, the length of the first gate connection member 71A in plan view, the length LY2 of the second interconnect portion 42 in the Y-direction, and the length of the second gate connection member 72A in plan view is greater than the first inter-gate distance GD1, which is the distance between the first gate electrode G1 and the second gate electrode G2 in plan view.

With this structure, the current path between the first gate electrode G1 and the second gate electrode G2 is increased in length as compared to, for example, a structure in which the first gate electrode G1 and the second gate electrode G2 are directly connected by the first gate connection member 71A. This increases the gate stray inductance, thereby limiting occurrence of the oscillations when the first switching element 61A and the second switching element 62A are simultaneously activated and simultaneously deactivated.
(1-6) The semiconductor device 10 includes the first gate terminal 14 electrically connected to the joint portion 45. The first interconnect portion 41 and the second interconnect portion 42 extend from the joint portion 45 in the Y-direction. The length LY1 of the first interconnect portion 41 in the Y-direction is equal to the length LY2 of the second interconnect portion 42 in the Y-direction.

This structure reduces variations in the length of the current path between the first gate terminal 14 and the first gate electrode G1 and the length of the current path between the first gate terminal 14 and the second gate electrode G2. This reduces deviation in the timing of activating and deactivating the first switching element 61A and the second switching element 62A based on a gate signal provided to the first gate terminal 14.
(1-7) The semiconductor device 10 includes the third switching element 63A including the third gate electrode G3, the fourth switching element 64A including the fourth gate electrode G4, the third gate connection member 73A connecting the third gate electrode G3 and the first gate interconnect 40, and the fourth gate connection member 74A connecting the fourth gate electrode G4 and the first gate interconnect 40. The third switching element 63A is located at a position spaced apart from the first switching element 61A in the Y-direction and toward the first switching element 61A in the X-direction with respect to the first gate interconnect 40 and is connected in parallel to the first switching element 61A and the second switching element 62A. The fourth switching element 64A is located at a position spaced apart from the second switching element 62A in the Y-direction and toward the second switching element 62A with respect to the first gate interconnect 40 in the X-direction and connected in parallel to the first switching element 61A, the second switching element 62A, and the third switching element 63A. The first gate interconnect 40 includes the third interconnect portion 43 spaced apart from the first interconnect portion 41 in the Y-direction and extending in the Y-direction and the fourth interconnect portion 44 spaced apart from the second interconnect portion 42 in the Y-direction and extending in the Y-direction. The joint portion 45 is arranged between the first interconnect portion 41 and the third interconnect portion 43 in the Y-direction and between the second interconnect portion 42 and the fourth interconnect portion 44 in the Y-direction and connects the first interconnect portion 41, the second interconnect portion 42, the third interconnect portion 43, and the fourth interconnect portion 44. The third gate connection member 73A is connected to a part of the third interconnect portion 43 distant from the joint portion 45 in the Y-direction. The fourth gate connection member 74A is connected to a part of the fourth interconnect portion 44 distant from the joint portion 45 in the Y-direction.

This structure increases the length of the current path between the third gate electrode G3 and the fourth gate electrode G4. This increases the gate stray inductance, thereby limiting occurrence of the oscillations when the third switching element 63A and the fourth switching element 64A are simultaneously activated and simultaneously deactivated.
(1-8) The third gate connection member 73A is connected to the distal part 43A of the third interconnect portion 43, which is distant from the joint portion 45 in the Y-direction. The fourth gate connection member 74A is connected to the distal part 44A of the fourth interconnect portion 44, which is distant from the joint portion 45 in the Y-direction.

This structure further increases the length of the current path between the third gate electrode G3 and the fourth gate electrode G4. As a result, the gate stray inductance is further increased, and occurrence of the oscillations is further limited.
(1-9) The length LY3 of the third interconnect portion 43 in the Y-direction and the length LY4 of the fourth interconnect portion 44 in the Y-direction are each greater than the distance DX2 between the third interconnect portion 43 and the fourth interconnect portion 44 in the X-direction.

This structure increases the length of the current path between the third gate electrode G3 and the fourth gate electrode G4 while limiting enlargement of the semiconductor device 10 in the X-direction. Thus, enlargement of the semiconductor device 10 and occurrence of the oscillations are both limited.
(1-10) The length LY3 of the third interconnect portion 43 in the Y-direction is greater than the length SY3 of the third switching element 63A in the Y-direction. The length LY4 of the fourth interconnect portion 44 in the Y-direction is greater than the length SY4 of the fourth switching element 64A in the Y-direction.

This structure increases the length of the current path between the third gate electrode G3 and the fourth gate electrode G4 as compared to a structure in which the length LY3 of the third interconnect portion 43 in the Y-direction is less than or equal to the length SY3 of the third switching element 63A in the Y-direction and the length LY4 of the fourth interconnect portion 44 in the Y-direction is less than or equal to the length SY4 of the fourth switching element 64A in the Y-direction. This increases the gate stray inductance, thereby limiting occurrence of the oscillations when the third switching element 63A and the fourth switching element 64A are simultaneously activated and simultaneously deactivated.
(1-11) The sum of the length LY3 of the third interconnect portion 43 in the Y-direction, the length of the third gate connection member 73A in plan view, the length LY4 of the fourth interconnect portion 44 in the Y-direction, and the length of the fourth gate connection member 74A in plan view is greater than the second inter-gate distance GD2, which is the distance between the third gate electrode G3 and the fourth gate electrode G4 in plan view.

With this structure, the current path between the third gate electrode G3 and the fourth gate electrode G4 is increased in length as compared to, for example, a structure in which the third gate electrode G3 and the fourth gate electrode G4 are directly connected by the third gate connection member 73A. This increases the gate stray inductance, thereby limiting occurrence of the oscillations when the third switching element 63A and the fourth switching element 64A are simultaneously activated and simultaneously deactivated.
(1-12) The semiconductor device 10 includes the first gate terminal 14 electrically connected to the joint portion 45. The length LY3 of the third interconnect portion 43 in the Y-direction is equal to the length LY4 of the fourth interconnect portion 44 in the Y-direction.

This structure reduces or eliminates the difference in the length of the current path between the first gate terminal 14 and the third gate electrode G3 and the length of the current path between the first gate terminal 14 and the fourth gate electrode G4. This reduces deviation in the timing for activating and deactivating the third switching element 63A and the fourth switching element 64A based on a gate signal provided to the first gate terminal 14.
(1-13) The semiconductor device 10 includes the first gate terminal 14 electrically connected to the joint portion 45. The length LY3 of the third interconnect portion 43 in the Y-direction is equal to the length LY1 of the first interconnect portion 41 in the Y-direction. The length LY4 of the fourth interconnect portion 44 in the Y-direction is equal to the length LY2 of the second interconnect portion 42 in the Y-direction.

This structure reduces variations in the length of the current path between the first gate terminal 14 and the first gate electrode G1, the length of the current path between the first gate terminal 14 and the second gate electrode G2, the length of the current path between the first gate terminal 14 and the third gate electrode G3, and the length of the current path between the first gate terminal 14 and the fourth gate electrode G4. This reduces deviation in the timing for activating and deactivating the first to fourth switching elements 61A to 64A based on a gate signal provided to the first gate terminal 14.
(1-14) The second inter-gate distance GD2, which is the distance between the third gate electrode G3 of the third switching element 63A and the fourth gate electrode G4 of the fourth switching element 64A, is equal to the first inter-gate distance GD1, which is the distance between the first gate electrode G1 of the first switching element 61A and the second gate electrode G2 of the second switching element 62A in plan view.

This structure further reduces variations in the length of the current path between the first gate terminal 14 and the first gate electrode G1, the length of the current path between the first gate terminal 14 and the second gate electrode G2, the length of the current path between the first gate terminal 14 and the third gate electrode G3, and the length of the current path between the first gate terminal 14 and the fourth gate electrode G4.
(1-15) The sum of the length LY1 of the first interconnect portion 41 in the Y-direction, the length of the first gate connection member 71A in plan view, the length of the joint portion 45 in the Y-direction, the length LY3 of the third interconnect portion 43 in the Y-direction, and the length of the third gate connection member 73A in plan view is greater than the third inter-gate distance GD3, which is the distance between the first gate electrode G1 and the third gate electrode G3 in plan view.

With this structure, the current path between the first gate electrode G1 and the third gate electrode G3 is increased in length as compared to, for example, a structure in which the first gate electrode G1 and the third gate electrode G3 are directly connected by the third gate connection member 73A. This increases the gate stray inductance, thereby limiting occurrence of the oscillations when the first switching element 61A and the third switching element 63A are simultaneously activated and simultaneously deactivated.
(1-16) The sum of the length LY2 of the second interconnect portion 42 in the Y-direction, the length of the second gate connection member 72A in plan view, the length of the joint portion 45 in the Y-direction, the length LY4 of the fourth interconnect portion 44 in the Y-direction, and the length of the fourth gate connection member 74A in plan view is greater than the fourth inter-gate distance GD4, which is the distance between the second gate electrode G2 and the fourth gate electrode G4 in plan view.

With this structure, the current path between the second gate electrode G2 and the fourth gate electrode G4 is increased in length as compared to, for example, a structure in which the second gate electrode G2 and the fourth gate electrode G4 are directly connected by the fourth gate connection member 74A. This increases the gate stray inductance, thereby limiting occurrence of the oscillations when the second switching element 62A and the fourth switching element 64A are simultaneously activated and simultaneously deactivated.
(1-17) The widths W1 and W2 of the first interconnect portion 41 and the second interconnect portion 42 are each smaller than the width of the joint portion 45.

This structure increases the electrical resistance of the first interconnect portion 41 and the second interconnect portion 42, thereby limiting occurrence of the oscillations when the first switching element 61A and the second switching element 62A are simultaneously activated and simultaneously deactivated.
(1-18) The width W1 of the first interconnect portion 41, the width W2 of the second interconnect portion 42, the width W3 of the third interconnect portion 43, and the width W4 of the fourth interconnect portion 44 are each smaller than the width of the joint portion 45.

This structure increases the electrical resistance in the first to fourth interconnect portions 41 to 44, thereby limiting occurrence of the oscillations when the first to fourth switching elements 61A to 64A are simultaneously activated and simultaneously deactivated.
(1-19) The width of the distal part 41A of the first interconnect portion 41 is greater than the width W1 of a part of the first interconnect portion 41 located closer to the joint portion 45 than the distal part 41A is. The width of the distal part 42A of the second interconnect portion 42 is greater than the width W2 of a part of the second interconnect portion 42 located toward the joint portion 45 from the distal part 42A is.

With this structure, the first gate connection member 71A is readily connected to the distal part 41A of the first interconnect portion 41. Also, the second gate connection member 72A is readily connected to the distal part 42A of the second interconnect portion 42.
(1-20) The width of the distal part 43A of the third interconnect portion 43 is greater than the width W3 of a part of the third interconnect portion 43 located closer to the joint portion 45 than the distal part 43A is. The width of the distal part 44A of the fourth interconnect portion 44 is greater than the width W4 of a part of the fourth interconnect portion 44 located closer to the joint portion 45 than the distal part 44A is.

With this structure, the third gate connection member 73A is readily connected to the distal part 43A of the third interconnect portion 43. Also, the fourth gate connection member 74A is readily connected to the distal part 44A of the fourth interconnect portion 44.

### Second Embodiment

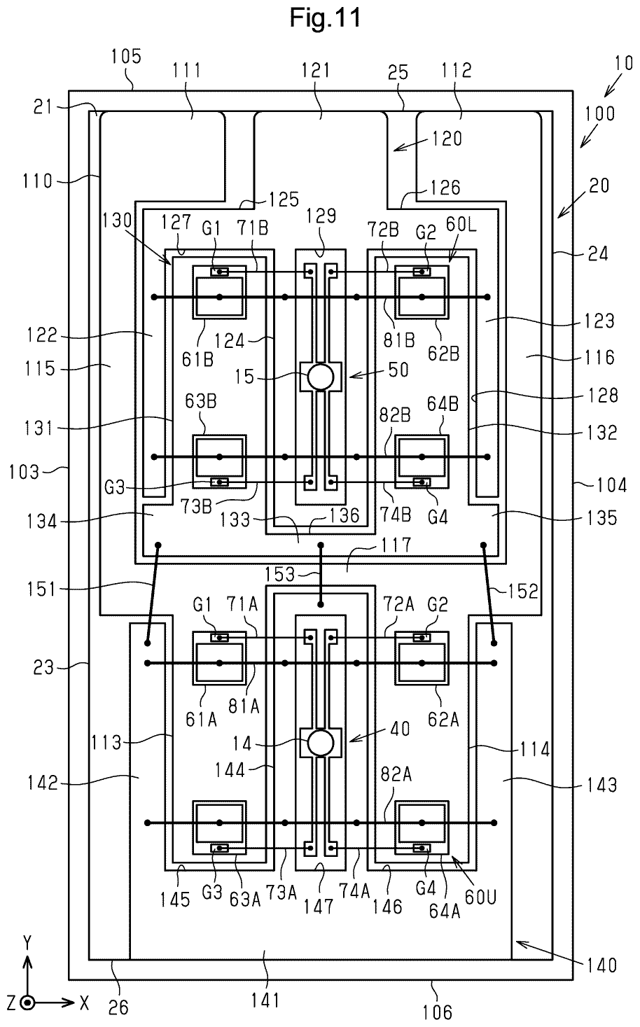

A second embodiment of a semiconductor device 10 will now be described with reference to FIGS. 11 to 13. The semiconductor device 10 of the second embodiment differs from the semiconductor device 10 of the first embodiment mainly in the structure of power interconnects and the manner of connecting the power interconnects to the switching elements 60U and 60L. In the description hereafter, same reference characters are given to those components that are the same as the corresponding components of the first embodiment. Such components will not be described in detail.

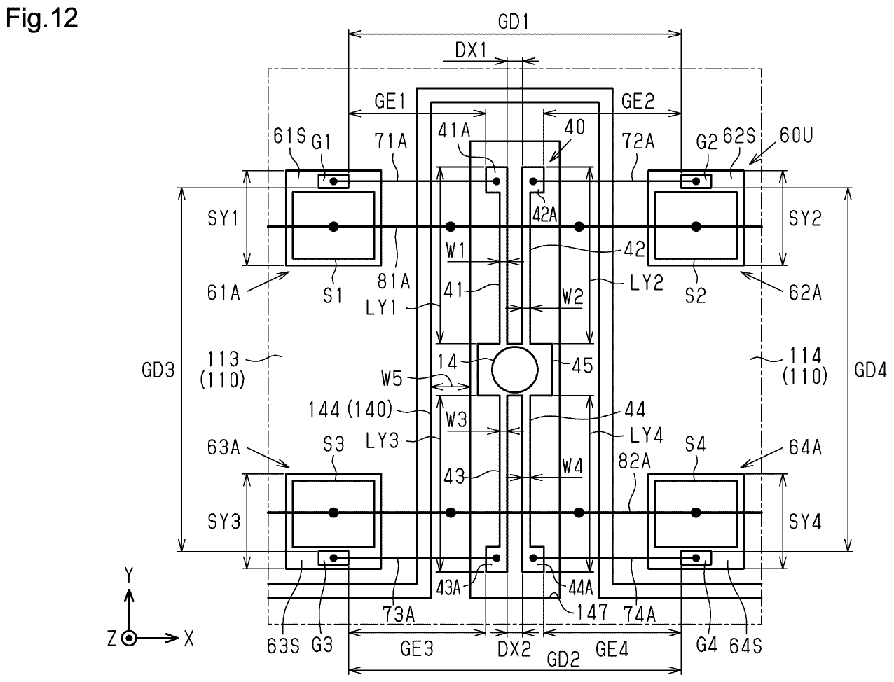

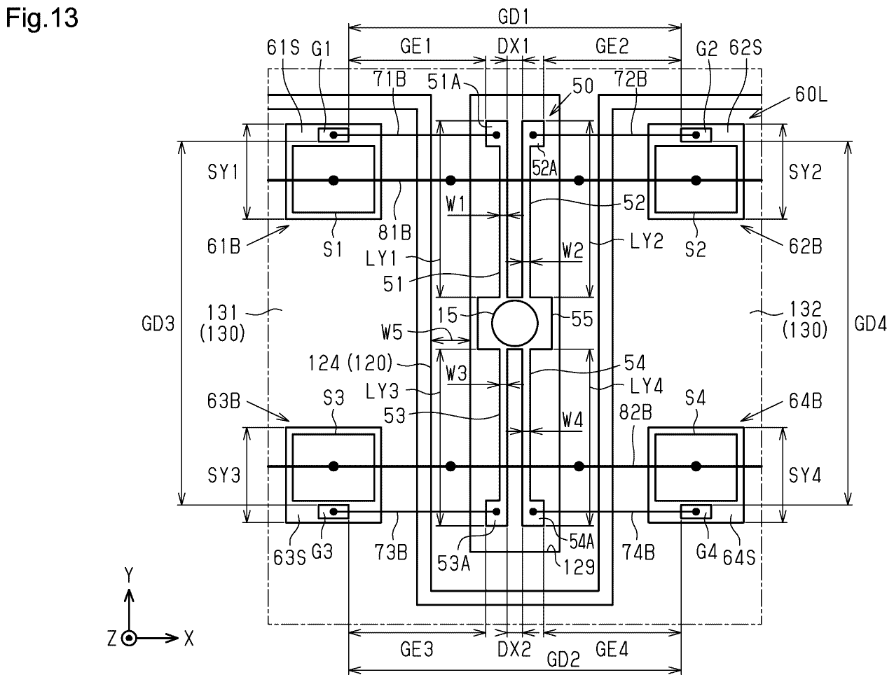

FIG. 11 is a schematic view showing the planar internal structure of the semiconductor device 10 of the second embodiment. FIG. 12 is a schematic enlarged view showing a portion of the planar structure shown in FIG. 11. FIG. 13 is a schematic enlarged view showing another portion of the planar structure shown in FIG. 11 differing from the portion shown in FIG. 12. In FIG. 11, the first power terminal 11, the second power terminal 12, and the output terminal 13 are not shown.

As shown in FIG. 11, the semiconductor device 10 of the second embodiment includes first to fourth power interconnects 110, 120, 130, and 140 instead of the first to third power interconnects 31 to 33 (refer to FIG. 2). The first to fourth power interconnects 110, 120, 130, and 140 are formed from, for example, the same conductive material as the first to third power interconnects 31 to 33.

The first power interconnect 110 is configured to be electrically connected to the first power terminal 11 shown in FIG. 1. In other words, the first power interconnect 110 is an interconnect on which the switching elements 60U are mounted. The first power interconnect 110 includes terminal connectors 111 and 112, a first element mount 113, a second element mount 114, a first joint portion 115, a second joint portion 116, and a third joint portion 117. In the example shown in FIG. 11, the terminal connectors 111 and 112, the first element mount 113, the second element mount 114, the first joint portion 115, the second joint portion 116, and the third joint portion 117 are integrated with each other.

The terminal connectors 111 and 112 are arranged on an end of the first substrate surface 21 of the insulative substrate 20 located toward the third substrate side surface 25. The terminal connectors 111 and 112 are located at the same position in the Y-direction and spaced apart from each other in the X-direction. The terminal connector 111 is arranged on one of the two ends of the first substrate surface 21 in the X-direction located closer to the first substrate side surface 23. The terminal connector 112 is arranged on one of the two ends of the first substrate surface 21 in the X-direction located closer to the second substrate side surface 24.

The first element mount 113 and the second element mount 114 are arranged toward the fourth substrate side surface 26 with respect to the center, in the Y-direction, of the first substrate surface 21. The first element mount 113 and the second element mount 114 are located at the same position in the Y-direction and spaced apart from each other in the X-direction. The first element mount 113 is arranged toward the first substrate side surface 23 with respect to the center, in the X-direction, of the first substrate surface 21. The second element mount 114 is arranged toward the second substrate side surface 24 with respect to the center, in the X-direction, of the first substrate surface 21. In plan view, each of the first element mount 113 and the second element mount 114 is rectangular such that the long sides extend in the Y-direction and the short sides extend in the X-direction.

The first joint portion 115 joins the terminal connector 111 and the first element mount 113. The first joint portion 115 is L-shaped in plan view. The first joint portion 115 is located closer to the fourth substrate side surface 26 than the terminal connector 111 is and closer to the first substrate side surface 23 than the first element mount 113 is. The first joint portion 115 includes a first part extending from the terminal connector 111 toward the fourth substrate side surface 26 in the Y-direction and a second part extending from the first part toward the second substrate side surface 24 in the X-direction. The first part is located adjacent to the first substrate side surface 23 in the X-direction in plan view. The second part is connected to one of the two ends of the first element mount 113 in the Y-direction located closer to the third substrate side surface 25.

The second joint portion 116 joins the terminal connector 112 and the second element mount 114. The second joint portion 116 is L-shaped in plan view. The second joint portion 116 is located closer to the fourth substrate side surface 26 than the terminal connector 112 is and closer to the second substrate side surface 24 than the second element mount 114 is. The second joint portion 116 includes a first part extending from the terminal connector 112 toward the fourth substrate side surface 26 in the Y-direction and a second part extending from the first part toward the first substrate side surface 23 in the X-direction. The first part is located adjacent to the second substrate side surface 24 in the X-direction in plan view. The second part is connected to one of the two ends of the second element mount 114 in the Y-direction located closer to the third substrate side surface 25.

The third joint portion 117 joins the first element mount 113 and the second element mount 114. The third joint portion 117 connects an end of the first element mount 113 located toward the third substrate side surface 25 and an end of the second element mount 114 located toward the third substrate side surface 25. The third joint portion 117 is arranged between the first element mount 113 and the second element mount 114. The third joint portion 117 extends in the X-direction.

The second power interconnect 120 is configured to be electrically connected to the second power terminal 12 shown in FIG. 1. The second power interconnect 120 includes a terminal connector 121, a first end connector 122, a second end connector 123, a center connector 124, a first joint portion 125, and a second joint portion 126. In the example shown in FIG. 10, the terminal connector 121, the first end connector 122, the second end connector 123, the center connector 124, the first joint portion 125, and the second joint portion 126 are integrated with each other.

The terminal connector 121 is arranged on an end of the first substrate surface 21 located toward the third substrate side surface 25. The terminal connector 121 is arranged between the terminal connector 111 and the terminal connector 112 of the first power interconnect 110 in the X-direction.

The first end connector 122, the second end connector 123, and the center connector 124 are arranged closer to the fourth substrate side surface 26 than the terminal connector 121 is. The first end connector 122, the second end connector 123, and the center connector 124 are located at the same position in the Y-direction and spaced apart from each other in the X-direction. The first end connector 122 is located closer to the first substrate side surface 23 than the terminal connector 121 is. The second end connector 123 is located closer to the second substrate side surface 24 than the terminal connector 121 is. The center connector 124 is arranged to overlap the terminal connector 121 as viewed in the Y-direction. The first end connector 122 and the second end connector 123 are belt-shaped and extend in the Y-direction. The center connector 124 is rectangular so that the long sides extend in the Y-direction and the short sides extend in the X-direction.

The first joint portion 125 joins the terminal connector 121, the first end connector 122, and the center connector 124. The first joint portion 125 extends in the X-direction. The first joint portion 125, the first end connector 122, and the center connector 124 define a first recess 127 that is open toward the fourth substrate side surface 26.

The second joint portion 126 joins the terminal connector 121, the second end connector 123, and the center connector 124. The second joint portion 126 extends in the X-direction. The second joint portion 126, the second end connector 123, and the center connector 124 define a second recess 128 that is open toward the fourth substrate side surface 26.

The center connector 124 includes an opening 129 in the center in the X-direction. The opening 129 is elongated in the Y-direction in plan view. The second gate interconnect 50 is arranged in the opening 129.

The third power interconnect 130 and the fourth power interconnect 140 are configured to electrically connect the output terminal 13, shown in FIG. 1, and the switching elements 60L. The switching elements 60L are mounted on the third power interconnect 130. The output terminal 13 is connected to the fourth power interconnect 140. The third power interconnect 130 and the fourth power interconnect 140 are spaced apart from each other in the Y-direction and electrically connected to each other.

The third power interconnect 130 is arranged closer to the third substrate side surface 25 than the fourth power interconnect 140 is. The third power interconnect 130 is arranged closer to the third substrate side surface 25 than the first element mount 113 and the second element mount 114 of the first power interconnect 110 are. The third power interconnect 130 includes a first element mount 131, a second element mount 132, and a joint portion 133. In the example shown in FIG. 11, the first element mount 131, the second element mount 132, and the joint portion 133 are integrated with each other.

The switching elements 60L are mounted on the first element mount 131 and the second element mount 132. The first element mount 131 and the second element mount 132 are located at the same position in the Y-direction and spaced apart from each other in the X-direction. In plan view, the first element mount 131 is arranged in the first recess 127 of the second power interconnect 120. In plan view, the second element mount 132 is arranged in the second recess 128 of the second power interconnect 120. In plan view, each of the first element mount 131 and the second element mount 132 is rectangular such that the long sides extend in the Y-direction and the short sides extend in the X-direction.

The first element mount 131 and the first element mount 113 of the first power interconnect 110 are located at the same position in the X-direction. The second element mount 132 and the second element mount 114 of the first power interconnect 110 are located at the same position in the X-direction.

A first connector 134 extends, toward the first substrate side surface 23, from an end of the first element mount 131 located toward the fourth substrate side surface 26. A second connector 135 extends, toward the second substrate side surface 24, from an end of the second element mount 132 located toward the fourth substrate side surface 26.

The joint portion 133 is arranged between the first element mount 131 and the second element mount 132 in the X-direction. The joint portion 133 extends in the X-direction. The joint portion 133 connects the first element mount 131 and the second element mount 132. In the example shown in FIG. 11, the joint portion 133 connects an end of the first element mount 131 located toward the fourth substrate side surface 26 and an end of the second element mount 132 located toward the fourth substrate side surface 26. The joint portion 133 is arranged closer to the fourth substrate side surface 26 than the center connector 124 of the second power interconnect 120 is.

The first element mount 131, the second element mount 132, and the joint portion 133 define a recess 136 that is open toward the third substrate side surface 25. The center connector 124 of the second power interconnect 120 is arranged in the recess 136 in plan view.

The fourth power interconnect 140 is arranged closer to the fourth substrate side surface 26 than the first to third joint portions 115 to 117 of the first power interconnect 110. The fourth power interconnect 140 includes a terminal connector 141, a first end connector 142, a second end connector 143, and a center connector 144. In the example shown in FIG. 11, the terminal connector 141, the first end connector 142, the second end connector 143, and the center connector 144 are integrated with one another.

The terminal connector 141 is connected to the output terminal 13 shown in FIG. 1. The terminal connector 141 is arranged on an end of the first substrate surface 21 located toward the fourth substrate side surface 26. In the example shown in FIG. 11, the width (dimension in X-direction) of the terminal connector 141 is greater than the width (dimension in X-direction) of the terminal connectors 111 and 112 of the first power interconnect 110.

The first end connector 142, the second end connector 143, and the center connector 144 are arranged closer to the third substrate side surface 25 than the terminal connector 141 is. The first end connector 142, the second end connector 143, and the center connector 144 are arranged at the same position in the Y-direction and spaced apart from each other in the X-direction. The first end connector 142 is arranged closer to the first substrate side surface 23 than the first element mount 113 of the first power interconnect 110 is. The second end connector 143 is arranged closer to the second substrate side surface 24 than the second element mount 114 of the first power interconnect 110 is. The center connector 144 is arranged between the first element mount 113 and the second element mount 114 in the X-direction. The first end connector 142 and the second end connector 143 are belt-shaped and extend in the Y-direction in plan view. In plan view, the center connector 144 is rectangular such that the long sides extend in the Y-direction and the short sides extend in the X-direction.

The terminal connector 141, the first end connector 142, and the center connector 144 define a first recess 145 that is open toward the third substrate side surface 25. The first element mount 113 is arranged in the first recess 145.

The terminal connector 141, the second end connector 143, and the center connector 144 define a second recess 146 that is open toward the third substrate side surface 25. The second element mount 114 is arranged in the second recess 146.

The center connector 144 includes an opening 147 in the center in the X-direction. The opening 147 is elongated in the Y-direction in plan view. The first gate interconnect 40 is arranged in the opening 147.

The third power interconnect 130 and the fourth power interconnect 140 are electrically connected by the first to third interconnect connection members 151 to 153. The first interconnect connection member 151 connects the first connector 134 of the third power interconnect 130 and the first end connector 142 of the fourth power interconnect 140. The first interconnect connection member 151 extends over the first joint portion 115 of the first power interconnect 110. The second interconnect connection member 152 connects the second connector 135 of the third power interconnect 130 and the second end connector 143 of the fourth power interconnect 140. The second interconnect connection member 152 extends over the second joint portion 116 of the first power interconnect 110. The third interconnect connection member 153 connects the joint portion 133 of the third power interconnect 130 and the center connector 144 of the fourth power interconnect 140. The third interconnect connection member 153 extends over the third joint portion 117 of the first power interconnect 110.

Of the switching elements 60U, the first switching element 61A and the third switching element 63A are mounted on the first element mount 113 of the first power interconnect 110. In the same manner as the first embodiment, the first switching element 61A and the third switching element 63A are bonded to the first element mount 113 by a conductive bonding material (not shown). Thus, the first drain electrode D1 (refer to FIG. 3) of the first switching element 61A and the third drain electrode D3 (refer to FIG. 4) of the third switching element 63A are electrically connected to the first element mount 113 (first power interconnect 110). In the example shown in FIG. 11, the first switching element 61A and the third switching element 63A are located at the same position in the X-direction and spaced apart from each other in the Y-direction. The first switching element 61A is arranged closer to the third substrate side surface 25 than the third switching element 63A is.

The second switching element 62A and the fourth switching element 64A of the switching elements 60U are mounted on the second element mount 114 of the first power interconnect 110. In the same manner as the first embodiment, the second switching element 62A and the fourth switching element 64A are bonded to the second element mount 114 by a conductive bonding material (not shown). Thus, the second drain electrode D2 (refer to FIG. 3) of the second switching element 62A and the fourth drain electrode D4 (refer to FIG. 4) of the fourth switching element 64A are electrically connected to the second element mount 114 (first power interconnect 110). In the example shown in FIG. 11, the second switching element 62A and the fourth switching element 64A are located at the same position in the X-direction and spaced apart from each other in the Y-direction. The second switching element 62A is arranged closer to the third substrate side surface 25 than the fourth switching element 64A is.

The first source connection member 81A connects the fourth power interconnect 140, the first source electrode S1 of the first switching element 61A, and the second source electrode S2 of the second switching element 62A. More specifically, the first source connection member 81A may be divided into first to fifth parts. The first part connects the first source electrode S1 of the first switching element 61A and the first end connector 142 of the fourth power interconnect 140. The second part connects the first source electrode S1 and the center connector 144 of the fourth power interconnect 140. The third part is connected to opposite sides of the opening 147 of the center connector 144 in the X-direction so as to extend over the opening 147 of the center connector 144, that is, over the first gate interconnect 40. The fourth part connects the center connector 144 and the second source electrode S2 of the second switching element 62A. The fifth part connects the second source electrode S2 and the second end connector 143.

The second source connection member 82A connects the fourth power interconnect 140, the third source electrode S3 of the third switching element 63A, and the fourth source electrode S4 of the fourth switching element 64A. The fourth power interconnect 140, the third source electrode S3, and the fourth source electrode S4 are connected by the second source connection member 82A in the same manner as the fourth power interconnect 140, the first source electrode S1, and the second source electrode S2 are connected by the first source connection member 81A.

As shown in FIG. 12, the structure of the first gate interconnect 40, the positional relationship of the first gate interconnect 40 with the first to fourth gate electrodes G1 to G4 of the first to fourth switching elements 61A to 64A, and the manner of connecting the first to fourth gate electrodes G1 to G4 and the first gate interconnect 40 by the first to fourth gate connection members 71A to 74A are the same as those of the first embodiment.

As shown in FIG. 11, the first switching element 61B and the third switching element 63B of the switching elements 60L are mounted on the first element mount 131 of the third power interconnect 130. In the same manner as the first embodiment, the first switching element 61B and the third switching element 63B are bonded to the first element mount 131 by a conductive bonding material (not shown). Thus, the first drain electrode D1 (refer to FIG. 5) of the first switching element 61B and the third drain electrode D3 (refer to FIG. 6) of the third switching element 63B are electrically connected to the first element mount 131 (third power interconnect 130). In the example shown in FIG. 11, the first switching element 61B and the third switching element 63B are located at the same position in the X-direction and spaced apart from each other in the Y-direction. The first switching element 61B is arranged closer to the third substrate side surface 25 than the third switching element 63B is.

Of the switching elements 60L, the second switching element 62B and the fourth switching element 64B are mounted on the second element mount 132 of the third power interconnect 130. In the same manner as the first embodiment, the second switching element 62B and the fourth switching element 64B are bonded to the second element mount 132 by a conductive bonding material (not shown). Thus, the second drain electrode D2 (refer to FIG. 5) of the second switching element 62B and the fourth drain electrode D4 (refer to FIG. 6) of the fourth switching element 64B are electrically connected to the second element mount 132 (third power interconnect 130). In the example shown in FIG. 11, the second switching element 62B and the fourth switching element 64B are located at the same position in the X-direction and spaced apart from each other in the Y-direction. The second switching element 62B is arranged closer to the third substrate side surface 25 than the fourth switching element 64B is.

The first source connection member 81B connects the second power interconnect 120, the first source electrode S1 of the first switching element 61B, and the second source electrode S2 of the second switching element 62B. More specifically, the first source connection member 81B is divided into first to fifth parts. The first part connects the first source electrode S1 of the first switching element 61B and the first end connector 122 of the second power interconnect 120. The second part connects the first source electrode S1 and the center connector 124 of the second power interconnect 120. The third part is connected to opposite sides of the opening 129 of the center connector 124 in the X-direction so as to extend over the opening 129 of the center connector 124, that is, over the second gate interconnect 50. The fourth part connects the center connector 124 and the second source electrode S2 of the second switching element 62B. The fifth part connects the second source electrode S2 and the second end connector 123.

The second source connection member 82B connects the second power interconnect 120, the third source electrode S3 of the third switching element 63B, and the fourth source electrode S4 of the fourth switching element 64B. The second power interconnect 120, the third source electrode S3, and the fourth source electrode S4 are connected by the second source connection member 82B in the same manner as the second power interconnect 120, the first source electrode S1, and the second source electrode S2 are connected by the first source connection member 81B.

As shown in FIG. 13, the structure of the second gate interconnect 50, the positional relationship of the second gate interconnect 50 with the first to fourth gate electrodes G1 to G4 of the first to fourth switching elements 61B to 64B, and the manner of connecting the second gate interconnect 50 and the first to fourth gate electrodes G1 to G4 with the first to fourth gate connection members 71B to 74B are the same as those of the first embodiment. The second embodiment has the same advantages as the first embodiment.

### Third Embodiment

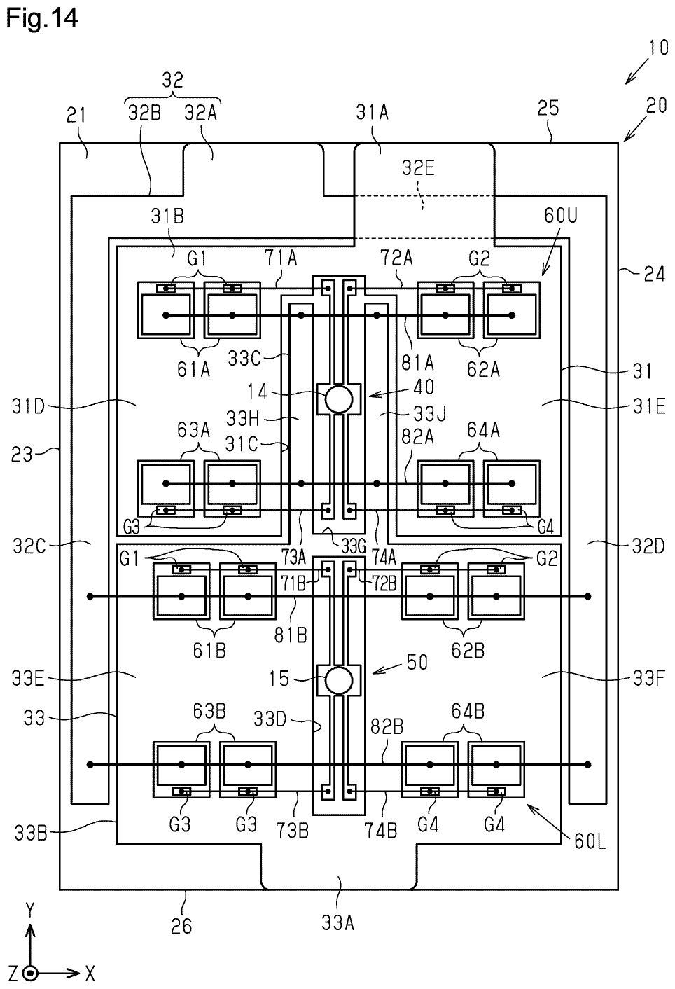

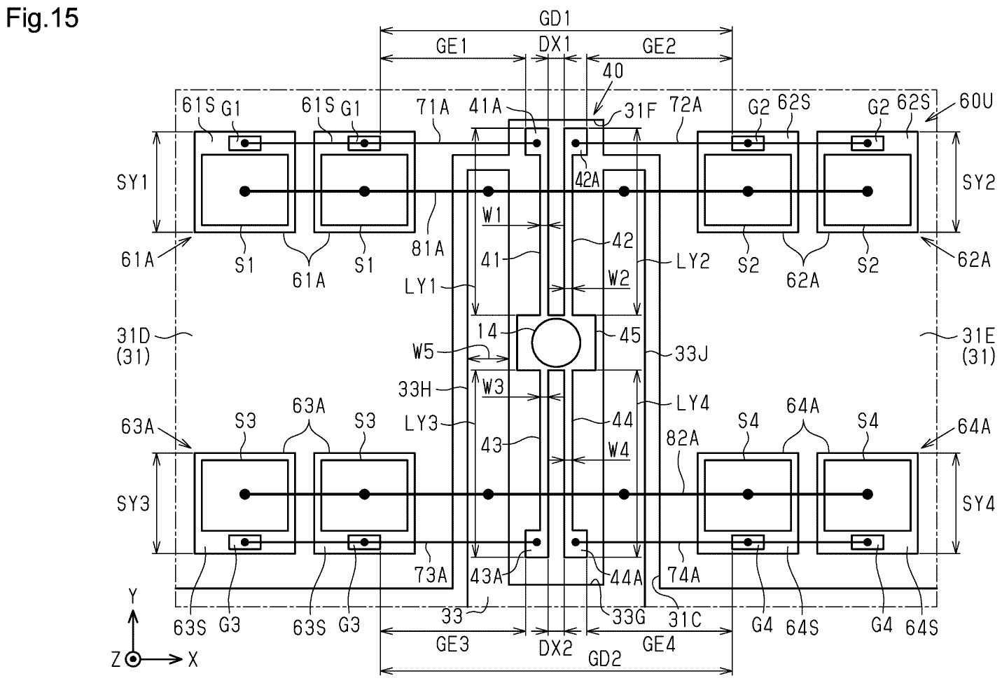

A third embodiment of a semiconductor device 10 will now be described with reference to FIGS. 14 and 15. The semiconductor device 10 of the third embodiment differs from the semiconductor device 10 of the first embodiment mainly in the number of switching elements 60U and 60L. In the description hereafter, same reference characters are given to those components that are the same as the corresponding components of the first embodiment. Such components will not be described in detail.

FIG. 14 is a schematic view showing the planar internal structure of the semiconductor device 10 of the third embodiment. FIG. 15 is a schematic enlarged view showing a portion of the planar structure shown in FIG. 14. In FIG. 14, the first power terminal 11, the second power terminal 12, the output terminal 13, and the package body 100 are not shown.

As shown in FIG. 14, in the third embodiment, the switching elements 60U include first switching elements 61A, second switching elements 62A, third switching elements 63A, and fourth switching elements 64A. Thus, as the number of switching elements 60U is increased from that of the first embodiment, the first power interconnect 31 has a different structure. More specifically, the width (dimension in X-direction) of the first mount portion 31D and the width (dimension in X-direction) of the second mount portion 31E of the first power interconnect 31 are greater than those of the first embodiment.

The first switching elements 61A are arranged on the first mount portion 31D at the same position in the Y-direction and spaced apart from each other in the X-direction. The third switching elements 63A are arranged on the first mount portion 31D at the same position in the Y-direction and spaced apart from each other in the X-direction. The first switching elements 61A and the third switching elements 63A are arranged in a matrix on the first mount portion 31D.

The second switching elements 62A are arranged on the second mount portion 31E at the same position in the Y-direction and spaced apart from each other in the X-direction. The fourth switching elements 64A are arranged on the second mount portion 31E at the same position in the Y-direction and spaced apart from each other in the X-direction. The second switching elements 62A and the fourth switching elements 64A are arranged in a matrix on the second mount portion 31E.

The first source connection member 81A connects the first source electrodes S1 of the first switching elements 61A, the third power interconnect 33, and the second source electrodes S2 of the second switching elements 62A. The first source connection member 81A of the third embodiment, which differs from the first source connection member 81A of the first embodiment, further includes a part that connects the first source electrodes S1 of the first switching elements 61A located adjacent to each other in the X-direction and a part that connects the second source electrodes S2 of the second switching elements 62A located adjacent to each other in the X-direction.

The second source connection member 82A connects the third source electrodes S3 of the third switching elements 63A, the third power interconnect 33, and the fourth source electrodes S4 of the fourth switching elements 64A. The second source connection member 82A of the third embodiment, which differs from the second source connection member 82A of the first embodiment, further includes a part that connects the third source electrodes S3 of the third switching elements 63A located adjacent to each other in the X-direction and a part that connects the fourth source electrodes S4 of the fourth switching elements 64A located adjacent to each other in the X-direction.

As shown in FIG. 15, the first gate connection member 71A of the third embodiment, which differs from the first gate connection member 71A of the first embodiment, further includes a part that connects the first gate electrodes G1 of the first switching elements 61A. The second gate connection member 72A of the third embodiment, which differs from the second gate connection member 72A of the first embodiment, includes a part that connects the second gate electrodes G2 of the second switching elements 62A. The third gate connection member 73A of the third embodiment, which differs from the third gate connection member 73A of the first embodiment, includes a part that connects the third gate electrodes G3 of the third switching elements 63A. The fourth gate connection member 74A of the third embodiment, which differs from the fourth gate connection member 74A of the first embodiment, further includes a part that connects the fourth gate electrodes G4 of the fourth switching elements 64A.

As shown in FIG. 14, the switching elements 60L include first switching elements 61B, second switching elements 62B, third switching elements 63B, and fourth switching elements 64B. Thus, as the number of switching elements 60L is increased from that of the first embodiment, the third power interconnect 33 has a different structure. More specifically, the width (dimension in X-direction) of the first mount portion 33E and the width (dimension in X-direction) of the second mount portion 33F of the third power interconnect 33 are greater than those of the first embodiment.

The first switching elements 61B are arranged on the first mount portion 33E at the same position in the Y-direction and spaced apart from each other in the X-direction. The third switching elements 63B are arranged on the first mount portion 33E at the same position in the Y-direction and spaced apart from each other in the X-direction. The first switching elements 61B and the third switching elements 63B are arranged in a matrix on the first mount portion 33E.

The second switching elements 62B are arranged on the second mount portion 33F at the same position in the Y-direction and spaced apart from each other in the X-direction. The fourth switching elements 64B are arranged on the second mount portion 33F at the same position in the Y-direction and spaced apart from each other in the X-direction. The second switching elements 62B and the fourth switching elements 64B are arranged in a matrix on the second mount portion 33F.

The first source connection member 81B connects the first source electrodes S1 of the first switching elements 61B, the second power interconnect 32, and the second source electrodes S2 of the second switching elements 62B. The first source connection member 81B of the third embodiment, which differs from the first source connection member 81B of the first embodiment, further includes a part connecting the first source electrodes S1 of the first switching elements 61B that are adjacent to each other in the X-direction and a part connecting the second source electrodes S2 of the second switching elements 62B that are adjacent to each other in the X-direction.

The second source connection member 82B connects the third source electrodes S3 of the third switching elements 63B, the second power interconnect 32, and the fourth source electrodes S4 of the fourth switching elements 64B. The second source connection member 82B of the third embodiment, which differs from the second source connection member 82B of the first embodiment, further includes a part that connects the third source electrodes S3 of the third switching elements 63B located adjacent to each other in the X-direction and a part that connects the fourth source electrodes S4 of the fourth switching elements 64B located adjacent to each other in the X-direction.

The first gate connection member 71B of the third embodiment, which differs from the first gate connection member 71B of the first embodiment, further includes a part that connects the first gate electrodes G1 of the first switching elements 61B. The second gate connection member 72B of the third embodiment, which differs from the second gate connection member 72B of the first embodiment, further includes a part that connects the second gate electrodes G2 of the second switching elements 62B. The third gate connection member 73B of the third embodiment, which differs from the third gate connection member 73B of the first embodiment, includes a part that connects the third gate electrodes G3 of the third switching elements 63B. The fourth gate connection member 74B of the third embodiment, which differs from the fourth gate connection member 74B of the first embodiment, further includes a part that connects the fourth gate electrodes G4 of the fourth switching elements 64A. The third embodiment has the same advantages as the first embodiment.

### Fourth Embodiment

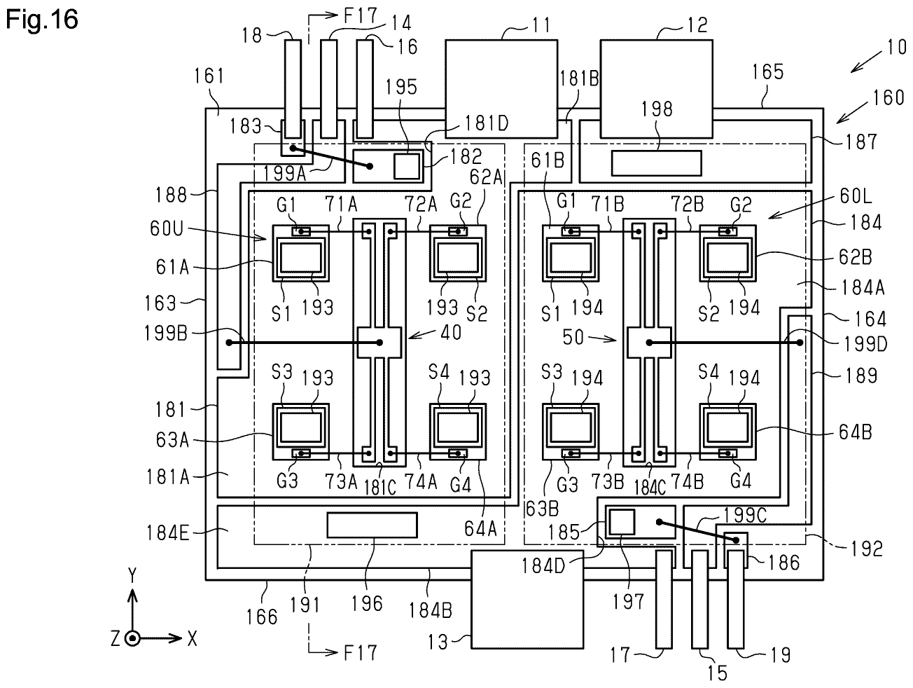

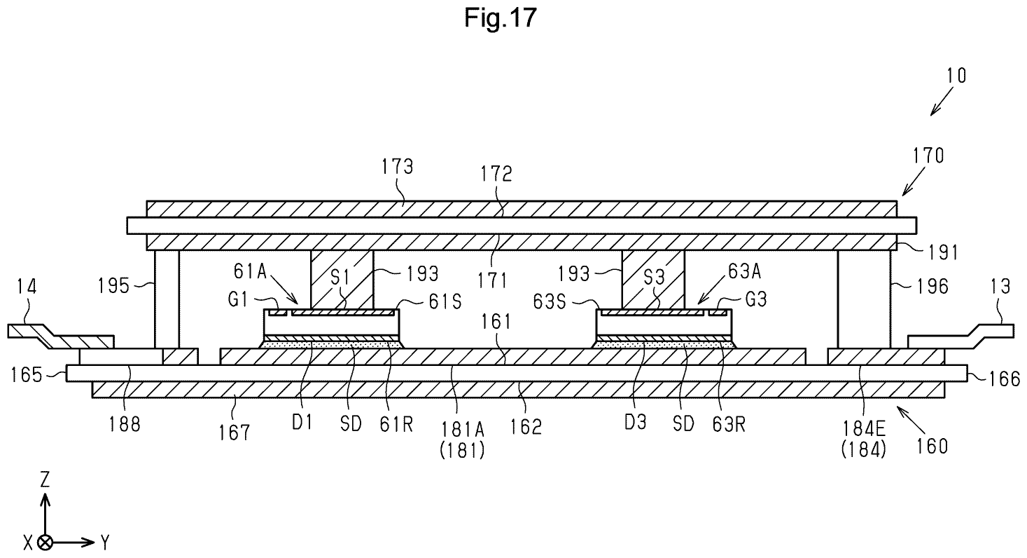

A fourth embodiment of a semiconductor device 10 will now be described with reference to FIGS. 16 and 17. The semiconductor device 10 of the fourth embodiment differs from the semiconductor device 10 of the first embodiment mainly in the electrical connection structure of the switching elements 60U and 60L. In the description hereafter, same reference characters are given to those components that are the same as the corresponding components of the first embodiment. Such components will not be described in detail.

FIG. 16 is a schematic view showing the planar internal structure of the semiconductor device 10 of the fourth embodiment. FIG. 17 is a schematic view of a cross-sectional structure of the semiconductor device 10 taken along line F17-F17 in FIG. 16.

As shown in FIGS. 16 and 17, the semiconductor device 10 includes a first substrate 160 and a second substrate 170 instead of the insulative substrate 20 (refer to FIG. 3). The first substrate 160 and the second substrate 170 are spaced apart from each other and faced to each other in the Z-direction. The switching elements 60U and 60L are mounted on the first substrate 160.

The first substrate 160 has the form of a rectangular plate having a thickness extending in the Z-direction. In the example shown in FIG. 16, in plan view, the first substrate 160 is rectangular so that the long sides extend in the X-direction and the short sides extend in the Y-direction. The first substrate 160 includes a first substrate surface 161, a second substrate surface 162 opposite to the first substrate surface 161, and first to fourth substrate side surfaces 163 to 166 as four substrate side surfaces connecting the first substrate surface 161 and the second substrate surface 162. The first substrate side surface 163 and the second substrate side surface 164 define two end surfaces of the first substrate 160 in the X-direction. The third substrate side surface 165 and the fourth substrate side surface 166 define two end surfaces of the first substrate 160 in the Y-direction.

First to seventh power interconnects 181 to 187, a first signal interconnect 188, and a second signal interconnect 189 are arranged on the first substrate surface 161. In the same manner as the first embodiment, a heat dissipation plate 167 is arranged on the second substrate surface 162. The heat dissipation plate 167 is an example of a “first heat dissipation plate.” The first power interconnect 181 is an example of a “first element mount interconnect.” The fourth power interconnect 184 is an example of a “second element mount interconnect.”

The first power interconnect 181 is arranged on the first substrate surface 161 toward the first substrate side surface 163 in plan view. The switching elements 60U (in the example shown in FIG. 16, first to fourth switching elements 61A to 64A) are mounted on the first power interconnect 181. In the same manner as the first embodiment, the first to fourth switching elements 61A to 64A are bonded to the first power interconnect 181 by the conductive bonding material SD. Thus, the first to fourth drain electrodes D1 to D4 of the first to fourth switching elements 61A to 64A are electrically connected to the first power interconnect 181.

The first power interconnect 181 includes an element mount 181A and a terminal connector 181B. In an example, the element mount 181A and the terminal connector 181B are integrated with each other.

The first to fourth switching elements 61A to 64A are mounted on the element mount 181A. The element mount 181A includes an opening 181C. In plan view, the first gate interconnect 40 is arranged in the opening 181C. The first gate interconnect 40 and the first to fourth switching elements 61A to 64A are arranged in the same manner as the first embodiment. The first gate interconnect 40 and the first to fourth gate electrodes G1 to G4 are connected to in the same manner as the first embodiment.

The terminal connector 181B is arranged closer to the third substrate side surface 165 than the element mount 181A. The depression 181D extends between the terminal connector 181B and the element mount 181A. The depression 181D is open toward the first substrate side surface 163. The first power terminal 11 and the first drain detection terminal 16 are connected to the terminal connector 181B. Thus, the first power terminal 11 and the first drain detection terminal 16 are electrically connected to the first to fourth drain electrodes D1 to D4 of the first to fourth switching elements 61A to 64A. The first power terminal 11 and the first drain detection terminal 16 are arranged at the same position in the Y-direction and spaced apart from each other in the X-direction. The first drain detection terminal 16 is located closer to the first substrate side surface 163 than the first power terminal 11 is. The first drain detection terminal 16 is belt-shaped and extends in the Y-direction in plan view.

A second power interconnect 182 is arranged in the depression 181D of the first power interconnect 181. A third power interconnect 183 is spaced apart from the second power interconnect 182 and located toward the first substrate side surface 163 and the third substrate side surface 165 with respect to the second power interconnect 182. The second power interconnect 182 and the third power interconnect 183 are connected by a wire 199A. Thus, the second power interconnect 182 and the third power interconnect 183 are electrically connected. The third power interconnect 183 is connected to a first source detection terminal 18. The first source detection terminal 18 is belt-shaped and extends in the Y-direction in plan view.

The first signal interconnect 188 surrounds part of the first power interconnect 181 from the first substrate side surface 163 and the third substrate side surface 165 in plan view. The first signal interconnect 188 includes first to third patterns. The first pattern is located between the first power interconnect 181 and the first substrate side surface 163 in the X-direction in plan view. The first pattern extends in the Y-direction. The first pattern is electrically connected to the first gate interconnect 40 by a wire 199B. That is, the first signal interconnect 188 is electrically connected to the first gate interconnect 40. The second pattern extends from the first pattern toward the second power interconnect 182 in the X-direction. The second pattern is located closer to the third substrate side surface 165 than the element mount 181A of the first power interconnect 181 is. The third pattern extends from the second pattern toward the third substrate side surface 165 in the Y-direction. The third pattern extends through space between the second power interconnect 182 and the third power interconnect 183 in the X-direction. The third pattern is connected to the first gate terminal 14. The first gate terminal 14 differs from the first embodiment in that the first gate terminal 14 is belt-shaped and extends in the Y-direction in plan view.

The fourth power interconnect 184 is arranged on the first substrate surface 161 toward the second substrate side surface 164 in plan view. The fourth power interconnect 184 is located adjacent to the first power interconnect 181 in the X-direction. The switching elements 60L (in the example shown in FIG. 16, first to fourth switching elements 61B to 64B) are mounted on the fourth power interconnect 184. In the same manner as the first embodiment, the first to fourth switching elements 61B to 64B are bonded to the fourth power interconnect 184 by the conductive bonding material SD. Thus, the first to fourth drain electrodes D1 to D4 of the first to fourth switching elements 61B to 64B are electrically connected to the fourth power interconnect 184.

The fourth power interconnect 184 includes an element mount 184A and a connector 184B. In an example, the element mount 184A and the connector 184B are integrated with each other.

The first to fourth switching elements 61B to 64B are mounted on the element mount 184A. The element mount 184A includes an opening 184C. In plan view, the second gate interconnect 50 is arranged in the opening 184C. The second gate interconnect 50 and the first to fourth switching elements 61B to 64B are arranged in the same manner as the first embodiment. The first to fourth gate electrodes G1 to G4 are connected to the second gate interconnect 50 in the same manner as the first embodiment.

The connector 184B is located closer to the fourth substrate side surface 166 than the element mount 184A is. The depression 184D extends between the connector 184B and the element mount 184A. The depression 184D is open toward the second substrate side surface 164. The output terminal 13 and the second drain detection terminal 17 are connected to the connector 184B. Thus, the output terminal 13 and the second drain detection terminal 17 are electrically connected to the first to the fourth drain electrodes D1 to D4 of the first to fourth switching elements 61B to 64B. The output terminal 13 and the second drain detection terminal 17 are located at the same position in the Y-direction and spaced apart from each other in the X-direction. The second drain detection terminal 17 is located closer to the second substrate side surface 164 than the output terminal 13 is. The second drain detection terminal 17 is belt-shaped and extends in the Y-direction in plan view.

The connector 184B extends toward the first substrate side surface 163 from the element mount 184A. The connector 184B includes an extension 184E extending in the X-direction between the first power interconnect 181 and the fourth substrate side surface 166 in the Y-direction.

The fifth power interconnect 185 is arranged in the depression 184D of the fourth power interconnect 184. The sixth power interconnect 186 is spaced apart from the fifth power interconnect 185 and located toward the second substrate side surface 164 and the fourth substrate side surface 166 with respect to the fifth power interconnect 185. The fifth power interconnect 185 and the sixth power interconnect 186 are connected by a wire 199C. Thus, the fifth power interconnect 185 and the sixth power interconnect 186 are electrically connected. The sixth power interconnect 186 is connected to a second source detection terminal 19. The second source detection terminal 19 is belt-shaped and extends in the Y-direction in plan view.

The second signal interconnect 189 surrounds part of the fourth power interconnect 184 from the second substrate side surface 164 and the fourth substrate side surface 166 in plan view. The second signal interconnect 189 includes first to third patterns. The first pattern is located between the fourth power interconnect 184 and the second substrate side surface 164 in the X-direction in plan view. The first pattern extends in the Y-direction. The first pattern is electrically connected to the second gate interconnect 50 by a wire 199D. Thus, the second signal interconnect 189 is electrically connected to the second gate interconnect 50. The second pattern extends from the first pattern toward the fifth power interconnect 185 in the X-direction. The second pattern is located closer to the fourth substrate side surface 166 than the element mount 84A of the fourth power interconnect 184 is. The third pattern extends in the Y-direction from the second pattern toward the fourth substrate side surface 166. The third pattern extends through space between the fifth power interconnect 185 and the sixth power interconnect 186 in the X-direction. The second gate terminal 15 is connected to the third pattern. The second gate terminal 15, which differs from that of the first embodiment, is belt-shaped and extends in the Y-direction in plan view.

The seventh power interconnect 187 is arranged closer to the second substrate side surface 164 than the first power interconnect 181 is and closer to the third substrate side surface 165 than the fourth power interconnect 184 is. The seventh power interconnect 187 is arranged adjacent to the terminal connector 181B of the first power interconnect 181 in the X-direction. In plan view, the seventh power interconnect 187 is rectangular such that the long sides extend in the X-direction and the short sides extend in the Y-direction. The seventh power interconnect 187 is connected to the second power terminal 12. The second power terminal 12 is arranged toward the terminal connector 181B with respect to the center, in the X-direction, of the seventh power interconnect 187.

The second substrate 170 includes a first substrate surface 171 and a second substrate surface 172 opposite to the first substrate surface 171. A first power interconnect 191 and a second power interconnect 192 are arranged on the first substrate surface 171. A heat dissipation plate 173 is arranged on the second substrate surface 172. The heat dissipation plate 173 is an example of a “second heat dissipation plate.”

The first power interconnect 191 is configured to be electrically connected to the first to fourth source electrodes S1 to S4 of the first to fourth switching elements 61A to 64A. The first power interconnect 191 is opposed to the first power interconnect 181, the second power interconnect 182, and the extension 184E of the fourth power interconnect 184 in the Z-direction.

First source connection members 193 are individually connected to the first to fourth source electrodes S1 to S4 of the first to fourth switching elements 61A to 64A. The first source connection members 193 each include a pillar formed from a conductive material such as Al and/or Cu. In the example shown in FIG. 16, the pillar is rectangular in plan view. The first source connection members 193 are connected to the first power interconnect 191. Thus, the first to fourth source electrodes S1 to S4 are electrically connected to the first power interconnect 191.

The second power interconnect 182 is connected to a first interconnect connection member 195. The first interconnect connection member 195 includes a pillar formed from a conductive material such as Al and/or Cu. In the example shown in FIG. 16, the pillar is rectangular in plan view. The first interconnect connection member 195 is located closer to the second substrate side surface 164 than the wire 199A is. The first interconnect connection member 195 is electrically connected to the first power interconnect 191. Thus, the second power interconnect 182 is electrically connected to the first to fourth source electrodes S1 to S4 of the first to fourth switching elements 61A to 64A.

The extension 184E of the fourth power interconnect 184 is connected to a second interconnect connection member 196. The second interconnect connection member 196 includes a pillar formed from a conductive material such as Al and/or Cu. In the example shown in FIG. 16, the pillar is rectangular such that the long sides extend in the X-direction and the short sides extend in the Y-direction in plan view. The second interconnect connection member 196 is located at the same position as the first gate interconnect 40 in the X-direction. The second interconnect connection member 196 is connected to the first power interconnect 191. This electrically connects the fourth power interconnect 184 to the first to fourth source electrodes S1 to S4 of the first to fourth switching elements 61A to 64A. Thus, the first to fourth source electrodes S1 to S4 of the first to fourth switching elements 61A to 64A are electrically connected to the first to fourth drain electrodes D1 to D4 of the first to fourth switching elements 61B to 64B.

The second power interconnect 192 is configured to be electrically connected to the first to fourth source electrodes S1 to S4 of the first to fourth switching elements 61B to 64B. The second power interconnect 192 is opposed to the fourth power interconnect 184, the fifth power interconnect 185, and the seventh power interconnect 187 in the Z-direction.

Second source connection members 194 are individually connected to the first to fourth source electrodes S1 to S4 of the first to fourth switching elements 61B to 64B. The second source connection members 194 each include a pillar formed from a conductive material such as Al and/or Cu. In the example shown in FIG. 16, the pillar is rectangular in plan view. The second source connection members 194 are connected to the second power interconnect 192. Thus, the first to fourth source electrodes S1 to S4 of the first to fourth switching elements 61B to 64B are electrically connected to the second power interconnect 192.

The third interconnect connection member 197 is connected to the fifth power interconnect 185. The third interconnect connection member 197 includes a pillar formed from a conductive material such as Al and/or Cu. In the example shown in FIG. 16, the pillar is rectangular in plan view. The third interconnect connection member 197 is located closer to the first substrate side surface 163 than the wire 199B is. The third interconnect connection member 197 is electrically connected to the second power interconnect 192. Thus, the fifth power interconnect 185 is electrically connected to the first to fourth source electrodes S1 to S4 of the first to fourth switching elements 61B to 64B.

The seventh power interconnect 187 is connected to a fourth interconnect connection member 198. The fourth interconnect connection member 198 includes a pillar formed from a conductive material such as Al and/or Cu. In the example shown in FIG. 16, the pillar is rectangular such that the long sides extend in the X-direction and the short sides extend in the Y-direction in plan view. The fourth interconnect connection member 198 and the second gate interconnect 50 are located at the same position in the X-direction. The fourth interconnect connection member 198 is located closer, in the Y-direction, to the fourth power interconnect 184 than the second power terminal 12 is. The fourth interconnect connection member 198 is connected to the second power interconnect 192. Thus, the seventh power interconnect 187 is electrically connected to the first to fourth source electrodes S1 to S4 of the first to fourth switching elements 61B to 64B. The first to fourth source electrodes S1 to S4 are electrically connected to the second power terminal 12.

### Advantages of Fourth Embodiment

The semiconductor device 10 of the fourth embodiment has the following advantages.
(4-1) The semiconductor device 10 includes the first to fourth switching elements 61B to 64B connected in parallel to each other and connected in series to the first to fourth switching elements 61A to 64A, the first substrate 160 including the first substrate surface 161 and the second substrate surface 162 opposite to the first substrate surface 161, the first power interconnect 181 arranged on the first substrate surface 161 of the first substrate 160 and on which the first to fourth switching elements 61A to 64A are mounted, the fourth power interconnect 184 arranged on the first substrate surface 161 of the first substrate 160 and on which the first to fourth switching elements 61B to 64B are mounted, the second substrate 170 including the first substrate surface 171 and the second substrate surface 172 opposite to the first substrate surface 171, the second substrate 170 being opposed to and spaced apart from the first substrate 160 in the Z-direction, the first power interconnect 191 arranged on the first substrate surface 171 of the second substrate 170 and opposed to the first to fourth switching elements 61A to 64A in the Z-direction, the second power interconnect 192 arranged on the first substrate surface 171 of the second substrate 170 and opposed to the first to fourth switching elements 61B to 64B in the Z-direction, the first source connection members 193 individually connecting the first to fourth source electrodes S1 to S4 of the first to fourth switching elements 61A to 64A to the first power interconnect 191, and the second source connection members 194 individually connecting the first to fourth source electrodes S1 to S4 of the first to fourth switching elements 61B to 64B to the second power interconnect 192.

In this structure, the first power interconnect 191, which is electrically connected to the first to fourth source electrodes S1 to S4 of the first to fourth switching elements 61A to 64A, and the second power interconnect 192, which is electrically connected to the first to fourth source electrodes S1 to S4 of the first to fourth switching elements 61B to 64B, are located at positions differing from the first substrate surface 161 of the first substrate 160 in the Z-direction. Thus, the first substrate 160 is reduced in size in the X-direction and the Y-direction as compared to a structure in which the first power interconnect 191 and the second power interconnect 192 are arranged on the first substrate surface 161 of the first substrate 160. Accordingly, the semiconductor device 10 is reduced in size in the X-direction and the Y-direction.
(4-2) The first source connection member 193 and the second source connection member 194 each include a pillar.

This structure reduces the inductance of current paths between the first to fourth source electrodes S1 to S4 of the first to fourth switching elements 61A to 64A and the first power interconnect 191 as compared to a structure in which the first to fourth source electrodes S1 to S4 of the first to fourth switching elements 61A to 64A are connected to the first power interconnect 191 by wires. Also, the inductance of current paths between the first to fourth source electrodes S1 to S4 of the first to fourth switching elements 61B to 64B and the second power interconnect 192 is reduced as compared to a structure in which the first to fourth source electrodes S1 to S4 of the first to fourth switching elements 61B to 64B are connected to the second power interconnect 192 by wires.

In addition, the first power interconnect 191 and the second power interconnect 192 are arranged on the first substrate surface 171 of the second substrate 170, which provides a relatively large space for the first power interconnect 191 and the second power interconnect 192. Thus, the degree of freedom for designing the first power interconnect 191 and the second power interconnect 192 is increased.
(4-3) The semiconductor device 10 includes the heat dissipation plate 167, which is arranged on the second substrate surface 162 of the first substrate 160, and the heat dissipation plate 173, which is arranged on the second substrate surface 172 of the second substrate 170.

In this structure, heat generated in the first to fourth switching elements 61A to 64A and 61B to 64B is readily transferred to the heat dissipation plates 167 and 173. The heat dissipation plates 167 and 173 dissipate the heat to the outside of the semiconductor device 10. Thus, the cooling efficiency of the semiconductor device 10 is improved.

### Application Examples of Semiconductor Device

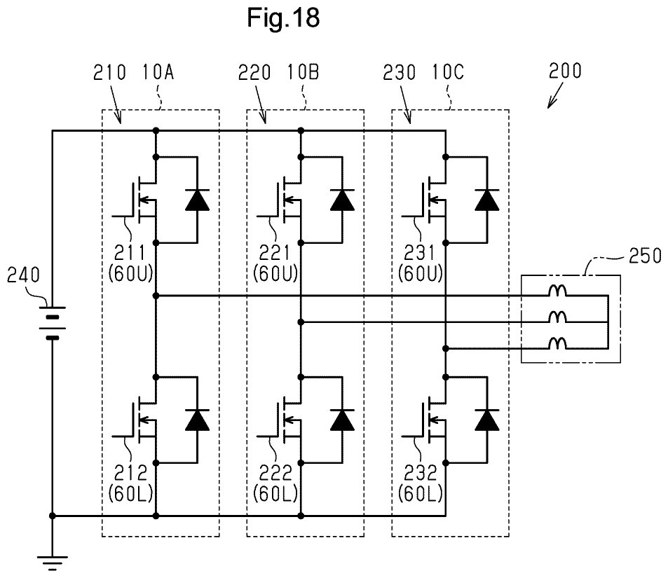

The semiconductor device 10 of each embodiment may be configured as an inverter unit that drives, for example, one of the U-phase, the V-phase, and the W-phase of a three-phase drive motor 250 (refer to FIG. 18). Therefore, three semiconductor devices 10 corresponding to the U-phase, the V-phase, and the W-phase may form an inverter device 200 that drives the three-phase drive motor 250.

FIG. 18 shows an example of the circuit configuration of the inverter device 200.

As shown in FIG. 18, the inverter device 200 includes a U-phase inverter circuit 210, a V-phase inverter circuit 220, and a W-phase inverter circuit 230.

The U-phase inverter circuit 210 includes switching elements 211 and 212 that are connected in series to each other. The V-phase inverter circuit 220 includes switching elements 221 and 222 that are connected in series to each other. The W-phase inverter circuit 230 includes switching elements 231 and 232 that are connected in series to each other. In the example shown in FIG. 18, the U-phase inverter circuit 210, the V-phase inverter circuit 220, and the W-phase inverter circuit 230 are each formed of a semiconductor device 10. The semiconductor device 10 including the U-phase inverter circuit 210 is referred to as a “first semiconductor device 10A.” The semiconductor device 10 including the V-phase inverter circuit 220 is referred to as a “second semiconductor device 10B.” The semiconductor device 10 including the W-phase inverter circuit 230 is referred to as a “third semiconductor device 10C.”

The switching element 211 of the U-phase inverter circuit 210 includes multiple switching elements 60U of the first semiconductor device 10A. The switching element 212 of the U-phase inverter circuit 210 includes multiple switching elements 60L of the first semiconductor device 10A. The switching element 221 of the V-phase inverter circuit 220 includes multiple switching elements 60U of the second semiconductor device 10B. The switching element 222 of the V-phase inverter circuit 220 includes multiple switching elements 60L of the second semiconductor device 10B. The switching element 231 of the W-phase inverter circuit 230 includes multiple switching elements 60U of the third semiconductor device 10C. The switching element 232 of the W-phase inverter circuit 230 includes multiple switching elements 60L of the third semiconductor device 10C.

In the inverter device 200, a DC power supply 240 is electrically connected between the first power terminal 11 and the second power terminal 12 of each of the first semiconductor device 10A, the second semiconductor device 10B, and the third semiconductor device 10C. The three-phase drive motor 250 is electrically connected to the output terminals 13 of the first to third semiconductor devices 10A to 10C. The second power terminal 12 has a reference potential, and, for example, a direct current voltage of 500 V or greater and 2000 V or less is applied between the first power terminal 11 and the second power terminal 12.

In the inverter device 200, activation and deactivation of the switching elements 60U and 60L of the first to third semiconductor devices 10A to 10C are controlled based on a predetermined power supply method. The power supply method includes, for example, sine wave driving and square wave driving. The use of sine wave driving improves the motor efficiency of the three-phase drive motor 250. The use of square wave driving reduces the switching loss of the first to third semiconductor devices 10A to 10C.

### MODIFIED EXAMPLES

The above embodiments may be modified as described below. The embodiments described above and the modified examples described below can be combined as long as the combined modifications remain technically consistent with each other.

In the first embodiment, the shapes of the distal parts 41A to 44A of the first to fourth interconnect portions 41 to 44 may be changed in any manner. In an example, the distal part 41A of the first interconnect portion 41 may extend toward the second switching element 62A in the X-direction. In an example, the distal part 42A of the second interconnect portion 42 may extend toward the first switching element 61A in the X-direction. In an example, the distal part 43A of the third interconnect portion 43 may extend toward the fourth switching element 64A in the X-direction. In an example, the distal part 44A of the fourth interconnect portion 44 may extend toward the third switching element 63A in the X-direction.

In the first embodiment, the positional relationship of the first gate electrode G1 of the first switching element 61A and the first interconnect portion 41 of the first gate interconnect 40 in the Y-direction may be changed in any manner. In an example, the first gate electrode G1 may be located closer to the joint portion 45 than the distal part 41A of the first interconnect portion 41 in the Y-direction. In an example, the first gate electrode G1 may be arranged toward the distal part 41A with respect to the center, in the Y-direction, of the first interconnect portion 41. In the same manner, the positional relationship of the second gate electrode G2 of the second switching element 62A and the second interconnect portion 42 of the first gate interconnect 40 in the Y-direction, the positional relationship of the third gate electrode G3 of the third switching element 63A and the third interconnect portion 43 of the first gate interconnect 40 in the Y-direction, and the positional relationship of the fourth gate electrode G4 of the fourth switching element 64A and the fourth interconnect portion 44 of the first gate interconnect 40 in the Y-direction may be changed. In an example, the second gate electrode G2 may be arranged toward the distal part 42A with respect to the center, in the Y-direction, of the second interconnect portion 42. In an example, the third gate electrode G3 may be arranged toward the distal part 43A with respect to the center, in the Y-direction, of the third interconnect portion 43. In an example, the fourth gate electrode G4 may be arranged toward the distal part 44A with respect to the center, in the Y-direction, of the fourth interconnect portion 44.

In the third embodiment, the connection of the first gate electrodes G1 of the first switching elements 61A to the first interconnect portion 41, the connection of the second gate electrodes G2 of the second switching elements 62A to the second interconnect portion 42, the connection of the third gate electrodes G3 of the third switching elements 63A to the third interconnect portion 43, and the connection of the fourth gate electrodes G4 of the fourth switching elements 64A to the fourth interconnect portion 44 may be changed in any manner.

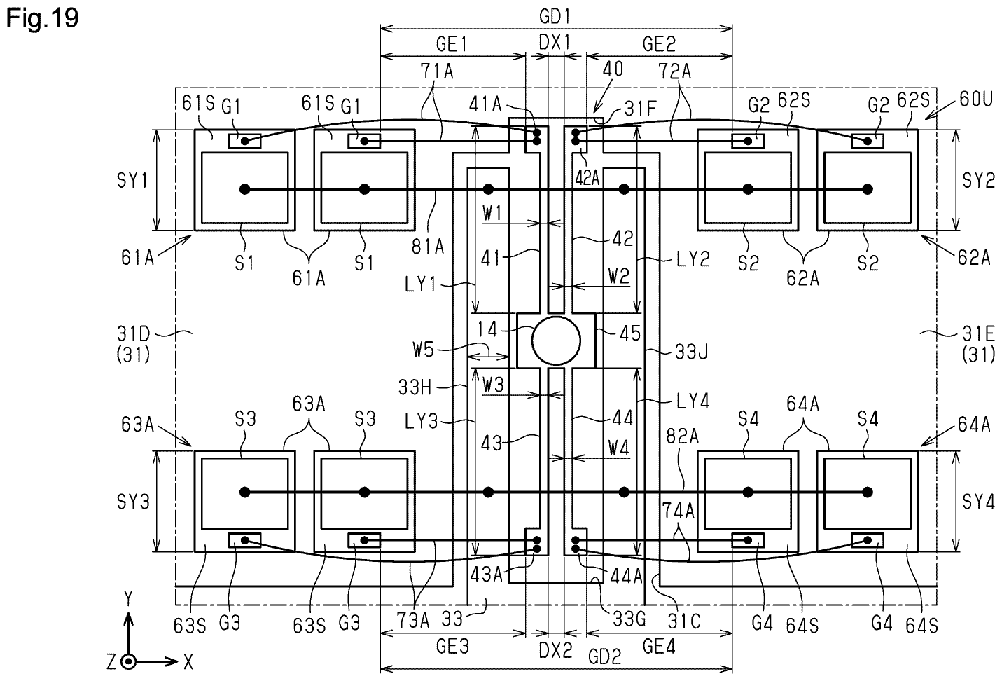

In an example, as shown in FIG. 19, the semiconductor device 10 may include multiple first gate connection members 71A corresponding to the first switching elements 61A, multiple second gate connection members 72A corresponding to the second switching elements 62A, multiple third gate connection members 73A corresponding to the third switching elements 63A, and multiple fourth gate connection members 74A corresponding to the fourth switching elements 64A. In the example shown in FIG. 19, the first gate connection members 71A are individually connected to the first gate electrodes G1. Each of the first gate connection members 71A is connected to the distal part 41A of the first interconnect portion 41. The second gate connection members 72A are individually connected to the second gate electrodes G2. The second gate connection members 72A are connected to the distal part 42A of the second interconnect portion 42. The third gate connection members 73A are individually connected to the third gate electrodes G3. The third gate connection members 73A are connected to the distal part 43A of the third interconnect portion 43. The fourth gate connection members 74A are individually connected to the fourth gate electrodes G4. The fourth gate connection members 74A are connected to the distal part 44A of the fourth interconnect portion 44. When connected in such a manner, the first gate connection members 71A each have a different length. The second gate connection members 72A each have a different length. The third gate connection members 73A each have a different length. The fourth gate connection members 74A each have a different length.

Although not shown in the drawings, the semiconductor device 10 may further include multiple first gate connection members 71B corresponding to the first switching elements 61B, multiple second gate connection members 72B corresponding to the second switching elements 62B, multiple third gate connection members 73B corresponding to the third switching elements 63B, and multiple fourth gate connection members 74B corresponding to the fourth switching elements 64B. The connection manner may be the same as, for example, shown in FIG. 19.

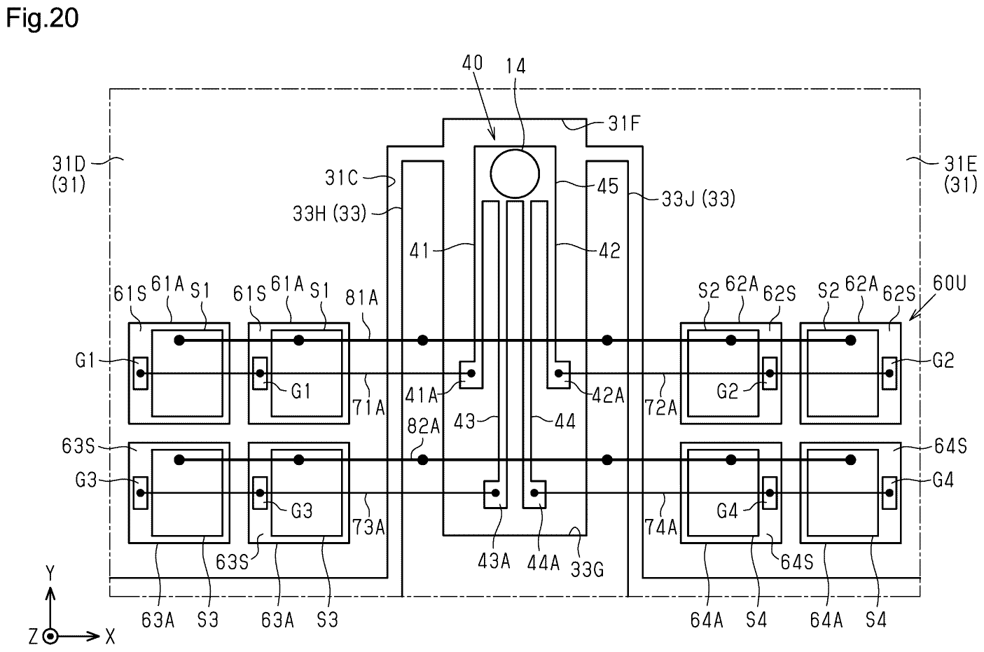

In each embodiment, the structures of the first gate interconnect 40 and the second gate interconnect 50 may be changed in any manner. For example, as shown in FIG. 20, the first to fourth interconnect portions 41 to 44 of the first gate interconnect 40 may extend from the joint portion 45 toward the fourth substrate side surface 26 (refer to FIG. 2) in the Y-direction. The first to fourth interconnect portions 41 to 44 are spaced apart from each other in the X-direction. The third interconnect portion 43 and the fourth interconnect portion 44 are located between the first interconnect portion 41 and the second interconnect portion 42. The first interconnect portion 41 is located toward the first switching elements 61A. The second interconnect portion 42 is located toward the second switching elements 62A. The third interconnect portion 43 is located adjacent to the first interconnect portion 41 in the X-direction. The fourth interconnect portion 44 is located adjacent to the second interconnect portion 42 in the X-direction. The third interconnect portion 43 and the fourth interconnect portion 44 are longer in the Y-direction than the first interconnect portion 41 and the second interconnect portion 42. Thus, the distal part 43A of the third interconnect portion 43 and the distal part 44A of the fourth interconnect portion 44 are located closer to the bottom surface of the recess 33G in the third power interconnect 33 than the distal part 41A of the first interconnect portion 41 and the distal part 42A of the second interconnect portion 42 are. The bottom surface of the recess 33G is the bottom surface when viewed from the opening of the recess 33G and includes a side surface of the element connector 33C of the third power interconnect 33 defining the recess 33G.

The first switching elements 61A are located at the same position in the Y-direction and spaced apart from each other in the X-direction. The third switching elements 63A are located at the same position in the Y-direction and spaced apart from each other in the X-direction. The third switching elements 63A are located closer to the fourth substrate side surface 26 than the first switching elements 61A are and adjacent to the first switching elements 61A in the Y-direction.

The first switching elements 61A are arranged so that the first gate electrodes G1 are separated away from the first interconnect portion 41 in the X-direction. The third switching elements 63A are arranged so that the third gate electrodes G3 are separated away from the third interconnect portion 43 in the X-direction. As described above, the first switching elements 61A and the third switching elements 63A are arranged in the same direction.

The second switching elements 62A are arranged so that the second gate electrodes G2 are separated away from the second interconnect portion 42 in the X-direction. The fourth switching elements 64A are arranged so that the fourth gate electrodes G4 are separated away from the fourth interconnect portion 44 in the X-direction. As described above, the second switching elements 62A and the fourth switching elements 64A are arranged in the same direction. Further, the second switching elements 62A and the fourth switching elements 64A are arranged at a side opposite to the first switching elements 61A and the third switching elements 63A in the X-direction.

The first gate connection member 71A connects the first gate electrodes G1 of the first switching elements 61A to the distal part 41A of the first interconnect portion 41. The second gate connection member 72A connects the second gate electrodes G2 of the second switching elements 62A to the distal part 42A of the second interconnect portion 42. The third gate connection member 73A connects the third gate electrodes G3 of the third switching elements 63A to the distal part 43A of the third interconnect portion 43. The fourth gate connection member 74A connects the fourth gate electrodes G4 of the fourth switching elements 64A to the distal part 44A of the fourth interconnect portion 44.

The joint portion 45 is located at a position differing from the first to fourth switching elements 61A to 64A in the Y-direction. In the example shown in FIG. 20, the joint portion 45 is located closer to the recess 31F than the first to fourth switching elements 61A to 64A are. The separation of the joint portion 45 from the first to fourth switching elements 61A to 64A in the Y-direction allows for extension of the first to fourth interconnect portions 41 to 44 in the Y-direction.

This structure increases the distance between the first gate electrode G1 and the first interconnect portion 41 in the X-direction and the distance between the second gate electrode G2 and the second interconnect portion 42 in the X-direction, thereby increasing the length of the current path between the first gate electrode G1 and the second gate electrode G2. In addition, the structure increases the distance between the third gate electrode G3 and the third interconnect portion 43 in the X-direction and the distance between the fourth gate electrode G4 and the fourth interconnect portion 44 in the X-direction, thereby extending the current path between the third gate electrode G3 and the fourth gate electrode G4. As a result, the gate stray inductance is increased, and occurrence of the oscillations is limited.

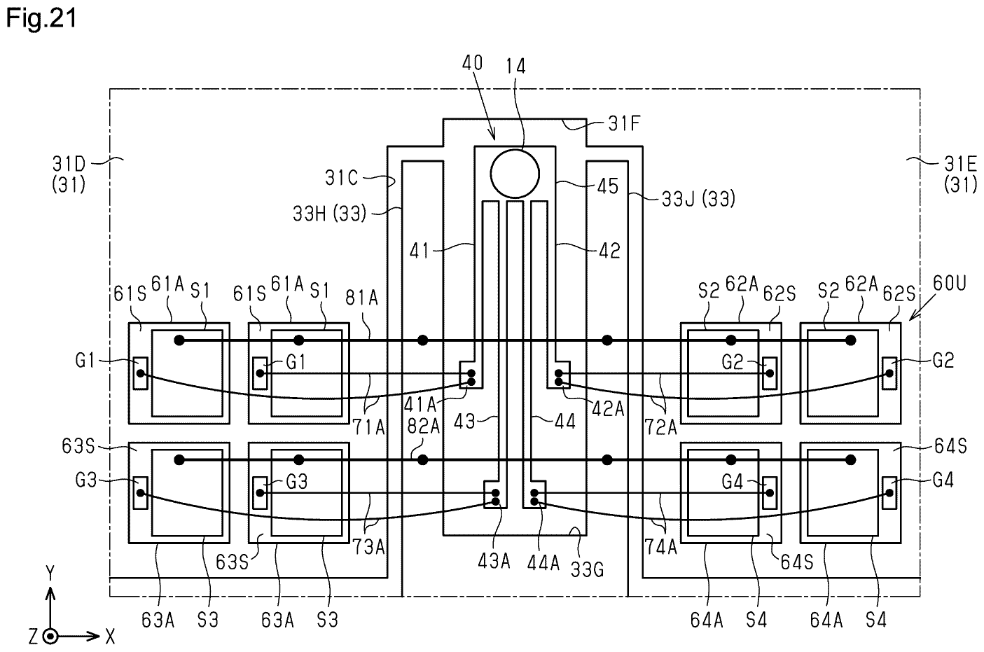

The connection of the first gate electrodes G1 and the first interconnect portion 41, the connection of the second gate electrodes G2 and the second interconnect portions 42, the connection of the third gate electrodes G3 to the third interconnect portion 43, and the connection of the fourth gate electrodes G4 to the fourth interconnect portion 44 may be changed in any manner. FIG. 21 shows a modified example of the connections. As shown in FIG. 21, the semiconductor device 10 may include multiple first gate connection members 71A corresponding to the first switching elements 61A, multiple second gate connection members 72A corresponding to the second switching elements 62A, multiple third gate connection members 73A corresponding to the third switching elements 63A, and multiple fourth gate connection members 74A corresponding to the fourth switching elements 64A. In the example shown in FIG. 21, the first gate connection members 71A are individually connected to the first gate electrodes G1. The first gate connection members 71A are connected to the distal part 41A of the first interconnect portion 41. The second gate connection members 72A are individually connected to the second gate electrodes G2. The second gate connection members 72A are connected to the distal part 42A of the second interconnect portion 42. The third gate connection members 73A are individually connected to the third gate electrodes G3. The third gate connection members 73A are connected to the distal part 43A of the third interconnect portion 43. The fourth gate connection members 74A are individually connected to the fourth gate electrodes G4. The fourth gate connection members 74A are connected to the distal part 44A of the fourth interconnect portion 44. When connected in such a manner, the first gate connection members 71A each have a different length. The second gate connection members 72A each have a different length. The third gate connection members 73A each have a different length. The fourth gate connection members 74A each have a different length.

The modified examples shown in FIGS. 20 and 21 may be applied to, for example, the switching elements 60L and the second gate interconnect 50. Thus, occurrence of the oscillations is also limited in the switching elements 60L and the second gate interconnect 50.

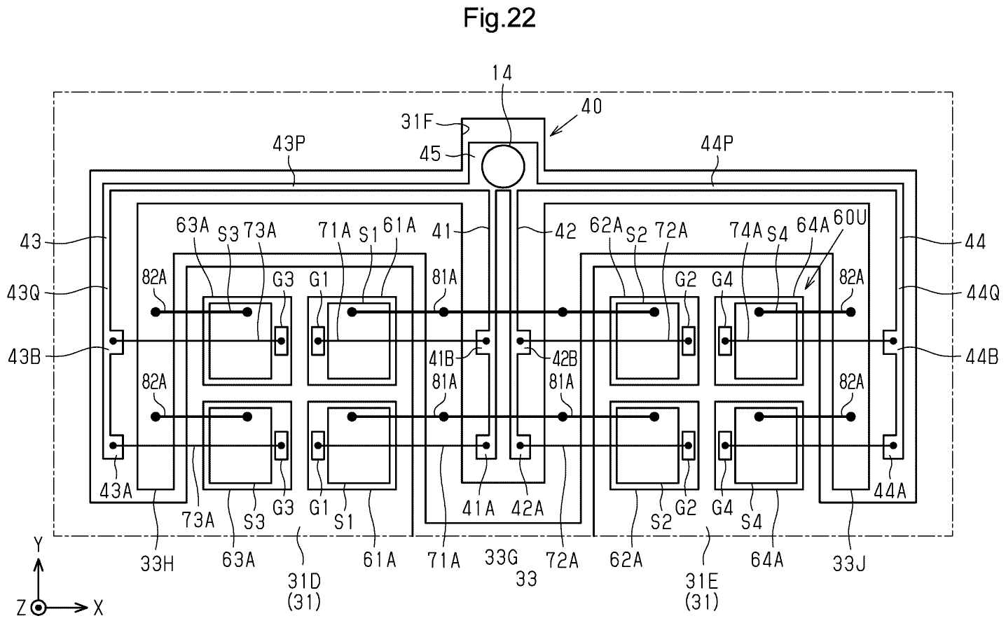

In an example, as shown in FIG. 22, the first gate interconnect 40 may include a structure surrounding the first switching elements 61A and the third switching elements 63A and a structure surrounding the second switching elements 62A and the fourth switching elements 64A. More specifically, the first interconnect portion 41 and the second interconnect portion 42 extend from the joint portion 45 toward the bottom surface of the recess 33G of the third power interconnect 33 in the Y-direction. The first interconnect portion 41 and the second interconnect portion 42 are spaced apart from each other in the X-direction. The first interconnect portion 41 includes a connector 41B arranged between the joint portion 45 and the distal part 41A in the Y-direction. In the example shown in FIG. 22, the connector 41B is located, in the Y-direction, closer to the distal part 41A than the joint portion 45 is. The second interconnect portion 42 includes a connector 42B arranged between the joint portion 45 and the distal part 42A in the Y-direction. In the example shown in FIG. 22, the connector 42B is located, in the Y-direction, closer to the distal part 42A than the joint portion 45 is. In an example, the connector 42B and the connector 41B of the first interconnect portion 41 are located at the same position in the Y-direction.

The first switching elements 61A are located at the same position in the X-direction and spaced apart from each other in the Y-direction. The first switching element 61A and the second interconnect portion 42 are located at opposite sides of the first interconnect portion 41 in the X-direction. The first switching element 61A is arranged so that the first gate electrode G1 and the first interconnect portion 41 are located at opposite sides in the X-direction. One of the first switching elements 61A is arranged so that the first gate electrode G1 and the distal part 41A of the first interconnect portion 41 are located at the same position in the Y-direction. The first gate electrode G1 of the one of the first switching elements 61A and the distal part 41A of the first interconnect portion 41 are electrically connected by one first gate connection member 71A. A further one of the first switching elements 61A is arranged so that the first gate electrode G1 and the connector 41B of the first interconnect portion 41 are located at the same position in the Y-direction. The first gate electrode G1 of the further one of the first switching elements 61A and the connector 41B of the first interconnect portion 41 are electrically connected by another first gate connection member 71A.

The second switching elements 62A are located at the same position in the X-direction and spaced apart from each other in the Y-direction. The second switching elements 62A and the first interconnect portion 41 are located at opposite sides of the second interconnect portion 42 in the X-direction. In an example, the second switching elements 62A and the first switching elements 61A are located at the same position in the Y-direction. The second switching elements 62A are arranged so that the second gate electrodes G2 and the second interconnect portion 42 are located at opposite sides in the X-direction. One of the second switching elements 62A is arranged so that the second gate electrode G2 and the distal part 42A of the second interconnect portion 42 are located at the same position in the Y-direction. The second gate electrode G2 of the one of the second switching elements 62A and the distal part 42A of the second interconnect portion 42 are electrically connected by one second gate connection member 72A. A further one of another one of the second switching elements 62A is arranged so that the second gate electrode G2 and the connector 42B of the second interconnect portion 42 are located at the same position in the Y-direction. The second gate electrode G2 of the further one of the second switching elements 62A and the connector 42B of the second interconnect portion 42 are electrically connected by another second gate connection members 72A.

The third switching elements 63A are located at the same position in the X-direction and spaced apart from each other in the Y-direction. The third switching elements 63A and the first switching elements 61A are located at the same position in the Y-direction. The fourth switching elements 63A are located at a side of the first switching elements 61A opposite to the first interconnect portion 41 and adjacent to the first switching elements 61A in the X-direction.

The fourth switching elements 64A are located at the same position in the X-direction and spaced apart from each other in the Y-direction. The fourth switching elements 64A and the second switching elements 62A are located at the same position in the Y-direction. The fourth switching elements 64A are located at a side of the second switching elements 62A opposite to the second interconnect portion 42 and adjacent to the second switching elements 62A in the X-direction.

The third interconnect portion 43 extends from the third substrate side surface 25 and the first substrate side surface 23 so as to surround the first switching elements 61A and the third switching elements 63A. The third interconnect portion 43 includes a joint portion 43P extending from the joint portion 45 toward the first substrate side surface 23 in the X-direction and a first gate connector 43Q extending from the joint portion 43P toward the fourth substrate side surface 26 in the Y-direction.

The joint portion 43P is located closer to the third substrate side surface 25 than the first switching elements 61A and the third switching elements 63A. The first gate connector 43Q and the first interconnect portion 41 are located at opposite sides of the first switching elements 61A and the third switching elements 63A in the X-direction. The first gate connector 43Q includes a distal part 43A and a connector 43B. The distal part 43A defines an end of the first gate connector 43Q located toward the fourth substrate side surface 26. The connector 43B is arranged on the first gate connector 43Q at a position closer to the distal part 43A than the joint portion 43P is.

The third switching elements 63A are arranged so that the third gate electrodes G3 and the first gate connector 43Q are located at opposite sides in the X-direction. One of the third switching elements 63A is arranged so that the third gate electrode G3 and the distal part 43A of the first gate connector 43Q are located at the same position in the Y-direction. The third gate electrode G3 of the one of the third switching elements 63A and the distal part 43A of the first gate connector 43Q are electrically connected by one third gate connection member 73A. A further one of the third switching elements 63A is arranged so that the third gate electrode G3 and the connector 43B of the first gate connector 43Q are located at the same position in the Y-direction. The third gate electrode G3 of the further one of the third switching elements 63A and the connector 43B of the first gate connector 43Q are electrically connected by another third gate connection member 73A.

The fourth interconnect portion 44 extends from the third substrate side surface 25 and the second substrate side surface 24 so as to surround the second switching elements 62A and the fourth switching elements 64A. The fourth interconnect portion 44 includes a joint portion 44P extending from the joint portion 45 toward the second substrate side surface 24 in the X-direction and a second gate connector 44Q extending from the joint portion 44P toward the fourth substrate side surface 26 in the Y-direction.

The joint portion 44P is located closer to the third substrate side surface 25 than the second switching elements 62A and the fourth switching elements 64A. The second gate connector 44Q and the second interconnect portion 42 are located at opposite sides of the second switching elements 62A and the fourth switching elements 64A in the X-direction. The second gate connector 44Q includes a distal part 44A and a connector 44B. The distal part 44A defines an end of the second gate connector 44Q located toward the fourth substrate side surface 26. The connector 44B is arranged on the second gate connector 44Q at a position closer to the distal part 44A than the joint portion 44P is.

The fourth switching elements 64A are arranged so that the fourth gate electrode G4 and the second gate connector 44Q are located at opposite sides in the X-direction. One of the fourth switching elements 64A is arranged so that the fourth gate electrode G4 and the distal part 44A of the second gate connector 44Q are located at the same position in the Y-direction. The fourth gate electrode G4 of the one of the fourth switching elements 64A and the distal part 44A of the second gate connector 44Q are electrically connected by one fourth gate connection member 74A. A further one of the fourth switching elements 64A is arranged so that the fourth gate electrode G4 and the connector 44B of the second gate connector 44Q are located at the same position in the Y-direction. The fourth gate electrode G4 of the further one of the fourth switching elements 64A and the connector 44B of the second gate connector 44Q are electrically connected by another third gate connection member 73A.

The joint portion 45 is located at a position differing from the first to fourth switching elements 61A to 64A in the Y-direction. In the example shown in FIG. 22, the joint portion 45 is located closer to the recess 31F than the first to fourth switching elements 61A to 64A are. The separation of the joint portion 45 from the first to fourth switching elements 61A to 64A in the Y-direction allows for extension of the length of the first interconnect portion 41 in the Y-direction, the length of the second interconnect portion 42 in the Y-direction, the length of the first gate connector 43Q of the third interconnect portion 43 in the Y-direction, and the length of the second gate connector 44Q of the fourth interconnect portion 44 in the Y-direction. The switching elements 60L and the second gate interconnect 50 may also be changed in the same manner.

In each embodiment, the connection position of the first gate connection member 71A with the first interconnect portion 41 of the first gate interconnect 40 may be changed in any manner. The first gate connection member 71A may be connected to a part of the first interconnect portion 41 located closer to the joint portion 45 than the distal part 41A is. The connection positions of the second gate connection members 72A to 74A with the second to fourth interconnect portions 42 to 44 may be changed in any manner. The connection positions of the first to fourth gate connection members 71B to 74B with the first to fourth interconnect portions 51 to 54 of the second gate interconnect 50 may be changed in any manner.

In the first gate interconnect 40 of each embodiment, the positional relationship of the first interconnect portion 41 and the third interconnect portion 43 in the X-direction may be changed in any manner. In an example, the third interconnect portion 43 and the first interconnect portion 41 may be located at different positions in the X-direction. The positional relationship of the second interconnect portion 42 and the fourth interconnect portion 44 in the X-direction may be changed in any manner. In an example, the fourth interconnect portion 44 and the second interconnect portion 42 may be located at different positions in the X-direction. The first to fourth interconnect portions 51 to 54 of the second gate interconnect 50 may be changed in the same manner.

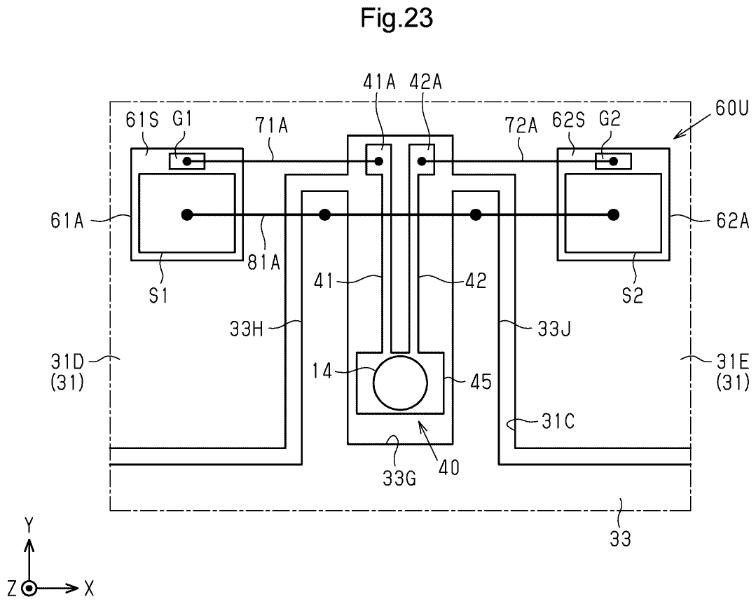

In each embodiment, the third interconnect portion 43 and the fourth interconnect portion 44 may be omitted from the first gate interconnect 40. In this case, the third switching element 63A and the fourth switching element 64A may be omitted from the switching elements 60U. FIG. 23 shows a planar structure of a part of the semiconductor device 10 from which the third interconnect portion 43, the fourth interconnect portion 44, the third switching element 63A, and the fourth switching element 64A are omitted.

As shown in FIG. 23, the first gate interconnect 40 includes the joint portion 45, the first interconnect portion 41, and the second interconnect portion 42. The first interconnect portion 41 and the second interconnect portion 42 extend from the joint portion 45 in the Y-direction. The first interconnect portion 41 and the second interconnect portion 42 are located at the same position in the Y-direction and spaced apart from each other in the X-direction. The first switching element 61A and the second interconnect portion 42 are located at opposite sides of the first interconnect portion 41 in the X-direction. The second switching element 62A and the first interconnect portion 41 are located at opposite sides of the second interconnect portion 42 in the X-direction. In other words, the second interconnect portion 42 is arranged toward the second switching element 62A with respect to the first interconnect portion 41 in the X-direction. The first gate connection member 71A is connected to the distal part 41A of the first interconnect portion 41. The second gate connection member 72A is connected to the distal part 42A of the second interconnect portion 42. This structure obtains the same advantages as the first embodiment. The second gate interconnect 50 may be changed in the same manner.

In each embodiment, the first to fourth gate connection members 71A to 74A and 71B to 74B are not limited to bonding wires and may be changed in any manner. In an example, the first to fourth gate connection members 71A to 74A and 71B to 74B may be formed of the combination of vias and wiring layers.

In each embodiment, the first source connection members 81A and 81B and the second source connection members 82A and 82B are not limited to bonding wires and may be changed in any manner. In an example, the first source connection members 81A and 81B and the second source connection members 82A and 82B may be formed of clips.

In each embodiment, the positional relationship of the first interconnect portion 41 and the third interconnect portion 43 in the X-direction and the positional relationship of the second interconnect portion 42 and the fourth interconnect portion 44 in the X-direction may be changed in any manner. In an example, the first interconnect portion 41 may be displaced from the third interconnect portion 43 in the X-direction. In an example, the second interconnect portion 42 may be displaced from the fourth interconnect portion 44 in the X-direction.

In each embodiment, the positional relationship of the first gate electrode G1 of the first switching element 61A and the first interconnect portion 41 in the Y-direction may be changed in any manner. In an example, the first gate electrode G1 may be arranged between the center and the distal part 41A of the first interconnect portion 41 in the Y-direction. The positional relationship of the second gate electrode G2 of the second switching element 62A and the second interconnect portion 42 in the Y-direction, the positional relationship of the third gate electrode G3 of the third switching element 63A and the third interconnect portion 43 in the Y-direction, and the positional relationship of the fourth gate electrode G4 of the fourth switching element 64A and the fourth interconnect portion 44 in the Y-direction may be changed in the same manner. The positional relationship of the first to fourth gate electrodes G1 to G4 of the first to fourth switching elements 61B to 64B and the first to fourth interconnect portions 51 to 54 of the second gate interconnect 50 may be changed in the same manner.

In each embodiment, the relationship of the widths of the distal parts 41A to 44A of the first to fourth interconnect portions 41 to 44 of the first gate interconnect 40 and the widths W1 to W4 of the parts of the first to fourth interconnect portions 41 to 44 differing from the distal parts 41A to 44A may be changed in any manner. In an example, the widths of the distal parts 41A to 44A of the first to fourth interconnect portions 41 to 44 of the first gate interconnect 40 may be equal to the widths W1 to W4 of the parts of the first to fourth interconnect portions 41 to 44 differing from the distal parts 41A to 44A.

In each embodiment, the direction in which the first to fourth interconnect portions 41 to 44 of the first gate interconnect 40 extend in plan view is not limited to the direction (Y-direction) orthogonal to the X-direction. The direction in which the first to fourth interconnect portions 41 to 44 extend in plan view may be any direction that intersects the X-direction. Also, the direction in which the first to fourth interconnect portions 51 to 54 of the second gate interconnect 50 extend may be any direction that intersects the X-direction in plan view.

One or more of the various examples described in the present disclosure may be combined within a range where there is no technical contradiction.

In the present disclosure, the term “on” includes the meaning of “above” in addition to the meaning of “on” unless otherwise clearly indicated in the context. Accordingly, for example, the expression of “first element arranged on second element” may mean that the first element is arranged directly on the second element in one embodiment and mean that the first element is arranged above the second element without contacting the second element in another embodiment. In other words, the term “on” does not exclude a structure in which another component is formed between the first component and the second component.

The Z-direction as referred to in the present disclosure does not necessarily have to be the vertical direction and does not necessarily have to exactly coincide with the vertical direction. In the structures according to the present disclosure, “upward” and “downward” in the Z-direction as referred to in the present disclosure are not limited to “upward” and “downward” in the vertical direction. For example, the X-direction may be the vertical direction. Alternatively, the Y-direction may be the vertical direction.

### CLAUSES

Technical concepts that can be understood from the present disclosure will now be described. Reference characters used in the above embodiments are added to corresponding elements in the clauses to aid understanding without any intention to impose limitations to these elements. The reference signs are used as examples to facilitate understanding, and the elements in each clause are not limited to those elements given with the reference signs.

[Clause 1] A semiconductor device (10), including:
a first switching element (61A) including a first gate electrode (G1);
a second switching element (62A) including a second gate electrode (G2), the second switching element (62A) spaced apart from the first switching element (61A) in a first direction (X) and connected in parallel to the first switching element (61A);
a gate interconnect (40) arranged between the first switching element (61A) and the second switching element (62A) in the first direction (X);
a first gate connection member (71A) connecting the first gate electrode (G1) and the gate interconnect (40); and
a second gate connection member (72A) connecting the second gate electrode (G2) and the gate interconnect (40), where
the gate interconnect (40) includes
   a first interconnect portion (41) extending in a second direction (Y) that intersects the first direction (X) in a plan view as viewed in a thickness-wise direction (Z) of the first switching element (61A),
   a second interconnect portion (42) spaced apart from the first interconnect portion (41) toward the second switching element (62A) in the first direction (X) and extending in the second direction (Y) in the plan view, and
   a joint portion (45) joining the first interconnect portion (41) and the second interconnect portion (42),
the first gate connection member (71A) is connected to a part of the first interconnect portion (41) distant from the joint portion (45) in the second direction (Y), and
the second gate connection member (72A) is connected to a part of the second interconnect portion (42) distant from the joint portion (45) in the second direction (Y).

[Clause 2] The semiconductor device according to clause 1, where
the first interconnect portion (41) includes a distal part (41A) distant from the joint portion (45) in the second direction (Y),
the first gate connection member (71A) is connected to the distal part (41A) of the first interconnect portion (41),
the second interconnect portion (42) includes a distal part (42A) distant from the joint portion (45) in the second direction (Y), and
the second gate connection member (72A) is connected to the distal part (42A) of the second interconnect portion (42).

[Clause 3] The semiconductor device according to clause 1 or 2, where a length (LY1) of the first interconnect portion (41) in the second direction (Y) and a length (LY2) of the second interconnect portion (42) in the second direction (Y) are each greater than a distance (DX1) between the first interconnect portion (41) and the second interconnect portion (42) in the first direction (X).

[Clause 4] The semiconductor device according to any one of clauses 1 to 3, where
a length (LY1) of the first interconnect portion (41) in the second direction (Y) is greater than a length (SY1) of the first switching element (61A) in the second direction (Y), and
a length (LY2) of the second interconnect portion (42) in the second direction (Y) is greater than a length (SY2) of the second switching element (62A) in the second direction (Y).

[Clause 5] The semiconductor device according to any one of clauses 1 to 4, where a sum of a length (LY1) of the first interconnect portion (41) in the second direction (Y), a length of the first gate connection member (71A) in the plan view, a length (LY2) of the second interconnect portion (42) in the second direction (Y), and a length of the second gate connection member (72A) in the plan view is greater than a first inter-gate distance (GD1) that is a distance between the first gate electrode (G1) and the second gate electrode (G2) in the plan view.

[Clause 6] The semiconductor device according to any one of clauses 1 to 5, where
the first interconnect portion (41) includes a distal part (41A) distant from the joint portion (45) in the second direction (Y), the first gate electrode (G1) is arranged toward the distal part (41A) of the first interconnect portion (41) with respect to a center, in the second direction (Y), of the first interconnect portion (41), and
the second interconnect portion (42) includes a distal part (42A) distant from the joint portion (45) in the second direction (Y), the second gate electrode (G2) is arranged toward the distal part (42A) of the second interconnect portion (42) with respect to a center, in the second direction (Y), of the second interconnect portion (42).

[Clause 7] The semiconductor device according to any one of clauses 1 to 6, where a length (LY1) of the first interconnect portion (41) in the second direction (Y) is equal to a length (LY2) of the second interconnect portion (42) in the second direction (Y).

[Clause 8] The semiconductor device according to clause 7, further including:
a gate terminal (14) electrically connected to the joint portion (45),
where the first interconnect portion (41) and the second interconnect portion (42) each extend from the joint portion (45) in the second direction (Y).

[Clause 9] The semiconductor device according to any one of clauses 1 to 8, further including:
a third switching element (63A) including a third gate electrode (G3) and located at a position spaced apart from the first switching element (61A) in the second direction (Y) and toward the first switching element (61A) in the first direction (X) with respect to the gate interconnect (40), the third switching element (63A) being connected in parallel to the first switching element (61A) and the second switching element (62A);
a fourth switching element (64A) including a fourth gate electrode (G4) and located at a position spaced apart from the second switching element (62A) in the second direction (Y) and toward the second switching element (62A) in the first direction (X) with respect to the gate interconnect (40), the fourth switching element (64A) being connected in parallel to the first switching element (61A), the second switching element (62A), and the third switching element (63A);
a third gate connection member (73A) connecting the third gate electrode (G3) and the gate interconnect (40); and
a fourth gate connection member (74A) connecting the fourth gate electrode (G4) and the gate interconnect (40), where
the gate interconnect (40) includes
   a third interconnect portion (43) spaced apart from the first interconnect portion (41) in the second direction (Y) and extending in the second direction (Y), and
   a fourth interconnect portion (44) spaced apart from the second interconnect portion (42) in the second direction (Y) and extending in the second direction (Y),
the joint portion (45) is located between the first interconnect portion (41) and the third interconnect portion (43) in the second direction (Y) and between the second interconnect portion (42) and the fourth interconnect portion (44) in the second direction (Y) and connects the first interconnect portion (41), the second interconnect portion (42), the third interconnect portion (43), and the fourth interconnect portion (44),
the third gate connection member (73A) is connected to a part of the third interconnect portion (43) distant from the joint portion (45) in the second direction (Y), and
the fourth gate connection member (74A) is connected to a part of the fourth interconnect portion (44) distant from the joint portion (45) in the second direction (Y).

[Clause 10] The semiconductor device according to clause 9, where
the third interconnect portion (43) includes a distal part (43A) distant from the joint portion (45) in the second direction (Y), the third gate connection member (73A) is connected to the distal part (43A) of the third interconnect portion (43), and
the fourth interconnect portion (44) includes a distal part (44A) distant from the joint portion (45) in the second direction (Y), the fourth gate connection member (74A) is connected to the distal part (44A) of the fourth interconnect portion (44).

[Clause 11] The semiconductor device according to clause 9 or 10, where a length (LY3) of the third interconnect portion (43) in the second direction (Y) and a length (LY4) of the fourth interconnect portion (44) in the second direction (Y) are each greater than a distance (DX2) between the third interconnect portion (43) and the fourth interconnect portion (44) in the first direction (X).

[Clause 12] The semiconductor device according to any one of clauses 9 to 11, where
a length (LY3) of the third interconnect portion (43) in the second direction (Y) is greater than a length (SY3) of the third switching element (63A) in the second direction (Y), and
a length (LY4) of the fourth interconnect portion (44) in the second direction (Y) is greater than a length (SY4) of the fourth switching element (64A) in the second direction (Y).

[Clause 13] The semiconductor device according to any one of clauses 9 to 12, where
the third interconnect portion (43) includes a distal part (43A) distant from the joint portion (45) in the second direction (Y), the third gate electrode (G3) is arranged toward the distal part (43A) of the third interconnect portion (43) with respect to a center, in the second direction (Y), of the third interconnect portion (43), and
the fourth interconnect portion (44) includes a distal part (44A) distant from the joint portion (45) in the second direction (Y), the fourth gate electrode (G4) is arranged toward the distal part (44A) of the fourth interconnect portion (44) with respect to a center, in the second direction (Y), of the fourth interconnect portion (44).

[Clause 14] The semiconductor device according to any one of clauses 9 to 13, where a sum of a length (LY3) of the third interconnect portion (43) in the second direction (Y), a length of the third gate connection member (73A) in the plan view, a length (LY4) of the fourth interconnect portion (44) in the second direction (Y), and a length of the fourth gate connection member (74A) in the plan view is greater than a second inter-gate distance (GD2) that is a distance between the third gate electrode (G3) and the fourth gate electrode (G4) in the plan view.

[Clause 15] The semiconductor device according to clause 14, where the second inter-gate distance (GD2) is equal to a first inter-gate distance (GD1) between the first gate electrode (G1) and the second gate electrode (G2) in the plan view.

[Clause 16] The semiconductor device according to any one of clauses 9 to 15, further including:
a gate terminal (14) electrically connected to the joint portion (45),
where a length (LY3) of the third interconnect portion (43) in the second direction (Y) is equal to a length (LY4) of the fourth interconnect portion (44) in the second direction (Y).

[Clause 17] The semiconductor device according to any one of clauses 9 to 16, further including:
a gate terminal (14) electrically connected to the joint portion (45), where
a length (LY3) of the third interconnect portion (43) in the second direction (Y) is equal to a length (LY1) of the first interconnect portion (41) in the second direction (Y), and
a length (LY4) of the fourth interconnect portion (44) in the second direction (Y) is equal to a length (LY2) of the second interconnect portion (42) in the second direction (Y).

[Clause 18] The semiconductor device according to any one of clauses 1 to 8, further including:
a third switching element (63A) including a third gate electrode (G3) and located at a position spaced apart from the first switching element (61A) in the second direction (Y) and toward the first switching element (61A) in the first direction (X) with respect to the gate interconnect (40), the third switching element (63A) being connected in parallel to the first switching element (61A) and the second switching element (62A);
a fourth switching element (64A) including a fourth gate electrode (G4) and located at a position spaced apart from the second switching element (62A) in the second direction (Y) and toward the second switching element (62A) in the first direction (X) with respect to the gate interconnect (40), the fourth switching element (64A) being connected in parallel to the first switching element (61A), the second switching element (62A), and the third switching element (63A);
a third gate connection member (73A) connecting the third gate electrode (G3) and the gate interconnect (40); and
a fourth gate connection member (74A) connecting the fourth gate electrode (G4) and the gate interconnect (40), where
the gate interconnect (40) includes
   a third interconnect portion (43) spaced apart from the first interconnect portion (41) in the first direction (X) at the same position as the first interconnect portion (41) in the second direction (Y) and extending in the second direction (Y), and
   a fourth interconnect portion (44) spaced apart from the second interconnect portion (42) in the first direction (X) at the same position as the second interconnect portion (42) in the second direction (Y) and extending in the second direction (Y),
the joint portion (45) connects the first interconnect portion (41), the second interconnect portion (42), the third interconnect portion (43), and the fourth interconnect portion (44),
the third gate connection member (73A) is connected to a part of the third interconnect portion (43) distant from the joint portion (45) in the second direction (Y), and
the fourth gate connection member (74A) is connected to a part of the fourth interconnect portion (44) distant from the joint portion (45) in the second direction (Y).

[Clause 19] The semiconductor device according to clause 18, in which
the third interconnect portion (43) and the fourth interconnect portion (44) are arranged between the first interconnect portion (41) and the second interconnect portion (42) in the first direction (X), and
a length (LY3, LY4) of each of the third interconnect portion (43) and the fourth interconnect portion (44) in the second direction (Y) is greater than a length (LY1, LY2) of each of the first interconnect portion (41) and the second interconnect portion (42) in the second direction (Y).

[Clause 20] The semiconductor device according to any one of clauses 1 to 8, further including:
a third switching element (63A) including a third gate electrode (G3) and located at a position spaced apart from the first switching element (61A) in the second direction (Y) and toward the first switching element (61A) in the first direction (X) with respect to the gate interconnect (40), the third switching element (63A) being connected in parallel to the first switching element (61A) and the second switching element (62A);
a fourth switching element (64A) including a fourth gate electrode (G4) and located at a position spaced apart from the second switching element (62A) in the second direction (Y) and toward the second switching element (62A) in the first direction (X) with respect to the gate interconnect (40), the fourth switching element (64A) being connected in parallel to the first switching element (61A), the second switching element (62A), and the third switching element (63A);
a third gate connection member (73A) connecting the third gate electrode (G3) and the gate interconnect (40); and
a fourth gate connection member (74A) connecting the fourth gate electrode (G4) and the gate interconnect (40), where
the gate interconnect (40) includes a third interconnect portion (43) and a fourth interconnect portion (44) that are connected to the joint portion (45),
the third interconnect portion (43) includes a first gate connector (43Q) located opposite from the first interconnect portion (41) with respect to the first switching element (61A) and the third switching element (63A) in the first direction (X),
the fourth interconnect portion (44) includes a second gate connector (44Q) located opposite from the second interconnect portion (42) with respect to the second switching element (62A) and the fourth switching element (64A) in the first direction (X),
the third gate connection member (73A) is connected to the first gate connector (43Q), and
the fourth gate connection member (74A) is connected to the second gate connector (44Q).

[Clause 21] The semiconductor device according to any one of clauses 1 to 8, where
the first switching element (61A) is one of multiple first switching elements (61A),
the second switching element (62A) is one of multiple second switching elements (62A),
the first switching elements (61A) are arranged next to each other in the first direction (X),
the second switching elements (62A) are arranged next to each other in the first direction (X),
the first gate connection member (71A) connects the first gate electrodes (G1) of the first switching elements (61A) and is connected to a part of the first interconnect portion (41) distant from the joint portion (45) in the second direction (Y),
the second gate connection member (72A) connects the second gate electrodes (G2) of the second switching elements (62A) and is connected to a part of the second interconnect portion (42) distant from the joint portion (45) in the second direction (Y).

[Clause 22] The semiconductor device according to any one of clauses 1 to 8, where
the first switching element (61A) is one of multiple first switching elements (61A),
the second switching element (62A) is one of multiple second switching elements (62A),
the first switching elements (61A) are arranged next to each other in the first direction (X),
the second switching elements (62A) are arranged next to each other in the first direction (X),
the first gate connection member (71A) is one of multiple first gate connection members (71A) corresponding to the first switching elements (61A),
the second gate connection member (72A) is one of multiple second gate connection members (72A) corresponding to the second switching elements (62A),
the first gate connection members (71A) are individually connected to the first gate electrodes (G1) of the first switching elements (61A) and are connected to a part of the first interconnect portion (41) distant from the joint portion (45) in the second direction (Y), and
the second gate connection members (72A) are individually connected to the second gate electrodes (G2) of the second switching elements (62A) and are connected to a part of the second interconnect portion (42) distant from the joint portion (45) in the second direction (Y).

[Clause 23] The semiconductor device according to clause 21, further including:
multiple third switching elements (63A) each including a third gate electrode (G3) and located at a position spaced apart from the first switching elements (61A) in the second direction (Y) and toward the first switching elements (61A) in the first direction (X) with respect to the gate interconnect (40), the third switching elements (63A) being connected in parallel to the first switching elements (61A) and the second switching elements (62A); and
multiple fourth switching elements (64A) each including a fourth gate electrode (G4) and located at a position spaced apart from the second switching elements (62A) in the second direction (Y) and toward the second switching elements (62A) in the first direction (X) with respect to the gate interconnect (40), the fourth switching elements (64A) being connected in parallel to the first switching elements (61A), the second switching elements (62A), and the third switching elements (63A), where
the third switching elements (63A) are arranged next to each other in the first direction (X),
the fourth switching elements (64A) are arranged next to each other in the first direction (X),
the gate interconnect (40) includes
   a third interconnect portion (43) spaced apart from the first interconnect portion (41) in the second direction (Y) and extending in the second direction (Y), and
   a fourth interconnect portion (44) spaced apart from the second interconnect portion (42) in the second direction (Y) and extending in the second direction (Y),
the joint portion (45) is located between the first interconnect portion (41) and the third interconnect portion (43) in the second direction (Y) and between the second interconnect portion (42) and the fourth interconnect portion (44) in the second direction (Y) and connects the first interconnect portion (41), the second interconnect portion (42), the third interconnect portion (43), and the fourth interconnect portion (44),
a third gate connection member (73A) connecting the third gate electrodes (G3) of the third switching elements (63A) and being connected to a part of the third interconnect portion (43) distant from the joint portion (45) in the second direction (Y), and
a fourth gate connection member (74A) connecting the fourth gate electrodes (G4) of the fourth switching elements (64A) and being connected to a part of the fourth interconnect portion (44) distant from the joint portion (45) in the second direction (Y).

[Clause 24] The semiconductor device according to clause 22, further including:
multiple third switching elements (63A) each including a third gate electrode (G3) and located at a position spaced apart from the first switching elements (61A) in the second direction (Y) and toward the first switching elements (61A) in the first direction (X) with respect to the gate interconnect (40), the third switching elements (63A) being connected in parallel to the first switching elements (61A) and the second switching elements (62A);
multiple fourth switching elements (64A) each including a fourth gate electrode (G4) and located at a position spaced apart from the second switching elements (62A) in the second direction (Y) and toward the second switching elements (62A) in the first direction (X) with respect to the gate interconnect (40), the fourth switching elements (64A) being connected in parallel to the first switching elements (61A), the second switching elements (62A), and the third switching elements (63A), where
the third switching elements (63A) are arranged next to each other in the first direction (X),
the fourth switching elements (64A) are arranged next to each other in the first direction (X),
the gate interconnect (40) includes
   a third interconnect portion (43) spaced apart from the first interconnect portion (41) in the second direction (Y) and extending in the second direction (Y), and
   a fourth interconnect portion (44) spaced apart from the second interconnect portion (42) in the second direction (Y) and extending in the second direction (Y),
the joint portion (45) is located between the first interconnect portion (41) and the third interconnect portion (43) in the second direction (Y) and between the second interconnect portion (42) and the fourth interconnect portion (44) in the second direction (Y) and connects the first interconnect portion (41), the second interconnect portion (42), the third interconnect portion (43), and the fourth interconnect portion (44),
multiple third gate connection members (73A) individually connecting the third gate electrodes (G3) of the third switching elements (63A) and being connected to a part of the third interconnect portion (43) distant from the joint portion (45) in the second direction (Y), and
multiple fourth gate connection members (74A) individually connecting the fourth gate electrodes (G4) of the fourth switching elements (64A) and being connected to a part of the fourth interconnect portion (44) distant from the joint portion (45) in the second direction (Y).

[Clause 25] The semiconductor device according to any one of clauses 1 to 8, where a width (W1, W2) of each of the first interconnect portion (41) and the second interconnect portion (42) is less than a width of the joint portion (45).

[Clause 26] The semiconductor device according to any one of clauses 9 to 20, where a width (W1, W2, W3, W4) of each of the first interconnect portion (41), the second interconnect portion (42), the third interconnect portion (43) and the fourth interconnect portion (44) is less than a width of the joint portion (45).

[Clause 27] The semiconductor device according to any one of clauses 1 to 8, further including:
an upper-arm switching element (60U) and a lower-arm switching element (60L) connected to each other in series,
an upper-arm power interconnect (31) on which the upper-arm switching element (60U) is mounted,
a lower-arm power interconnect (33) spaced apart from the upper-arm power interconnect (31), the lower-arm switching element (60L) being mounted on the lower-arm power interconnect (33), where
the upper-arm switching element (60U) includes the first switching element (61A) and the second switching element (62A),
the lower-arm switching element (60L) includes a fifth switching element (61B) and a sixth switching element (62B), and
the gate interconnect includes
   a first gate interconnect (40) electrically connected to the first gate electrode (G1) of the first switching element (61A) and the second gate electrode (G2) of the second switching element (62A), and
   a second gate interconnect (50) electrically connected to a fifth gate electrode (G1) of the fifth switching element (61B) and a sixth gate electrode (G2) of the sixth switching element (62B).

[Clause 28] The semiconductor device according to clause 27, where
the upper-arm power interconnect (31) and the lower-arm power interconnect (33) are arranged next to each other in the second direction (Y),
the upper-arm power interconnect (31) includes a first recess (31C) that is open toward the lower-arm power interconnect (33),
the lower-arm power interconnect (33) includes
   an element mount (33B) on which the fifth switching element (61B) and the sixth switching element (62B) are mounted, and
   a connector (33C) extending from the element mount (33B) in the second direction (Y) and being arranged in the first recess (31C),
the connector (33C) includes a second recess (33G) that is open opposite to the first recess (31C) in the second direction (Y),
the first gate interconnect (40) is arranged in an opening defined by the first recess (31C) and the second recess (33G), and
the second gate interconnect (50) is arranged in an opening (33D) of the element mount (33B) located between the fifth switching element (61B) and the sixth switching element (62B) in the first direction (X).

[Clause 29] The semiconductor device according to any one of clauses 1 to 8, further including:
a first power interconnect (31) on which the first switching element (61A) and the second switching element (62A) are mounted; and
a third power interconnect (33) spaced apart from the first power interconnect (31), where
the first switching element (61A) includes a first element surface (61S) on which the first gate electrode (G1) is mounted and a first source electrode (S1) mounted on the first element surface (61S),
the second switching element (62A) includes a second element surface (62S) on which the second gate electrode (G2) is mounted and a second source electrode (S2) mounted on the second element surface (62S),
the third power interconnect (33) is electrically connected to the first source electrode (S1) and the second source electrode (S2), and
a portion of the third power interconnect (33) is arranged between the first power interconnect (31) and the gate interconnect (40) in the first direction (X).

[Clause 30] The semiconductor device according to any one of clauses 9 to 17, where a sum of a length (LY1) of the first interconnect portion (41) in the second direction (Y), a length of the first gate connection member (71A) in the plan view, a length of the joint portion (45) in the second direction (Y), a length (LY3) of the third interconnect portion (43) in the second direction (Y), and a length of the third gate connection member (73A) in the plan view is greater than a third inter-gate distance (GD3) that is a distance between the first gate electrode (G1) and the third gate electrode (G3) in the plan view.

[Clause 31] The semiconductor device according to any one of clauses 9 to 17, where a sum of a length (LY2) of the second interconnect portion (42) in the second direction (Y), a length of the second gate connection member (72A) in the plan view, a length of the joint portion (45) in the second direction (Y), a length (LY4) of the fourth interconnect portion (44) in the second direction (Y), and a length of the fourth gate connection member (74A) in the plan view is greater than a fourth inter-gate distance (GD4) that is a distance between the second gate electrode (G2) and the fourth gate electrode (G4) in the plan view.

[Clause 32] The semiconductor device according to clause 2, where
a width of the distal part (41A) of the first interconnect portion (41) is greater than a width of a part of the first interconnect portion (41) located closer to the joint portion (45) than the distal part (41A), and
a width of the distal part (42A) of the second interconnect portion (42) is greater than a width of a part of the second interconnect portion (42) located closer to the joint portion (45) than the distal part (42A).

[Clause 33] The semiconductor device according to clause 10, where
a width of the distal part (41A) of the first interconnect portion (41) is greater than a width of a part of the first interconnect portion (41) located closer to the joint portion (45) than the distal part (41A), and
a width of the distal part (42A) of the second interconnect portion (42) is greater than a width of a part of the second interconnect portion (42) located closer to the joint portion (45) than the distal part (42A),
a width of the distal part (43A) of the third interconnect portion (43) is greater than a width of a part of the third interconnect portion (43) located closer to the joint portion (45) than the distal part (43A), and
a width of the distal part (44A) of the fourth interconnect portion (44) is greater than a width of a part of the fourth interconnect portion (44) located closer to the joint portion (45) than the distal part (44A).

[Clause 34] The semiconductor device according to any one of clauses 1 to 17, where
the first interconnect portion (41) and the second interconnect portion (42) each include a first side surface (FA1, FB1) and a second side surface (FA2, FB2) extending in the second direction (Y) and a third side surface (FA3, FB3) extending in the first direction (X), and
the joint portion (45) includes a joint side surface (FP1) joining the first interconnect portion (41) and the second interconnect portion (42).

[Clause 35] The semiconductor device according to any one of clauses 9 to 17, where
the first interconnect portion (41), the second interconnect portion (42), the third interconnect portion (43), and the fourth interconnect portion (44) each include a first side surface (FA1, FB1, FC1, FD1) and a second side surface (FA2, FB2, FC2, FD2) extending in the second direction (Y) and a third side surface (FA3, FB3, FC3, FD3) extending in the first direction (X), and
the joint portion (45) includes
   a first joint side surface (FP1) joining the first interconnect portion (41) and the second interconnect portion (42), and
   a second joint side surface (FP2) joining the third interconnect portion (43) and the fourth interconnect portion (44).

[Clause 36] The semiconductor device according to any one of clauses 1 to 8, further including:
a fifth switching element (61B) and a sixth switching element (62B) that are connected in parallel to each other and connected in series to the first switching element (61A) and the second switching element (62A);
a first substrate (160) including a first substrate surface (161) and a second substrate surface (162) opposite to the first substrate surface (161);
a first element mount interconnect (181) arranged on the first substrate surface (161) of the first substrate (160), the first switching element (61A) and the second switching element (62A) being mounted on the first element mount interconnect (181);
a second element mount interconnect (184) arranged on the first substrate surface (161) of the first substrate (160), the fifth switching element (61B) and the sixth switching element (62B) being mounted on the second element mount interconnect (181);
a second substrate (170) including a first substrate surface (171) and a second substrate surface (712) opposite to the first substrate surface (171), the second substrate (170) being opposed to and spaced apart from the first substrate (160) in a thickness-wise direction (Z) of the first substrate (160);
a first power interconnect (191) arranged on the first substrate surface (171) of the second substrate (170) and opposed to the first switching element (61A) and the second switching element (62A) in the thickness-wise direction (Z);
a second power interconnect (192) arranged on the first substrate surface (171) of the second substrate (170) and opposed to the fifth switching element (61B) and the sixth switching element (62B) in the thickness-wise direction (Z);
multiple first source connection members (193) individually connecting the source electrodes (S1, S2) of the first switching element (61A) and the second switching element (62A) to the first power interconnect (191); and
multiple second source connection members (194) individually connecting the source electrodes (S1, S2) of the fifth switching element (61B) and the sixth switching element (62B) to the second power interconnect (192).

[Clause 37] The semiconductor device according to clause 36, where the first source connection members (193) and the second source connection members (194) each include a pillar.

[Clause 38] The semiconductor device according to clause 36 or 37, further including:
a first heat dissipation plate (167) arranged on the second substrate surface (162) of the first substrate (160); and
a second heat dissipation plate (173) arranged on the second substrate surface (172) of the second substrate (170).

[Clause 39] An inverter device (200), including:
a first semiconductor device (10A) forming a U-phase inverter circuit (210);
a second semiconductor device (10B) forming a V-phase inverter circuit (220); and
a third semiconductor device (10C) forming a W-phase inverter circuit (230), where
the first semiconductor device (10A), the second semiconductor device (10B), and the third semiconductor device (10C) each include the semiconductor device (10) according to any one of clauses 1 to 38.

The description above illustrates examples. One skilled in the art may recognize further possible combinations and replacements of the elements and methods (manufacturing processes) in addition to those listed for purposes of describing the techniques of the present disclosure. All replacements, modifications, and variations within the scope of the claims are intended to be encompassed in the present disclosure.

What is claimed is:

1. A semiconductor device, comprising:
a first switching element including a first gate electrode;
a second switching element including a second gate electrode, the second switching element spaced apart from the first switching element in a first direction and connected in parallel to the first switching element;
a gate interconnect arranged between the first switching element and the second switching element in the first direction;
a first gate connection member connecting the first gate electrode and the gate interconnect; and
a second gate connection member connecting the second gate electrode and the gate interconnect, wherein
the gate interconnect includes
a first interconnect portion extending in a second direction that intersects the first direction in a plan view as viewed in a thickness-wise direction of the first switching element,
a second interconnect portion spaced apart from the first interconnect portion toward the second switching element in the first direction and extending in the second direction in the plan view, and
a joint portion joining the first interconnect portion and the second interconnect portion,
the first gate connection member is connected to a part of the first interconnect portion distant from the joint portion in the second direction, and
the second gate connection member is connected to a part of the second interconnect portion distant from the joint portion in the second direction.

2. The semiconductor device according to claim 1, wherein
the first interconnect portion includes a distal part distant from the joint portion in the second direction,
the first gate connection member is connected to the distal part of the first interconnect portion,
the second interconnect portion includes a distal part distant from the joint portion in the second direction, and
the second gate connection member is connected to the distal part of the second interconnect portion.

3. The semiconductor device according to claim 1, wherein a length of the first interconnect portion in the second direction and a length of the second interconnect portion in the second direction are each greater than a distance between the first interconnect portion and the second interconnect portion in the first direction.

4. The semiconductor device according to claim 1, wherein
a length of the first interconnect portion in the second direction is greater than a length of the first switching element in the second direction, and
a length of the second interconnect portion in the second direction is greater than a length of the second switching element in the second direction.

5. The semiconductor device according to claim 1, wherein a sum of a length of the first interconnect portion in the second direction, a length of the first gate connection member in the plan view, a length of the second interconnect portion in the second direction, and a length of the second gate connection member in the plan view is greater than a first inter-gate distance that is a distance between the first gate electrode and the second gate electrode in the plan view.

6. The semiconductor device according to claim 1, wherein
the first interconnect portion includes a distal part distant from the joint portion in the second direction, the first gate electrode is located toward the distal part of the first interconnect portion with respect to a center, in the second direction, of the first interconnect portion, and
the second interconnect portion includes a distal part distant from the joint portion in the second direction, the second gate electrode is located toward the distal part of the second interconnect portion with respect to a center, in the second direction, of the second interconnect portion.

7. The semiconductor device according to claim 1, wherein a length of the first interconnect portion in the second direction is equal to a length of the second interconnect portion in the second direction.

8. The semiconductor device according to claim 7, further comprising:
a gate terminal electrically connected to the joint portion,
wherein the first interconnect portion and the second interconnect portion each extend from the joint portion in the second direction.

9. The semiconductor device according to claim 1, further comprising:
a third switching element including a third gate electrode and located at a position spaced apart from the first switching element in the second direction and toward the first switching element in the first direction with respect to the gate interconnect, the third switching element being connected in parallel to the first switching element and the second switching element;
a fourth switching element including a fourth gate electrode and located at a position spaced apart from the second switching element in the second direction and toward the second switching element in the first direction with respect to the gate interconnect, the fourth switching element being connected in parallel to the first switching element, the second switching element, and the third switching element;
a third gate connection member connecting the third gate electrode and the gate interconnect; and
a fourth gate connection member connecting the fourth gate electrode and the gate interconnect, wherein
the gate interconnect includes
a third interconnect portion spaced apart from the first interconnect portion in the second direction and extending in the second direction, and
a fourth interconnect portion spaced apart from the second interconnect portion in the second direction and extending in the second direction,
the joint portion is located between the first interconnect portion and the third interconnect portion in the second direction and between the second interconnect portion and the fourth interconnect portion in the second direction and connects the first interconnect portion, the second interconnect portion, the third interconnect portion, and the fourth interconnect portion,
the third gate connection member is connected to a part of the third interconnect portion distant from the joint portion in the second direction, and
the fourth gate connection member is connected to a part of the fourth interconnect portion distant from the joint portion in the second direction.

10. The semiconductor device according to claim 9, wherein
the third interconnect portion includes a distal part distant from the joint portion in the second direction, the third gate connection member is connected to the distal part of the third interconnect portion, and
the fourth interconnect portion includes a distal part distant from the joint portion in the second direction, the fourth gate connection member is connected to the distal part of the fourth interconnect portion.

11. The semiconductor device according to claim 9, wherein a length of the third interconnect portion in the second direction and a length of the fourth interconnect portion in the second direction are each greater than a distance between the third interconnect portion and the fourth interconnect portion in the first direction.

12. The semiconductor device according to claim 9, wherein
a length of the third interconnect portion in the second direction is greater than a length of the third switching element in the second direction, and
a length of the fourth interconnect portion in the second direction is greater than a length of the fourth switching element in the second direction.

13. The semiconductor device according to claim 9, wherein
the third interconnect portion includes a distal part distant from the joint portion in the second direction, the third gate electrode is arranged toward the distal part of the third interconnect portion with respect to a center, in the second direction, of the third interconnect portion, and
the fourth interconnect portion includes a distal part distant from the joint portion in the second direction, the fourth gate electrode is arranged toward the distal part of the fourth interconnect portion with respect to a center, in the second direction, of the fourth interconnect portion.

14. The semiconductor device according to claim 9, wherein a sum of a length of the third interconnect portion in the second direction, a length of the third gate connection member in the plan view, a length of the fourth interconnect portion in the second direction, and
a length of the fourth gate connection member in the plan view is greater than a second inter-gate distance that is a distance between the third gate electrode and the fourth gate electrode in the plan view.

15. The semiconductor device according to claim 14, wherein the second inter-gate distance is equal to a first inter-gate distance between the first gate electrode and the second gate electrode in the plan view.

16. The semiconductor device according to claim 9, further comprising:
a gate terminal electrically connected to the joint portion,
wherein a length of the third interconnect portion in the second direction is equal to a length of the fourth interconnect portion in the second direction.

17. The semiconductor device according to claim 9, further comprising:
a gate terminal electrically connected to the joint portion, wherein
a length of the third interconnect portion in the second direction is equal to a length of the first interconnect portion in the second direction, and
a length of the fourth interconnect portion in the second direction is equal to a length of the second interconnect portion in the second direction.

18. The semiconductor device according to claim 1, further comprising:
a third switching element including a third gate electrode and located at a position spaced apart from the first switching element in the second direction and toward the first switching element in the first direction with respect to the gate interconnect, the third switching element being connected in parallel to the first switching element and the second switching element;
a fourth switching element including a fourth gate electrode and located at a position spaced apart from the second switching element in the second direction and toward the second switching element in the first direction with respect to the gate interconnect, the fourth switching element being connected in parallel to the first switching element, the second switching element, and the third switching element;
a third gate connection member connecting the third gate electrode and the gate interconnect; and
a fourth gate connection member connecting the fourth gate electrode and the gate interconnect, wherein
the gate interconnect includes
a third interconnect portion spaced apart from the first interconnect portion in the first direction at the same position as the first interconnect portion in the second direction and extending in the second direction, and
a fourth interconnect portion spaced apart from the second interconnect portion in the first direction at the same position as the second interconnect portion in the second direction and extending in the second direction,
the joint portion connects the first interconnect portion, the second interconnect portion, the third interconnect portion, and the fourth interconnect portion,
the third gate connection member is connected to a part of the third interconnect portion distant from the joint portion in the second direction, and
the fourth gate connection member is connected to a part of the fourth interconnect portion distant from the joint portion in the second direction.

19. The semiconductor device according to claim 18, wherein
the third interconnect portion and the fourth interconnect portion are arranged between the first interconnect portion and the second interconnect portion in the first direction, and
a length of each of the third interconnect portion and the fourth interconnect portion in the second direction is greater than a length of each of the first interconnect portion and the second interconnect portion in the second direction.

20. The semiconductor device according to claim 1, further comprising:
a third switching element including a third gate electrode and located at a position spaced apart from the first switching element in the second direction and toward the first switching element in the first direction with respect to the gate interconnect, the third switching element being connected in parallel to the first switching element and the second switching element;
a fourth switching element including a fourth gate electrode and located at a position spaced apart from the second switching element in the second direction and toward the second switching element in the first direction with respect to the gate interconnect, the fourth switching element being connected in parallel to the first switching element, the second switching element, and the third switching element;
a third gate connection member connecting the third gate electrode and the gate interconnect; and
a fourth gate connection member connecting the fourth gate electrode and the gate interconnect, wherein
the gate interconnect includes a third interconnect portion and a fourth interconnect portion that are connected to the joint portion,
the third interconnect portion includes a first gate connector located opposite from the first interconnect portion with respect to the first switching element and the third switching element in the first direction,
the fourth interconnect portion includes a second gate connector located opposite from the second interconnect portion with respect to the second switching element and the fourth switching element in the first direction,
the third gate connection member is connected to the first gate connector, and
the fourth gate connection member is connected to the second gate connector.
